(19) United States
(12) Patent Application Publication
(10) Pub. No.: US 2026/0013289 A1
(43) Pub. Date: Jan. 8, 2026

(54) DISPLAY PANEL AND ELECTRONIC APPARATUS INCLUDING THE SAME

(71) Applicant: Samsung Display Co., LTD., Yongin-si (KR)

(72) Inventors: Daehyun Kim, Yongin-si (KR); Mihae KIm, Yongin-si (KR); Sunghwan Kim, Yongin-si (KR); Heyjin Shin, Yongin-si (KR); Changkyu Jin, Yongin-si (KR)

(21) Appl. No.: 19/172,908

(22) Filed: Apr. 8, 2025

(30) Foreign Application Priority Data
Jul. 8, 2024 (KR) 10-2024-0089887
Sep. 3, 2024 (KR) 10-2024-0119571

(51) Int. Cl. H10H 29/32; H10H 29/49

(52) U.S. Cl. CPC H10H 29/32; H10H 29/49

(57) ABSTRACT

A display panel includes first initialization voltage lines and second initialization voltage lines which are alternately arranged along a first direction in a display area, each of the first initialization voltage lines and second initialization voltage lines extending in a second direction crossing the first direction, first-color pixel circuits and second-color pixel circuits alternately arranged along the first initialization voltage lines, and third-color pixel circuits arranged along the second initialization voltage lines. An initialization transistor of each of the second-color pixel circuits is electronically connected to an initialization transistor of one third-color pixel circuit among the third-color pixel circuits, and the one third-color pixel circuit is disposed next (adjacent) to the initialization transistor of each of the second-color pixel circuits in the first direction.

This application claims priority to Korean Patent Application No. 10-2024-0089887, filed on Jul. 8, 2024, and Korean Patent Application No. 10-2024-0119571, filed on Sep. 3, 2024, and all the benefits accruing therefrom under 35 U.S.C. § 119, the content of which in their entirety is herein incorporated by reference.

### BACKGROUND

### 1. Field

Embodiments relate to a display panel and an electronic apparatus including the same, and more particularly, to a display panel capable of displaying high-quality images and an electronic apparatus including the display panel.

### 2. Description of the Related Art

Display panels are used in various electronic apparatuses. In order to display higher-quality images by increasing resolution, pixel sizes are decreased and thus, it is desired to place a variety of electronic components in a relatively small area.

### SUMMARY

A display panel and an electronic apparatus including the same, according to the related art, have a problem in that high-quality images cannot be displayed due to electrical interference between various electronic components placed in a relatively small area.

Embodiments include a display panel capable of displaying high-quality images and an electronic apparatus including the same. However, the above objective is just an example, and the scope of the disclosure is not limited thereto.

Additional features will be set forth in part in the description which follows and, in part, will be apparent from the description, or may be learned by practice of the presented embodiments of the disclosure.

In an embodiment of the disclosure, a display panel includes first initialization voltage lines and second initialization voltage lines which are alternately arranged along a first direction in a display area, each of the first initialization voltage lines and the second initialization voltage lines extending in a second direction crossing the first direction, first-color pixel circuits and second-color pixel circuits alternately arranged along the first initialization voltage lines, and third-color pixel circuits arranged along the second initialization voltage lines. An initialization transistor of each of the second-color pixel circuits is electronically connected to an initialization transistor of one third-color pixel circuit among the third-color pixel circuits, and the one third-color pixel circuit is disposed next (adjacent) to the initialization transistor of each of the second-color pixel circuits in the first direction.

In an embodiment, a semiconductor layer of the initialization transistor of each of the second-color pixel circuits may be electrically connected to a semiconductor layer of the initialization transistor of the one third-color pixel circuit.

In an embodiment, a semiconductor layer of the initialization transistor of each of the second-color pixel circuits and a semiconductor layer of the initialization transistor of the one third-color pixel circuit may be unitary as a single body.

In an embodiment, the first initialization voltage lines may be electrically connected to one end of an initialization transistor of each of the first-color pixel circuits, and the second initialization voltage lines may be electrically connected to one end of the initialization transistor of each of the second-color pixel circuits and one end of an initialization transistor of each of the third-color pixel circuits.

In an embodiment, an opposite end of the initialization transistor of each of the first-color pixel circuits opposite to the end of the initialization transistor of each of the first-color pixel circuits may be electrically connected to an element which emits first-color light, an opposite end of the initialization transistor of each of the second-color pixel circuits opposite to the one end of the initialization transistor of each of the second-color pixel circuits may be electrically connected to an element which emits second-color light, and an opposite end of the initialization transistor of each of the third-color pixel circuits opposite to the one end of the initialization transistor of each of the third-color pixel circuits may be electrically connected to an element which emits third-color light.

In an embodiment, an opposite end of the initialization transistor of each of the first-color pixel circuits opposite to the end of the initialization transistor of each of the first-color pixel circuits may be electrically connected to a pixel electrode of an element which emits first-color light, an opposite end of the initialization transistor of each of the second-color pixel circuits opposite to the one end of the initialization transistor of each of the second-color pixel circuits may be electrically connected to a pixel electrode of an element which emits second-color light, and an opposite end of the initialization transistor of each of the third-color pixel circuits opposite to the one end of the initialization transistor of each of the third-color pixel circuits may be electrically connected to a pixel electrode of an element which emits third-color light.

In an embodiment, each of the first-color pixel circuits may be electrically connected to an element which emits red light, each of the second-color pixel circuits may be electrically connected to an element which emits blue light, and each of the third-color pixel circuits may be electrically connected to an element which emits green light.

In an embodiment, each of the first-color pixel circuits may be electrically connected to an element which emits blue light, each of the second-color pixel circuits may be electrically connected to an element which emits red light, and each of the third-color pixel circuits may be electrically connected to an element which emits green light.

In an embodiment of the disclosure, an electronic apparatus includes a display panel and a lower cover forming an exterior of the electronic apparatus and defining an opening that exposes a portion of the display panel. The display panel includes first initialization voltage lines and second initialization voltage lines which are alternately arranged along a first direction in a display area, each of the first initialization voltage lines and the second initialization voltage lines extending in a second direction crossing the first direction, first-color pixel circuits and second-color pixel circuits alternately arranged along the first initialization voltage lines, and third-color pixel circuits arranged along the second initialization voltage lines. An initialization transistor of each of the second-color pixel circuits is electronically connected to an initialization transistor of one third-color pixel circuit among the third-color pixel circuits, and the one third-color pixel circuit is disposed next (adjacent) to the initialization transistor of each of the second-color pixel circuits in the first direction.

In an embodiment, a semiconductor layer of the initialization transistor of each of the second-color pixel circuits may be electrically connected to a semiconductor layer of the initialization transistor of the one third-color pixel circuit.

In an embodiment, a semiconductor layer of the initialization transistor of each of the second-color pixel circuits and a semiconductor layer of the initialization transistor of the one third-color pixel circuit may be unitary as a single body.

In an embodiment, the first initialization voltage lines may be electrically connected to one end of an initialization transistor of each of the first-color pixel circuits and one end of the initialization transistor of each of the second-color pixel circuits, and the second initialization voltage lines may be electrically connected to one end of an initialization transistor of each of the third-color pixel circuits.

In an embodiment, an opposite end of the initialization transistor of each of the first-color pixel circuits opposite to the end of the initialization transistor of each of the first-color pixel circuits may be electrically connected to an element which emits first-color light, an opposite end of the initialization transistor of each of the second-color pixel circuits opposite to the one end of the initialization transistor of each of the second-color pixel circuits may be electrically connected to an element which emits second-color light, and an opposite end of the initialization transistor of each of the third-color pixel circuits opposite to the one end of the initialization transistor of each of the third-color pixel circuits may be electrically connected to an element which emits third-color light.

In an embodiment, an opposite end of the initialization transistor of each of the first-color pixel circuits opposite to the end of the initialization transistor of each of the first-color pixel circuits may be electrically connected to a pixel electrode of an element which emits first-color light, an opposite end of the initialization transistor of each of the second-color pixel circuits opposite to the one end of the initialization transistor of each of the second-color pixel circuits may be electrically connected to a pixel electrode of an element which emits second-color light, and an opposite end of the initialization transistor of each of the third-color pixel circuits opposite to the one end of the initialization transistor of each of the third-color pixel circuits may be electrically connected to a pixel electrode of an element which emits third-color light.

In an embodiment, each of the first-color pixel circuits may be electrically connected to an element which emits red light, each of the second-color pixel circuits may be electrically connected to an element which emits blue light, and each of the third-color pixel circuits may be electrically connected to an element which emits green light.

In an embodiment, each of the first-color pixel circuits may be electrically connected to an element which emits blue light, each of the second-color pixel circuits may be electrically connected to an element which emits red light, and each of the third-color pixel circuits may be electrically connected to an element which emits green light.

In an embodiment, a signal applied to the first initialization voltage line may be different from a signal applied to the second initialization voltage line.

In an embodiment, electric potential of a signal applied to the first initialization voltage line may be different from electric potential of a signal applied to the second initialization voltage line.

In an embodiment of the disclosure, an electronic apparatus includes first initialization voltage lines and second initialization voltage lines which are alternately arranged along a first direction in a display area, each of the first initialization voltage lines and the second initialization voltage lines extending in a second direction crossing the first direction, first-color pixel circuits and second-color pixel circuits alternately arranged along the first initialization voltage lines, and third-color pixel circuits arranged along the second initialization voltage lines. A signal applied to the first initialization voltage lines is different from a signal applied to the second initialization voltage lines.

In an embodiment, the first initialization voltage lines may be electrically connected to one end of an initialization transistor of each of the first-color pixel circuits and one end of the initialization transistor of each of the second-color pixel circuits, and the second initialization voltage lines may be electrically connected to one end of an initialization transistor of each of the third-color pixel circuits.

In an embodiment, an opposite end of the initialization transistor of each of the first-color pixel circuits opposite to the end of the initialization transistor of each of the first-color pixel circuits may be electrically connected to an element which emits first-color light, an opposite end of the initialization transistor of each of the second-color pixel circuits opposite to the one end of the initialization transistor of each of the second-color pixel circuits may be electrically connected to an element which emits second-color light, and an opposite end of the initialization transistor of each of the third-color pixel circuits opposite to the one end of the initialization transistor of each of the third-color pixel circuits may be electrically connected to an element which emits third-color light.

In an embodiment, an opposite end of the initialization transistor of each of the first-color pixel circuits opposite to the end of the initialization transistor of each of the first-color pixel circuits may be electrically connected to a pixel electrode of an element which emits first-color light, an opposite end of the initialization transistor of each of the second-color pixel circuits opposite to the one end of the initialization transistor of each of the second-color pixel circuits may be electrically connected to a pixel electrode of an element which emits second-color light, and an opposite end of the initialization transistor of each of the third-color pixel circuits opposite to the one end of the initialization transistor of each of the third-color pixel circuits may be electrically connected to a pixel electrode of an element which emits third-color light.

In an embodiment, electric potential of a signal applied to the first initialization voltage line may be different from electric potential of a signal applied to the second initialization voltage line.

In an embodiment, each of the first-color pixel circuits may be electrically connected to an element which emits red light, each of the second-color pixel circuits may be electrically connected to an element which emits blue light, and each of the third-color pixel circuits may be electrically connected to an element which emits green light.

Other features and advantages than those described above will become apparent from the following drawings, claims, and detailed description of the disclosure.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a perspective view schematically illustrating an embodiment of an electronic apparatus;

FIG. 2 is an exploded perspective view schematically illustrating the electronic apparatus of FIG. 1;

FIG. 3 is a block diagram schematically illustrating the electronic apparatus of FIG. 1;

FIG. 4 is a plan view schematically illustrating an embodiment of a display panel;

FIG. 5 is a side view schematically illustrating the display panel of FIG. 4;

FIG. 6 is a plan view schematically illustrating the display panel of FIG. 4;

FIG. 7 is an enlarged conceptual diagram schematically illustrating a portion A of the display panel of FIG. 6;

FIG. 8 is an enlarged conceptual diagram schematically illustrating an embodiment of a portion of a display panel;

FIG. 9 is an equivalent circuit diagram of one pixel disposed in a display area of the display panel of FIG. 6;

FIG. 10 is a layout diagram schematically illustrating locations of transistors, a capacitor, etc. in pixels arranged in the display area of the display panel of FIG. 6;

FIG. 11 is a cross-sectional view schematically illustrating a cross-section of the display panel taken along line B-B′ of FIG. 6;

FIGS. 12 to 20 are layout diagrams schematically illustrating, by layer, components, such as the transistors, the capacitor, etc. of the display panel illustrated in FIG. 10;

FIG. 21 is a layout diagram schematically illustrating pixel electrodes of the display panel illustrated in FIG. 10;

FIG. 22 is a cross-sectional view schematically illustrating a cross-section of the display panel taken along line C-C′ of FIG. 21;

FIG. 23 is a cross-sectional view schematically illustrating an embodiment of a cross-section of a display panel;

FIG. 24 is a plan view showing a voltage layer of FIG. 20;

FIG. 25 is a plan view schematically illustrating an embodiment of a voltage layer of a display panel;

FIG. 26 is a layout diagram schematically illustrating an embodiment of a semiconductor layer of a display panel;

FIG. 27 is a layout diagram schematically illustrating the positional relationship between the semiconductor layer of FIG. 26 and initialization voltage lines;

FIG. 28 is a layout diagram schematically illustrating an embodiment of a semiconductor layer of a display panel;

FIG. 29 is a layout diagram schematically illustrating the positional relationship between the semiconductor layer of FIG. 28 and initialization voltage lines;

FIG. 30 is a layout diagram schematically illustrating an embodiment of a semiconductor layer of a display panel;

FIG. 31 is a layout diagram schematically illustrating the positional relationship between the semiconductor layer of FIG. 30 and initialization voltage lines;

FIG. 32 is a layout diagram schematically illustrating an embodiment of the positional relationship between semiconductor layer patterns and initialization voltage lines of a display panel;

FIG. 33 is a layout diagram schematically illustrating an embodiment of the positional relationship between semiconductor layer patterns and initialization voltage lines of a display panel;

FIG. 34 is a layout diagram schematically illustrating an embodiment of the positional relationship between semiconductor layer patterns and initialization voltage lines of a display panel according to an embodiment.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

Hereinafter, embodiments of the disclosure will be described in detail with reference to the accompanying drawings, and in the description with reference to the drawings, the same or corresponding components are indicated by the same reference numerals and redundant descriptions thereof are omitted.

In the following embodiments, when an element, such as a layer, a film, a region, or a plate, is referred to as being “on” another element, the element may be directly on the other element, or intervening elements may be therebetween. Also, sizes of elements in the drawings may be exaggerated or reduced for convenience of description. For example, because sizes and thicknesses of elements in the drawings are arbitrarily illustrated for convenience of description, the following disclosure is not limited thereto.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the following embodiments, while terms such as “first” and “second” are used to describe various elements, these elements are not limited by these terms. These terms are only used to distinguish one element from another element.

In the following embodiments, terms such as “include,” “comprise,” and “have” specify the presence of stated features or elements, but do not preclude the presence or addition of one or more other features or elements.

In the specification, the expression “A and/or B” represents A, B, or A and B. Also, the expression “at least one of A and B” represents A, B, or A and B.

In the following embodiments, when a layer, region, or element is referred to as being “connected to” another layer, region, or element, it may be directly or indirectly connected to the other layer, region, or element. That is, for example, intervening layers, regions, or elements may be present. For example, when a layer, region, or element is referred to as being “electrically connected to” or “electrically coupled to” another layer, region, or element, it may be directly or indirectly electrically connected or coupled to the other layer, region, or element. That is, for example, intervening layers, regions, or elements may be present.

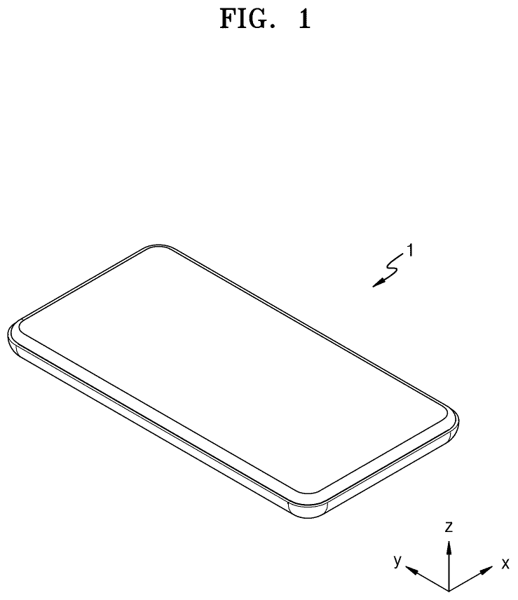

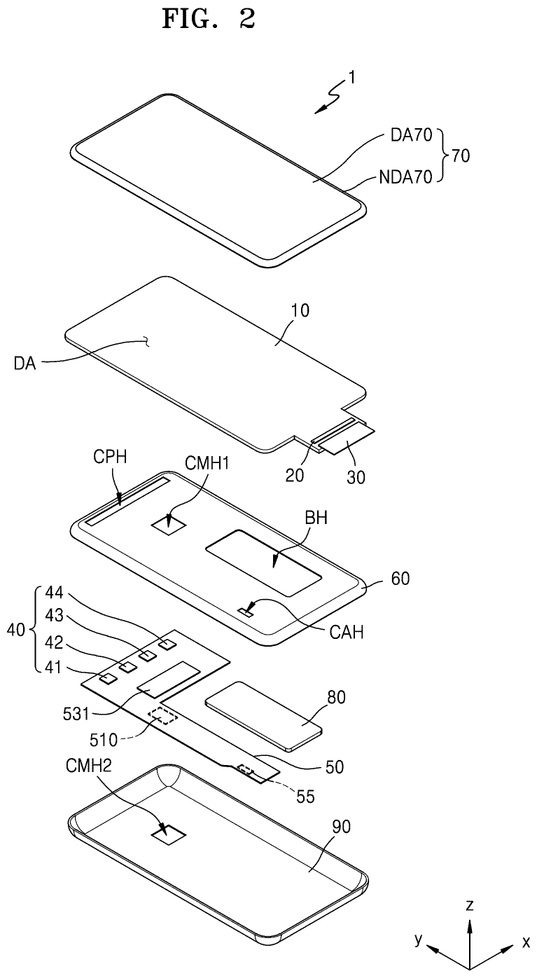

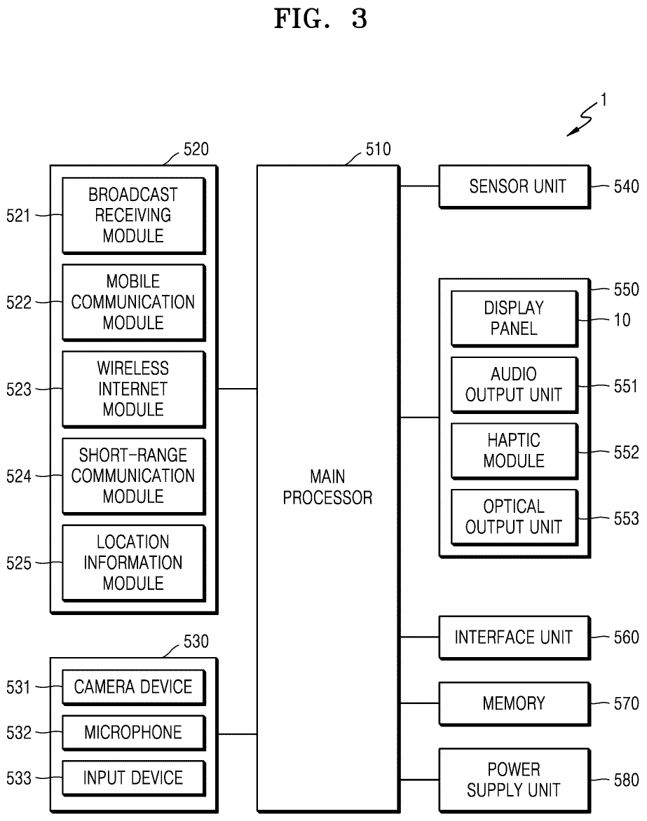

FIG. 1 is a perspective view schematically illustrating an embodiment of an electronic apparatus 1, FIG. 2 is an exploded perspective view schematically illustrating the electronic apparatus 1 of FIG. 1, and FIG. 3 is a block diagram schematically illustrating the electronic apparatus 1 of FIG. 1.

Referring to FIGS. 1 and 2, the electronic apparatus 1, which is a device for displaying moving images or still images, may be used in a portable electronic apparatus, such as a mobile phone, a smartphone, a tablet personal computer, a mobile communication terminal, an electronic notebook, an electronic book, a portable multimedia player (“PMP”), a navigation, or an ultra mobile personal computer (“UMPC”), or may be a variety of products, such as televisions, laptops, monitors, billboards, or an Internet of things (“IoT”)-linked device. The electronic apparatus 1 in an embodiment may also be a wearable device, such as a smart watch, a watch phone, a glasses-type display, or a head-mounted display (“HMD”). The electronic apparatus 1 in an embodiment may also be an instrument panel of a vehicle, a center fascia of a vehicle or a center information display (“CID”) disposed on a dashboard, a room mirror display replacing a side view mirror of a vehicle, or a display disposed on the rear side of a front seat for entertainment of backseat passengers of a vehicle.

In FIGS. 1 and 2, for convenience of description, the electronic apparatus 1 in an embodiment is illustrated as a smartphone. The electronic apparatus 1 may include a cover window 70, a display panel 10, a data driver 20, a display circuit board 30, components 40, a bracket 60, a main circuit board 50, a battery 80, and/or a lower cover 90.

Herein, “left,” “right,” “up,” and “down” in a plan view indicate directions when the display panel 10 is viewed from a direction perpendicular to the display panel 10. For example, “left” indicates a −x direction, “right” indicates a +x direction, “up” indicates a +y direction, and “down” indicates a −y direction.

The electronic apparatus 1 may appear to have an approximately quadrangular shape, e.g., rectangular shape in a plan view. In an embodiment, the electronic apparatus 1 may appear to have an approximately quadrangular shape, e.g., rectangular shape having a short side in the x-axis direction and a long side in the y-axis direction in the x-y plane, as shown in FIG. 1, for example. A corner at which the short side in the x-axis direction meets the long side in the y-axis direction may be formed to have a round shape with a predetermined curvature or formed to be a right angle. The planar shape of the electronic apparatus 1 is not limited to a rectangle, and may include other polygonal, elliptical, or irregular shapes.

The cover window 70 may be disposed over the display panel 10 to cover an upper surface of the display panel 10. The cover window 70 as above may function to protect the upper surface of the display panel 10.

The cover window 70 may include a transparent cover unit DA70 corresponding to the display panel 10 and a light-shielding cover unit NDA70 surrounding the transparent cover unit DA70. The light-shielding cover unit NDA70 may include an opaque material (e.g., a colored opaque material) that blocks light. The light-shielding cover unit NDA70 may include a pattern that is visible to the user when no image is displayed.

The display panel 10 may be disposed below the cover window 70. The display panel 10 may overlap the transparent cover unit DA70 of the cover window 70. The display panel 10 may include a display area DA. The display area DA, which is an area where an image is displayed, may include an area (hereinafter, also referred to as “component area”) through which light emitted from the components 40 disposed below the display panel 10 passes. The component may include sensors, cameras, or the like that use visible light, an infrared ray, or sound.

The display panel 10 may be a light-emitting display panel including a light-emitting element (e.g., light-emitting diode). The light-emitting element may be a light-emitting diode such as an organic light-emitting diode (“OLED”) including an organic light-emitting layer, or an inorganic light-emitting diode including an inorganic material. The inorganic light-emitting diode may include a PN diode including inorganic semiconductor-based materials. When a voltage is applied in a forward direction to a PN junction diode, holes and electrons may be injected, and energy generated by recombination of the holes and electrons may be converted into light energy, to emit light of a predetermined color. The inorganic light-emitting diode described above may have a width of several to several hundred micrometers. The inorganic light-emitting diodes may be also referred to as micro light-emitting diodes.

The display panel 10 may be a rigid display panel that is rigid and is not easily bendable, or a flexible display panel that is easily bendable, foldable, or rollable. In an embodiment, the display panel 10 may be a foldable display panel, a curved display panel with a curved display surface, a bended display panel in which an area other than a display surface is bent, a rollable display panel that may be rolled or unrolled, or a stretchable display panel, for example.

The display panel 10 may be a transparent display panel that allows an object or background in a rear side of the display panel 10 to be visible from a front side of the display panel 10. In an alternative embodiment, the display panel 10 may be a reflective display panel capable of reflecting light from an object in front of the display panel 10 or light from the background in the rear side of the display panel 10.

The data driver 20 may be disposed (e.g., mounted) on the display panel 10 in the form of an integrated circuit (“IC”). In another embodiment, the data driver 20 may be disposed on the display circuit board 30.

The display circuit board 30 may be affixed to one side of the display circuit board 30. The display circuit board 30 may be a flexible printed circuit board (“FPCB”) that may be bent, a rigid printed circuit board (“PCB”) that is hard and is not easily bendable, or a composite printed circuit board including both an FPCB and a rigid PCB. A touch sensor driving unit may be disposed (e.g., mounted) on the display circuit board 30. The touch sensor driving unit may be formed as an IC. The touch sensor driving unit may be electrically connected to touch electrodes of a touch screen layer of the display circuit board 30 through the display circuit board 30.

The touch screen layer of the display panel 10 may detect a user's touch input by at least one of various touch methods such as a resistive film method and an electrostatic capacitance method. When the touch screen layer of the display panel 10 detects a user's touch input in an electrostatic capacitive manner, the touch sensor driving unit may apply driving signals to driving electrodes of the touch electrodes and detect, through sensing electrodes of the touch electrodes, voltages due to mutual electrostatic capacitances (hereinafter, also referred to as “mutual capacitance”) between the driving electrodes and the sensing electrodes, thereby determining whether a user's touch is received.

The user's touch may include a contact touch and a proximity touch. The contact touch indicates that a user's finger or an object such as a pen is in direct contact with the cover window 70 disposed on the touch screen layer. The proximity touch indicates that a user's finger or an object such as a pen is disposed close to the cover window 70, such as by hovering. The touch sensor driving unit may transmit sensor data to a main processor 510 according to the detected voltages, and the main processor 510 may analyze the sensor data and calculate touch coordinates at which a touch input has occurred.

A control unit for supplying driving voltages for driving pixels of the display panel 10, a gate driver, and the data driver 20 may be disposed on the display circuit board 30.

The bracket 60 for supporting the display panel 10 may be disposed below the display panel 10. The bracket 60 may include plastic, metal, or both plastic and metal. The bracket 60 may define a first camera hole CMH1 into which a camera device 531 is inserted, a battery hole BH in which the battery 80 is disposed, a cable hole CAH through which a cable connected to the display circuit board 30 passes, and component hole CPH corresponding to the components 40. The component hole CPH may overlap the components 40 of the main circuit board 50 when viewed from a third direction (z-axis direction). For reference, the display area DA of the display panel 10 may overlap the components 40 of the main circuit board 50 when viewed from the third direction (z-axis direction). In another embodiment, the bracket 60 may not define a component hole CPH.

The components 40 of the electronic apparatus 1 may include a first component 41, a second component 42, a third component 43, and a fourth component 44 which overlap the display panel 10. Each of the first component 41, the second component 42, the third component 43, and the fourth component 44 may include at least one of a proximity sensor, an illumination sensor, an iris sensor, a face recognition sensor, and a camera (or image sensor). The proximity sensor using infrared rays may detect an object disposed close to an upper surface of the electronic apparatus 1, and the illumination sensor may detect a brightness of light incident on the upper surface of the electronic apparatus 1. In addition, the iris sensor may photograph a person's iris over the upper surface of the electronic apparatus 1, and the camera may photograph an object disposed over the upper surface of the electronic apparatus 1. The components 40 are not limited to a proximity sensor, an illumination sensor, an iris sensor, a face recognition sensor, and a camera, and may include various sensors.

The main circuit board 50 and the battery 80 may be disposed below the bracket 60. The main circuit board 50 may be a printed circuit board or a FPCB.

The main circuit board 50 may include the main processor 510, the camera device 531, a main connector 55, and the components 40. The main processor 510 may be formed as an IC. When desired, the electronic apparatus 1 may include not only a camera device 531 disposed over the upper surface of the main circuit board 50 but also a camera device disposed below a lower surface of the main circuit board 50. Each of the main processor 510 and the main connector 55 may be disposed on either one of the upper and lower surfaces of the main circuit board 50. The main circuit board 50 may be electrically connected to the display circuit board 30 through the main connector 55, etc.

The main processor 510 may control all functions of the electronic apparatus 1. In an embodiment, the main processor 510 may output digital video data to the data driver 20 so that an image is displayed on the display panel 10, for example. The main processor 510 may receive an input of sensing data from the touch sensor driving unit. The main processor 510 may determine whether a user's touch is received according to the sensing data, and execute an operation corresponding to a direct touch or proximity touch of the user. The main processor 510 may be an application processor, a central processing unit, or a system chip, each of which include an IC.

The camera device 531 may process image frames of a still image, a moving image, or the like obtained by an image sensor in a camera mode, and output the processed image frames to the main processor 510. The camera device 531 may include at least one of a camera sensor (e.g., charge-coupled device (“CCD”), complementary metal-oxide-semiconductor (“CMOS”), or the like), a photo sensor (or image sensor), or a laser sensor.

A cable, which passes through the cable hole CAH defined in the bracket 60, may be connected to the main connector 55, and thus the main connector 55 may be electrically connected to the display circuit board 30.

The electronic apparatus 1 may be represented by a block diagram as shown in FIG. 3. The electronic apparatus 1 may be represented as including, in addition to the main processor 510, a wireless communication unit 520, an input unit 530, a sensor unit 540, an output unit 550, an interface unit 560, a memory 570, and/or a power supply unit 580 shown in FIG. 3.

The wireless communication unit 520 may include at least one of a broadcast receiving module 521, a mobile communication module 522, a wireless Internet module 523, a short-range communication module 524, or a location information module 525.

The broadcast receiving module 521 may receive broadcast signals and/or broadcast-related information from an external broadcast management server via a broadcast channel. The broadcast channel may include satellite channels and terrestrial channels.

The mobile communication module 522 may transmit and receive wireless signals to and from at least one of, an external terminal, a server on a mobile communication network, or a base station established according to technology standards or communication methods for mobile communication (e.g., global system for mobile communication (“GSM”), code division multi access (“CDMA”), code division multi access 2000 (“CDMA2000”), enhanced voice-data optimized or enhanced voice-data only (“EV-DO”), wideband CDMA (“WCDMA”), high speed downlink packet access (“HSDPA”), high speed uplink packet access (“HSUPA”), long term evolution (“LTE”), and long term evolution-advanced (“LTE-A”)). The wireless signal may include voice call signals, video call signals, or various forms of data according to text/multimedia message transmission and reception.

The wireless Internet module 523 is a module for wireless Internet connection. The wireless Internet module 523 may transmit and receive wireless signals in a communication network according to wireless Internet technologies. The wireless Internet technology may include wireless LAN (“WLAN”), wireless-fidelity (“Wi-Fi”), Wi-Fi direct, digital living network alliance (“DLNA”), or the like, for example.

The short-range communication module 524, which ensures short-range communication, may support short-range communication by at least one of Bluetooth® radio frequency identification (“RFID”), infrared data association (“IrDA”), ultra wideband (“UWB”), Zigbee, near field communication (“NFC”), Wi-Fi, Wi-Fi Direct, or Wireless universal seral bus (“USB”) technologies. The short-range communication module 524 may support wireless communication between the electronic apparatus 1 and a wireless communication system, between the electronic apparatus 1 and another electronic apparatus, or the electronic apparatus 1 and a network where another electronic apparatus (or external server) is disposed, through wireless area networks. The wireless area networks may be wireless personal area networks. A remaining (the other) electronic apparatus may be a wearable device capable of mutually exchanging data with (or linking with) the electronic apparatus 1.

The location information module 525, which is a module for obtaining a location (or current location) of the electronic apparatus 1, may include a global positioning system (“GPS”) module or a Wi-Fi module.

The input unit 530 may include an image input unit such as the camera device 531 for inputting an image signal, an audio input unit such as a microphone 532 for inputting an audio signal, and an input device 533 for receiving information from a user. The camera device 531 may process image frames, such as still images or moving images, obtained by an image sensor in a video call mode or shooting mode. The processed image frames may be displayed on the display panel 10 or stored in the memory 570. The microphone 532 may process external audio signals into electrical sound data. The processed sound data may be variously used according to a function being performed (or application being run) in the electronic apparatus 1.

The main processor 510 may control an operation of the electronic apparatus 1 to correspond to information received via the input device 533. The input device 533 may include a touch input means, or a mechanical input means, such as a button disposed on the rear surface or side surface of the electronic apparatus 1, a dome switch, a jog wheel, or a jog switch. The touch input means may include a touch screen layer of the display panel 10.

The sensor unit 540 may include one or more sensors configured to sense at least one of information within the electronic apparatus 1, surrounding environment information of the electronic apparatus 1, or user information, and generate a sensing signal corresponding thereto. Based on this sensing signal, the main processor 510 may control driving or operation of the electronic apparatus 1 or perform data processing, functions, or operations associated with applications installed in the electronic apparatus 1. The sensor unit 540 may be a proximity sensor, an illumination sensor, or a facial recognition sensor as described above with respect to the components 40. The sensor unit 540 may include an acceleration sensor, a magnetic sensor, a G-sensor, a gyroscope sensor, a motion sensor, an RGB sensor, an infrared (“IR”) sensor, a finger scan sensor, an ultrasonic sensor, an optical sensor, and/or a battery gauge. In addition, the sensor unit 540 may include an environmental sensor or a chemical sensor. The environmental sensors may include a barometer, a hygrometer, a thermometer, a radiation detection sensor, a heat detection sensor, and/or a gas detection sensor, for example. Chemical sensors may include an electronic nose, a healthcare sensor, and/or a biometric recognition sensor, for example.

The output unit 550 is for generating an output associated with vision, hearing, and tactile sensations, and may include at least one of the display panel 10, an audio output unit 551, a haptic module 552, or an optical output unit 553.

The display panel 10 may display (output) information processed in the electronic apparatus 1. In an embodiment, the display panel 10 may display execution screen information of an application driven in the electronic apparatus 1, or to display user interface (“UI”) or graphic UI (“GUI”) information according to the execution screen information, for example. The display panel 10 may include a display layer for displaying images and a touch screen layer for detecting a touch input of a user. Therefore, the display panel 10 may function as one of the input devices 533 that provide an input interface between the electronic apparatus 1 and the user, and at the same time, may function as the output unit 550 that provides an output interface between the electronic apparatus 1 and the user.

The audio output unit 551 may output audio data received from the wireless communication unit 520 or stored in the memory 570 in a call signal reception mode, a call mode, a recording mode, a speech recognition mode, a broadcast reception mode, or the like. The audio output unit 551 may output audio signals associated with functions performed in the electronic apparatus 1, such as call signal reception sound, message reception sound, or the like. The audio output unit 551 may include a receiver or a speaker. At least one of the receiver or the speaker may be a sound generation device that is attached below the display panel 10 and vibrates the display panel 10 to output sound. The sound generation device may be a piezoelectric element, or piezoelectric actuator, that contracts and expands in response to an electric signal, or an exciter that generates a magnetic force by a voice coil and vibrates the display panel 10.

The haptic module 552 may generate various tactile effects that may be felt by the user. The haptic module 552 may provide vibration to the user as a tactile effect. The haptic module 552 may not only transfer a tactile effect through direct contact, but also may be implemented such that the user may feel the tactile effect through muscle senses of the fingers or arms.

The optical output unit 553 may output a signal for notifying the occurrence of an event by light from a light source. In embodiments, events occurring in the electronic apparatus 1 may include receiving a message, receiving a call signal, receiving a missed call, an alarm, a schedule alarm, a schedule reminder, receiving an e-mail, receiving information through an application, or the like. The signal output from the optical output unit 553 may be implemented as the electronic apparatus 1 emits light of a single color or a plurality of colors from the front or rear thereof. The outputting of the signal may be terminated when the electronic apparatus 1 detects the user's identification of the event.

The interface unit 560 serves as a passageway for various types of external devices connected to the electronic apparatus 1. The interface unit 560 may include at least one of a wired/wireless headset port, an external charger port, a wired/wireless data port, a memory card port, a port connecting a device equipped with an identification module, an audio input/output (“I/O”) port, a video I/O port, or an earphone port. When the electronic apparatus 1 is connected to an external device through the interface unit 560, the electronic apparatus 1 may perform an appropriate control associated with the connected external device.

The memory 570 may store data supporting various functions of the electronic apparatus 1. The memory 570 may store a plurality of application programs running on the electronic apparatus 1, data for an operation of the electronic apparatus 1, and instructions. At least some of the plurality of applications may be downloaded from an external server through wireless communication. The memory 570 may store an application for an operation of the main processor 510, or may temporarily store input/output data, e.g., data such as a phonebook, messages, still images, and moving images. In addition, the memory 570 may store haptic data for vibration of various patterns provided to the haptic module 552, and audio data associated with various sounds provided to the audio output unit 551.

The memory 570 may include a storage medium of at least one type from among a flash memory type, a hard disk type, a solid state disk type (“SSD”) type, a silicon disk drive (“SDD”) type, a multimedia card micro type, a card-type memory (e.g., secure digital (“SD”) or extreme digital (“XD”) memory), random access memory (“RAM”), static RAM (“SRAM”), read-only memory (“ROM”), electrically erasable programmable ROM (“EEPROM”), programmable ROM (“PROM”), magnetic memory, a magnetic disk, or an optical disk.

Under the control of the main processor 510, the power supply unit 580 may receive external power and/or internal power and supply power to each of elements included in the electronic apparatus 1. The power supply unit 580 may include the battery 80. In addition, the power supply unit 580 may have a connection port, and the connection port may be configured in an embodiment of the interface unit 560 to which an external charger supplying power for battery charging is electrically connected. In an alternative embodiment, the power supply unit 580 may charge the battery 80 in a wireless manner. As shown in in FIG. 2, the battery 80 may be disposed not to overlap the main circuit board 50 in the third direction (z-axis direction). The battery 80 may overlap the battery hole BH of the bracket 60.

As shown in FIG. 2, the lower cover 90 may define the exterior shape of the electronic apparatus 1, and may define an opening that exposes a part of the display panel 10. The lower cover 90 may be assembled with the display panel 10 such that the display area of the display panel 10 is exposed through the opening of the lower cover 90. The lower cover 90 may be disposed such that the display panel 10 is interposed between the lower cover 90 and the cover window 70. The lower cover 90 may be disposed below the main circuit board 50 and the battery 80. The lower cover 90 may be fastened and fixed to the bracket 60. The lower cover 90 may define the exterior shape of a lower part of the electronic apparatus 1. The lower cover 90 may include plastic, metal, or both plastic and metal.

A second camera hole CMH2 through which a lower surface of the camera device 531 is exposed may be defined in the lower cover 90. A location of the camera device 531 and positions of the first and second camera holes CMH1 and CMH2 corresponding to the camera device 531 are not limited to the embodiments shown in FIGS. 1 and 2, and may be variously modified.

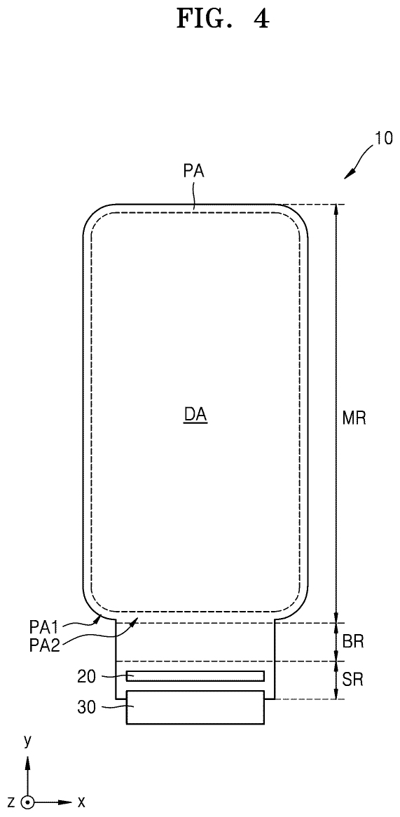

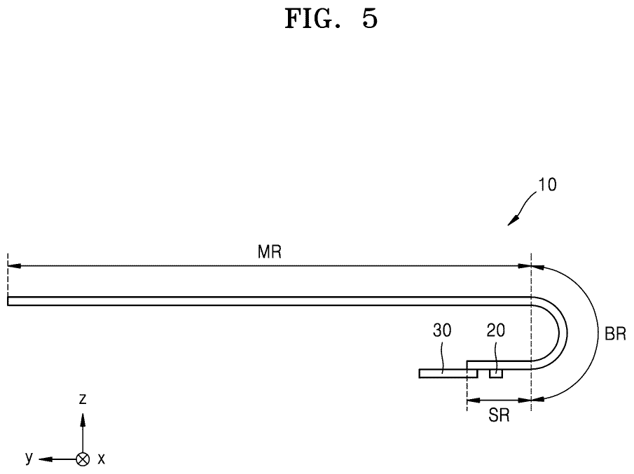

FIG. 4 is a plan view schematically illustrating an embodiment of the display panel 10, and FIG. 5 is a side view schematically illustrating the display panel 10 of FIG. 4. The electronic apparatus 1 described above may include the display panel 10 shown in FIGS. 4 and 5.

The display panel 10 may include the display area DA and a peripheral area PA outside the display area DA. The display area DA is a portion in which an image is displayed, and a plurality of pixels may be disposed in the display area DA. The display area DA may have various shapes such as a circle, an ellipse, a polygon, and/or some other predetermined shape, for example. FIG. 4 shows that the display area DA has an approximately quadrangular shape, e.g., rectangular shape with round corners.

The peripheral area PA may be disposed outside the display area DA. The peripheral area PA may include a first peripheral area PA1 surrounding at least a part of the display area DA, and a second peripheral area PA2 at the bottom of the display area DA and extending in the first direction (x-axis direction). The width of the second peripheral area PA2 in the first direction (x-axis direction) may be smaller than the width of the display area DA in the first direction (x-axis direction). This structure may make it easy for at least a part of the second peripheral area PA2 to be bent.

A planar shape of the display panel 10 shown in FIG. 4 may be substantially identical to a shape of a substrate 100 included in the display panel 10. When it is described that the display panel 10 includes the display area DA and the peripheral area PA outside the display area DA, it may indicate that the substrate 100 includes the display area DA and the peripheral area PA outside the display area DA. Hereinbelow, for convenience of description, it is described that the substrate 100 includes the display area DA and the peripheral area PA.

The display panel 10 may include a main area MR, a bending area BR outside the main area MR, and a sub-area SR spaced apart from the main area MR with the bending area BR therebetween. The main area MR may be disposed at one side of the bending area BR, and the sub-area SR may be disposed on an opposite side of the bending area BR opposite to the one side of the bending area BR. The display panel 10 may be bent in the bending area BR, as shown in FIG. 5, and when viewed from the third direction (e.g., a z-axis direction), at least part of the sub-area SR may overlap the main area MR. FIG. 5 shows that the display panel 10 is bent, but the disclosure is not limited thereto. In an embodiment, the display panel 10 is a foldable display panel, and the display panel 10 may be bent with respect to a bending axis crossing the display area DA. In another embodiment, the display panel 10 may not be bent, for example. The sub-area SR may be a non-display area.

The data driver 20 may be disposed in the sub-area SR of the display panel 10. The data driver 20 may be disposed on the display panel 10 in the form of an IC. In an embodiment, the data driver 20 may be a data driving IC configured to generate data signals, for example.

The display circuit board 30 may be affixed to an end of the sub-area SR of the display panel 10. The display circuit board 30 may be electrically connected to the data driver 20 or the like through a pad of the sub-area SR of the display panel 10.

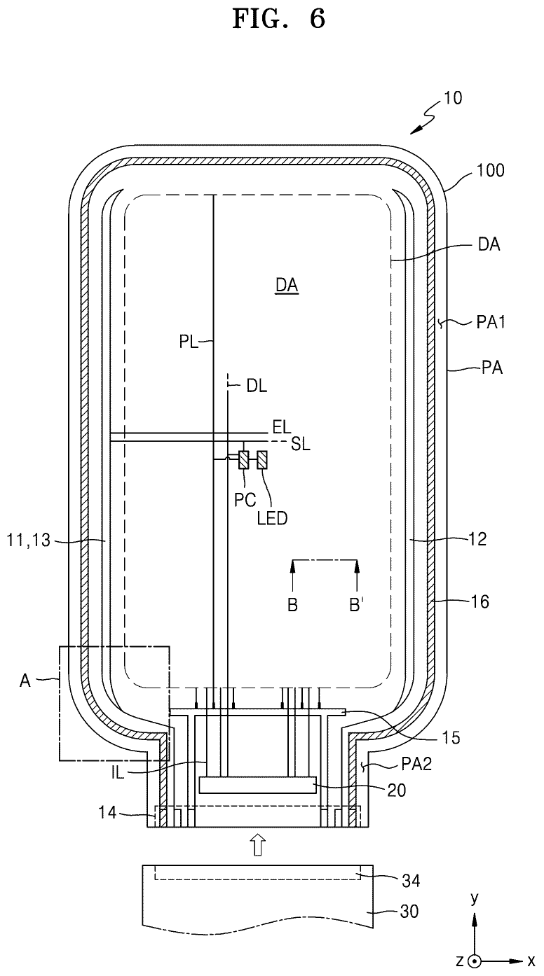

FIG. 6 is a plan view schematically illustrating an embodiment of the display panel 10. As shown in FIG. 6, the display panel 10 may include the substrate 100. Various elements included in the display panel 10 may be disposed on the substrate 100.

The substrate 100 may include glass, metal, or polymer resin. The substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layer structure including two layers and an inorganic layer between the two layers, the two layers including the polymer resin described above. In an alternative embodiment, the substrate 100 may have a layered-structure in which layers including polymer resin and inorganic layers are alternately stacked. The inorganic layers may include silicon oxide, silicon nitride or silicon oxynitride, for example.

Pixels may be disposed in the display area DA, and the display area DA may provide images by light emitted from the pixels. Each of the pixels may include a light-emitting element LED, and the light-emitting element LED may be electrically connected to a pixel circuit PC. The pixel circuit PC and the light-emitting element LED may be disposed in the display area DA. In FIG. 6, for convenience, the pixel circuit PC and the light-emitting element LED are shown as being disposed side by side, however, the pixel circuit PC and the light-emitting element LED may overlap at least partially. In an embodiment, the light-emitting diode (“LED”) may be disposed over the pixel circuit PC, for example.

A gate driving circuit, a pad 14, a first power supply line 15, and a second power supply line 16 may be arranged in the peripheral area PA. The gate driving circuit may include a first scan driving circuit 11, a second scan driving circuit 12, and/or an emission control driving circuit 13, for example.

The first scan driving circuit 11 may provide a scan signal to the pixel circuit PC through a gate line SL. The second scan driving circuit 12 may be disposed on the opposite side from the first scan driving circuit 11 with the display area DA therebetween. Some of the pixel circuits PC disposed in the display area DA may be electrically connected to the first scan driving circuit 11, and the remaining one(s) may be connected to the second scan driving circuit 12. In another embodiment, the second scan driving circuit 12 may be omitted.

The emission control driving circuit 13 may be disposed on the first scan driving circuit 11 side and may provide an emission control signal to a pixel P through an emission control line EL. The emission control driving circuit 13 may provide an emission control signal to the pixel P through the emission control line EL. In FIG. 6, the emission control driving circuit 13 may be disposed on only one side of the display area DA. However, the disclosure is not limited thereto. In an embodiment, the display panel 10 may comprise one emitting control driving circuit 13 disposed on one side of the display area DA and another emitting control driving circuit 13 on an opposite side of the display area DA. In an alternative embodiment, the display panel 10 may comprise the first scan driving circuit 11 disposed on one side of the display area DA, and the emission control driving circuit 13 disposed on the opposite side of the display area DA.

The pad 14 may be disposed in the second peripheral area PA2 of the substrate 100. The pad 14 may not be covered by an insulating layer, but may be exposed and electrically connected to the display circuit board 30. A pad 34 of the display circuit board 30 may be electrically connected to the pad 14 of the display panel 10.

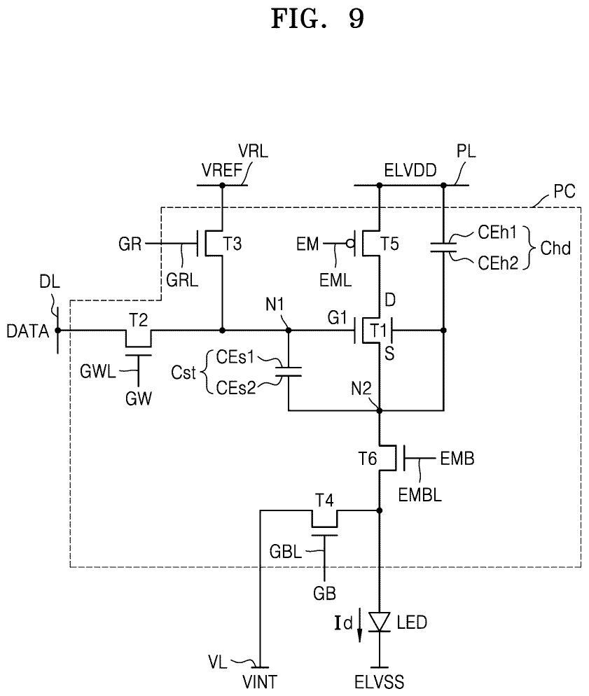

The display circuit board 30 may transmit a signal or power of a control unit to the display panel 10. Control signals generated by the control unit may be transmitted to a gate driving circuit through the display circuit board 30. In addition, the control unit may provide a first power voltage ELVDD (refer to FIG. 9) to a first power supply line 15 and a second power voltage ELVSS (refer to FIG. 9) to second power supply line 16. The first power voltage ELVDD (hereinafter, also referred to as “driving voltage”) may be provided to each pixel circuit PC through a driving voltage line PL connected to the first power supply line 15, and the second power voltage ELVSS (hereinafter, also referred to as “common voltage”) may be provided to a common electrode of the light-emitting element LED connected to the second power supply line 16. The first power supply line 15 may extend in the first direction (e.g., the x-axis direction). The second power supply line 16 may have a loop shape with one open side and partially surround the display area DA.

A data signal of the data driver 20 may be transmitted to the pixel circuit PC through an input line IL and a data line DL electrically connected to the input line IL.

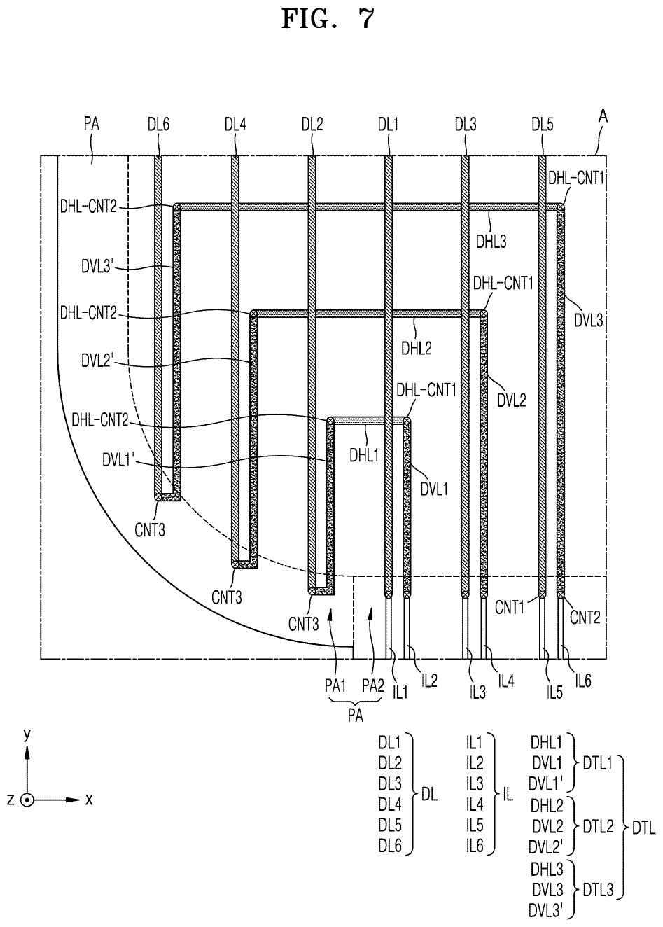

FIG. 7 is an enlarged conceptual diagram schematically illustrating part A of the display panel 10 of FIG. 6. As shown in FIG. 7, a data line DL extending in the second direction (y-axis direction) may be disposed in the display area DA, and the input line IL may be disposed in the peripheral area PA. The input line IL may transmit a data signal of the data driver 20 to the data line DL. For convenience of description, FIG. 7A shows that the data line DL includes a first data line DL1, a second data line DL2, a third data line DL3, a fourth data line DL4, a fifth data line DI5, and a sixth data line DL6 and the input line IL includes a first input line IL1, a second input line IL2, a third input line IL3, a fourth input line IL4, a fifth input line IL5, and a sixth input line IL6. However, the number of the data lines DL and the number of the input lines IL may be variously changed.

Some of the data lines DL may be directly connected to an input line, but some of remaining (the other) ones of the data lines DL may be electrically connected through a data transfer line DTL, which is between the input line IL and the data line DL corresponding thereto.

The first data line DL1, the third data line DL3, and the fifth data line DL5 may receive data signals from the first input line IL1, the third input line IL3, and the fifth input line IL5. The first data line DL1, the third data line DL3, and the fifth data line DL5 may be electrically connected to the first input line IL1, the third input line IL3, and the fifth input line IL5. Each of the first data line DL1, the third data line DL3, and the fifth data line DL5 may be unitary as a single body with a corresponding one of the first input line IL1, the third input line IL3, and the fifth input line IL5. In an alternative embodiment, each of the first data line DL1, the third data line DL3, and the fifth data line DL5 may be electrically connected to a corresponding one of the first input line IL1, the third input line IL3, and the fifth input line IL5 through a first contact hole CNT1, as shown in FIG. 7.

The second data line DL2, the fourth data line DL4, and the sixth data line DL6 may be electrically connected to the second input line IL2, the fourth input line IL4, and the sixth input line IL6 through a first data transfer line DTL1, a second data transfer DTL2, and a third data transfer line DTL3. That is, the second input line IL2 may be electrically connected to the second data line DL2 through the first data transfer line DTL1, the fourth input line IL4 may be electrically connected to the fourth data line DL4 through the second data transfer line DTL2, and the sixth input line IL6 may be electrically connected to the sixth data line DL6 through the third data transfer line DTL3.

Most of each of the first data transfer line DTL1, the second data transfer line DTL2, and the third data transfer line DTL3 may be disposed within the display area DA. One end of each of the first data transfer line DTL1, the second data transfer line DTL2, and the third data transfer line DTL3 may be electrically connected to a corresponding one of the second input line IL2, the fourth input line IL4, and the sixth input line IL6 through a second contact hole CNT2. An opposite end of each of the first data transfer line DTL1, the second data transfer line DTL2, and the third data transfer line DTL3 opposite to the one end of each of the first data transfer line DTL1, the second data transfer line DTL2, and the third data transfer line DTL3 may be electrically connected to a corresponding one of the second data line DL2, the fourth data line DL4, and the sixth data line DL6 through a third contact hole CNT3. In FIG. 7, the second contact hole CNT2 and the third contact hole CNT3 are disposed in the peripheral area PA. However, the disclosure is not limited thereto. In an embodiment, the second contact hole CNT2 and/or the third contact hole CNT3 may be disposed in the display area DA.

The first data transfer line DTL1 may include a first horizontal connection line DHL1, a first vertical connection line DVL1, and a first additional vertical connection line DVL1′, the second data transfer line DTL2 may include a second horizontal connection line DHL2, a second vertical connection line DVL2, and a second additional vertical connection line DVL2′, and the third data transfer line DTL3 may include a third horizontal connection line DHL3, a third vertical connection line DVL3, and a third additional vertical connection line DVL3′. The first horizontal connection line DHL1, the second horizontal connection line DHL2, and the third horizontal connection line DHL3 may extend approximately in the first direction (x-axis direction). The first vertical connection line DVL1, the second vertical connection line DVL2, the third vertical connection line DVL3, the first additional vertical connection line DVL1′, the second additional vertical connection line DVL2′, and the third additional vertical connection line DVL3′ may extend approximately in the second direction (y-axis direction) and may be substantially parallel to the data line DL.

Each of the second input line IL2, the fourth input line IL4, and the sixth input line IL6 may be electrically connected to a corresponding one of the first vertical connection line DVL1, the second vertical connection line DVL2, and the third vertical connection line DVL3 through the second contact hole CNT2, and each of the second data line DL2, the fourth data line DL4, and the sixth data line DL6 may be electrically connected to a corresponding one of the first additional vertical connection line DVL1′, the second additional vertical connection line DVL2′, and the third additional vertical connection line DVL3′ through the third contact hole CNT3. Each of the first horizontal connection line DHL1, the second horizontal connection line DHL2, and the third horizontal connection line DHL3 may be electrically connected to a corresponding one of the first vertical connecting line DVL1, the second vertical connecting line DVL2, and the third vertical connecting line DVL3 through a first connecting contact hole DHL-CNT1, and may be electrically connected to a corresponding one of the first additional vertical connecting line DVL1′, the second additional vertical connecting line DVL2′, and the third additional vertical connecting line DVL3′ through a second connecting contact hole DHL-CNT2.

The first vertical connecting line DVL1, the second vertical connecting line DVL2, the third vertical connecting line DVL3, the first additional vertical connecting line DVL1′, the second additional vertical connecting line DVL2′, and the third additional vertical connecting line DVL3′ may be disposed on a first layer, and the first horizontal connection line DHL1, the second horizontal connection line DHL2, and the third horizontal connection line DHL3 may be disposed on a second layer which is different from the first layer. When predetermined components are disposed in a same layer, those components may be formed simultaneously with the same material through the same mask process.

As described above, FIG. 7 shows that the first data transfer line DTL1 includes a first horizontal connection line DHL1, a first vertical connection line DVL1, and a first additional vertical connection line DVL1′, the second data transfer line DTL2 includes a second horizontal connection line DHL2, a second vertical connection line DVL2, and a second additional vertical connection line DVL2′, and the third data transfer line DTL3 includes a third horizontal connection line DHL3, a third vertical connection line DVL3, and a third additional vertical connection line DVL3′. However, the disclosure is not limited thereto.

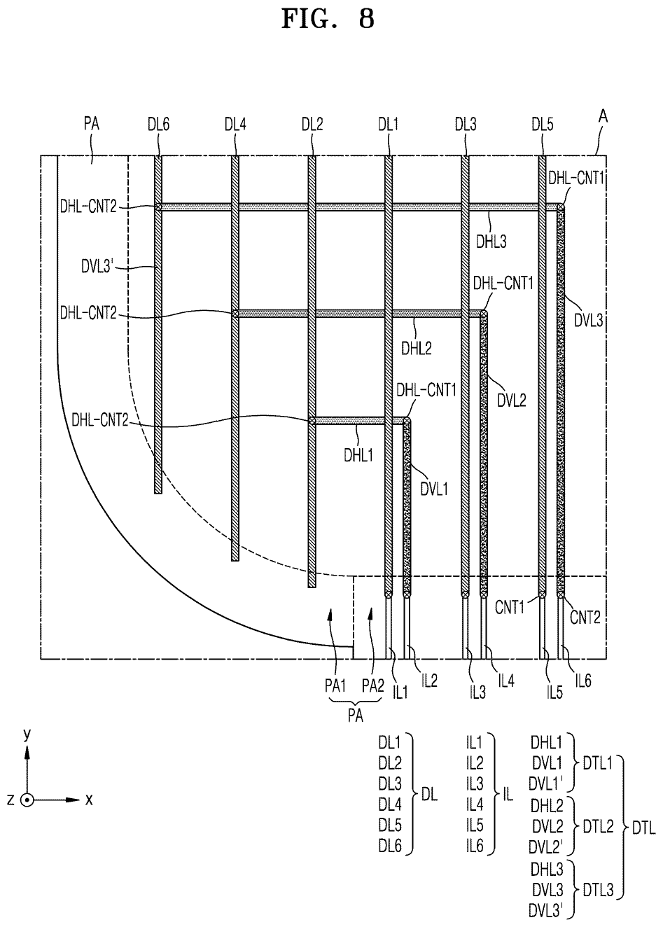

As shown in FIG. 8, which is an enlarged conceptual diagram schematically illustrating an embodiment of a portion of a display panel 10, a first data transfer line DTL1 may include a first horizontal connection line DHL1 and a first vertical connection line DVL1, a second data transfer line DTL2 may include a second horizontal connection line DHL2 and a second vertical connection line DVL2, and a third data transfer line DTL3 may include a third horizontal connection line DHL3 and a third vertical connection line DVL3. In this case, each of the first horizontal connection line DHL1, the second horizontal connection line DHL2, and the third horizontal connection line DHL3 may be electrically connected to a corresponding one of the first vertical connection line DVL1, the second vertical connection line DVL2, and the third vertical connection line DVL3 through the first connection contact hole DHL-CNT1, and may be electrically connected to a corresponding one of the second data line DL2, the fourth data line DL4, and the sixth data line DL6 through the second connection contact hole DHL-CNT2, for example.

FIG. 9 is an equivalent circuit diagram of one pixel disposed in the display area DA of the display panel 10 of FIG. 6. As illustrated in FIG. 9, the pixel circuit PC connected to the light-emitting element LED may include a plurality of transistors and a plurality of capacitors. In an embodiment, the pixel circuit PC may include a first transistor T1, a second transistor T2, a third transistor T3, a fourth transistor T4, a fifth transistor T5, a sixth transistor T6, a storage capacitor Cst, and a hold capacitor Chd, for example.

The first transistor T1 may be a driving transistor which outputs a driving current corresponding to a data signal, and the second transistor T2, the third transistor T3, the fourth transistor T4, the fifth transistor T5, and the sixth transistor T6 may be switching transistors which transfer signals through on/off. A first terminal (first electrode) of each of the first transistor T1, the second transistor T2, the third transistor T3, the fourth transistor T4, the fifth transistor T5, and the sixth transistor T6 may be one of a source region or a drain region, and a second terminal (second electrode) may be a remaining (the other) one of the source region and the drain region.

At least one of the first transistor T1, the second transistor T2, the third transistor T3, the fourth transistor T4, the fifth transistor T5, and the sixth transistor T6 may be a p-channel metal-oxide-semiconductor-field-effect transistor(s) (“MOSFET(s)”; “PMOS(s)”), and the remaining one(s) may be n-channel MOSFET(s) (“NMOS(s)”). In an embodiment, the fifth transistor T5 may be a PMOS, and the first transistor T1, the second transistor T2, the third transistor T3, the fourth transistor T4, and the sixth transistor T6 may be NMOSs, for example. In an alternative embodiment, the fifth transistor T5 and the sixth transistor T6 may be PMOSs, and the first transistor T1, the second transistor T2, the third transistor T3, and the fourth transistor T4 may be NMOSs. In an alternative embodiment, all transistors may be NMOSs or all transistors may be PMOSs.

At least one of the transistors may be a transistor having a low-temperature polycrystalline silicon (“LTPS”) semiconductor layer, and the remaining ones may be transistors having an oxide semiconductor layer. In an embodiment, the fifth transistor T5 may include a semiconductor layer including polycrystalline silicon with relatively high reliability, and each of the remaining transistors may include an oxide semiconductor layer with relatively high carrier mobility and relatively low leakage current, for example. Hereinbelow, an embodiment is mainly described in which the fifth transistor T5 is a PMOS including a silicon semiconductor, and the remaining transistors are NMOSs including an oxide semiconductor.

The pixel circuit PC may be electrically connected a gate line which transmits a signal to a gate electrode of each of the transistors. In an embodiment, the pixel circuit PC may be connected to a scan line GWL which transmits a scan signal GW, an initialization gate line GBL which transmits an initialization signal GB, a reference gate line GRL which transmits a reference signal GR, a first emission control line EML which transmits a first emission control signal EM, a second emission control line EMBL which transmits a second emission control signal EMB, and the data line DL which transmits a data signal DATA, for example. In addition, the pixel circuit PC may be connected to a driving voltage line PL which transfers a driving voltage ELVDD, a reference voltage line VRL which transfers a reference voltage VREF, and an initialization voltage line VL which transfers an initialization voltage VINT.

A first transistor T1, which is a driving transistor, may be electrically connected between a driving voltage line PL and a second node N2. The first transistor T1 may include a first gate electrode G1 connected to a first node N1, a first terminal electrically connected to a driving voltage line PL, and a second terminal connected to a second node N2. The first terminal may be a drain D and the second terminal may be a source S. The first terminal of the first transistor T1 may be connected to the driving voltage line PL via the fifth transistor T5, and the second terminal of the first transistor T1 may be connected to a pixel electrode of the light-emitting element LED via the sixth transistor T6. The first transistor T1 may receive the data signal DATA in response to a switching operation of the second transistor T2 and control an amount of current of a driving current Id flowing to the light-emitting element LED.

The second transistor T2, which is a data writing transistor, may be electrically connected between the data line DL and the first node N1. The second transistor T2 may include a gate electrode connected to the scan line GWL, a first terminal connected to the data line DL, and a second terminal connected to the first node N1. The second transistor T2 may be turned on according to the scan signal GW received via the scan line GWL to electrically connect the data line DL and the first node N1, and may transfer the data signal DATA received via the data line DL to the first node N1.

The third transistor T3, which is the first initialization transistor, may be electrically connected between the first node N1 and the reference voltage line VRL. The third transistor T3 may include a gate electrode connected to the reference gate line GRL, a first terminal connected to the first node N1, and a second terminal connected to the reference voltage line VRL. The third transistor T3 may be turned on according to the reference signal GR received via the reference gate line GRL and may transfer the reference voltage VREF received via the reference voltage line VRL to the first node N1.

The fourth transistor T4, which is a second initialization transistor, may be electrically connected between the first transistor T1 and the initialization voltage line VL. Specifically, the fourth transistor T4 may be electrically connected between the sixth transistor T6 which will be described later and the initialization voltage line VL. The fourth transistor T4 may include a gate electrode connected to the initialization gate line GBL, a first terminal connected to a second terminal of the sixth transistor T6 and the light-emitting element LED, and a second terminal connected to the initialization voltage line VL. The fourth transistor T4 may be turned on according to the initialization signal GB received via the initialization gate line GBL and may transfer the initialization voltage VINT received via the initialization voltage line VL to the pixel electrode of the light-emitting element LED. That is, the fourth transistor T4 may initialize the electric potential of the pixel electrode of the light-emitting element LED to the initialization voltage VINT.

The fifth transistor T5, which is an emission control transistor, may be electrically connected between the driving voltage line PL and the first transistor T1. The fifth transistor T5 may include a gate electrode connected to the first emission control line EML, a first terminal connected to the driving voltage line PL, and a second terminal connected to the first terminal of the first transistor T1. The fifth transistor T5 may be turned on or off according to the first emission control signal EM received via the first emission control line EML.

The sixth transistor T6, which is an operation control transistor, may be connected between the first transistor T1 and the light-emitting element LED. The sixth transistor T6 may include a gate electrode connected to the second emission control line EMBL, a first terminal connected to the second node N2, and a second terminal connected to the light-emitting element LED. The sixth transistor T6 may be turned on according to the second emission control signal EMB received via the second emission control line EMBL and may electrically connect the second node N2 and the pixel electrode of the light-emitting element LED.

In FIG. 9, the fifth transistor T5 is operated in response to the first emission control signal EM and the sixth transistor T6 is operated in response to the second emission control signal EMB. However, the disclosure is not limited thereto. In an embodiment, the fifth transistor T5 and the sixth transistor T6 may be operated in response to the same emission control signal, for example.

In an embodiment, the reference signal GR may be substantially synchronized with the scan signal GW of the pixel circuit PC in the previous row. The initialization signal GB may be substantially synchronized with the scan signal GW. In another embodiment, the initialization signal GB may be substantially synchronized with the scan signal GW of the pixel circuit PC in the next row or the reference signal GR.

The storage capacitor Cst may be connected between the first node N1 and the second node N2. In other words, the pixel circuit PC in an embodiment may be a source follower-type circuit, in which the storage capacitor Cst is connected between the first node N1 and the second node N2. A first storage electrode CEs1 of the storage capacitor Cst may be connected to the first node N1 and a second storage electrode CEs2 may be connected to the second node N2. The storage capacitor Cst may store a threshold voltage of the first transistor T1 and a voltage corresponding to the data signal DATA.

The hold capacitor Chd may be connected between the driving voltage line PL and the second node N2. A first hold electrode CEh1 of the hold capacitor Chd may be connected to the driving voltage line PL and a second hold electrode CEh2 may be connected to the second node N2. The hold capacitor Chd may ensure that a voltage at the second node N2 of the first transistor T1 does not fluctuate and has a constant voltage when a surrounding signal fluctuates.

The light-emitting element LED may include the pixel electrode electrically connected to the second node N2 via the sixth transistor T6 and the common electrode above the pixel electrode, and the common electrode may receive the common voltage ELVSS. The common electrode may be unitary as a single body throughout a plurality of light-emitting element LED.

In FIG. 9, the pixel circuit PC includes six transistors and two capacitors. However, the disclosure is not limited thereto. In an embodiment, the pixel circuit PC may include five transistors and two capacitors, for example. The pixel circuit PC may include seven transistors and one or two capacitors.

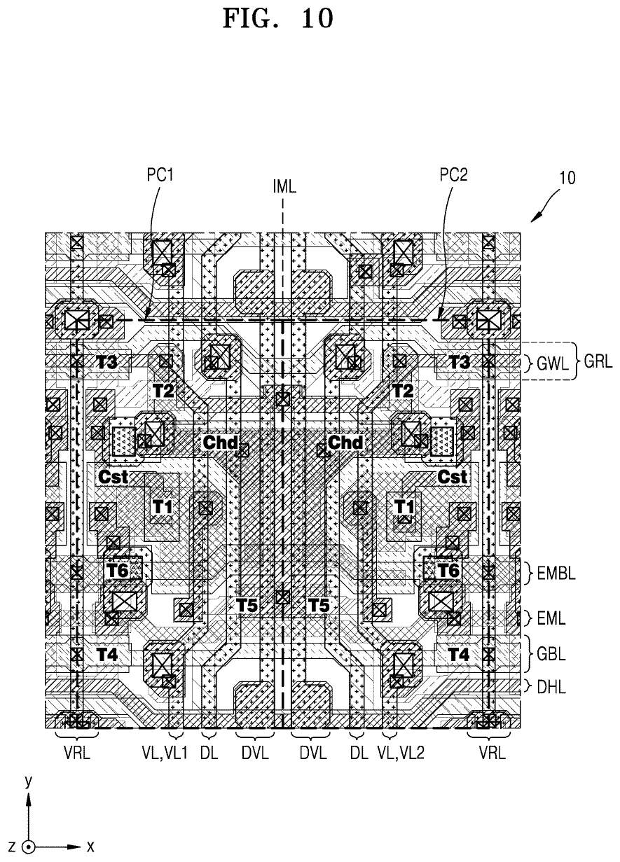

FIG. 10 is a layout diagram schematically showing the locations of transistors, capacitors, etc. in pixels arranged in the display area of the display panel 10 of FIG. 6. In FIG. 10, for convenience of description, two pixel circuits, e.g., a first pixel circuit PC1 and a second pixel circuit PC2, disposed in the same row in the first direction (x-axis direction) are shown. However, the disclosure is not limited thereto. In addition, FIG. 10 shows that the first pixel circuit PC1 and the second pixel circuit PC2 are approximately mirror-symmetrical with respect to an imaginary line IML extending in the second direction (y-axis direction) between the first pixel circuit PC1 and the second pixel circuit PC2. However, the disclosure is not limited thereto. The display panel 10 may include a plurality of pixel circuits disposed in rows in the first direction (the x-axis direction) and columns in the second direction (the y-axis direction).

As shown in FIG. 10, each of the first pixel circuit PC1 and the second pixel circuit PC2 may include transistors and capacitors. In an embodiment, each of the first pixel circuit PC1 and the second pixel circuit PC2 may include the first transistor T1, the second transistor T2, the third transistor T3, the fourth transistor T4, the fifth transistor T5, the sixth transistor T6, the storage capacitor Cst, and the hold capacitor Chd described above with reference to FIG. 9, for example.

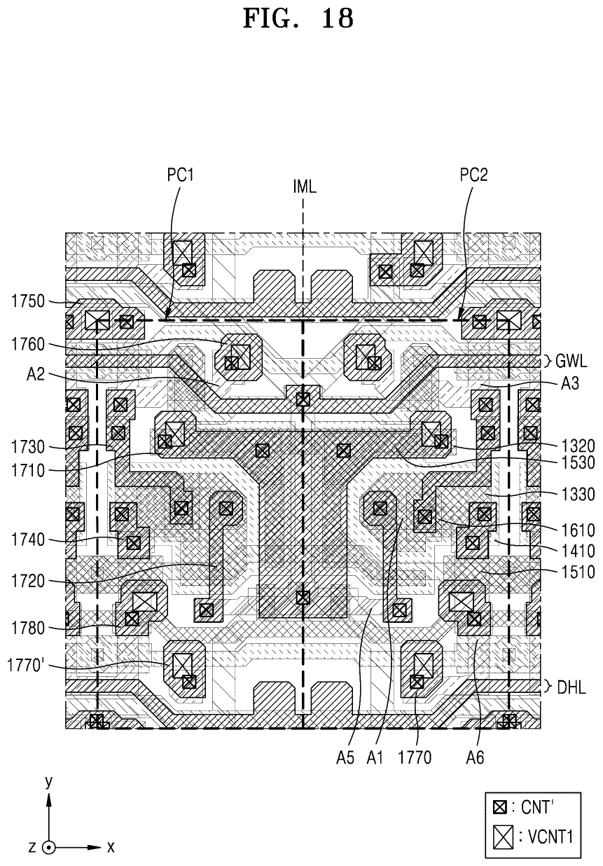

Gate lines electrically connected to the first pixel circuit PC1 and the second pixel circuit PC2, e.g., the scan line GWL, the initialization gate line GBL, the reference gate line GRL, the first emission control line EML, and the second emission control line EMBL, may extend approximately in the first direction (the x-axis direction). In addition to this, the horizontal connection line (DHL, refer to FIG. 18) may also extend approximately in the first direction (x-axis direction).

The first pixel circuit PC1 may be electrically connected to the data line DL passing through the first pixel circuit PC1, and the second pixel circuit PC2 may be electrically connected to the data line DL passing through the second pixel circuit PC2. The data line DL may extend approximately along the second direction (y-axis direction). The data line DL electrically connected to the first pixel circuit PC1 and the data line DL electrically connected to the second pixel circuit PC2 may be symmetrical with respect to the aforementioned imaginary line IML.

The first pixel circuit PC1 may be electrically connected to voltage lines passing through the first pixel circuit PC1, such as the reference voltage line VRL and the initialization voltage line VL. The second pixel circuit PC2 may be electrically connected to voltage lines passing through the second pixel circuit PC2, such as the reference voltage line VRL and the initialization voltage line VL. The reference voltage line VRL and the initialization voltage line VL electrically connected to the first pixel circuit PC1 may be symmetrical with the reference voltage line VRL and the initialization voltage line VL electrically connected to the second pixel circuit PC2, with respect to the aforementioned imaginary line IML. The reference voltage line VRL and the initialization voltage line VL may each extend approximately along the second direction (y-axis direction). For convenience, the initialization voltage line VL passing through the first pixel circuit PC1 may be also referred to as the first initialization voltage line VL1, and the initialization voltage line VL passing through the second pixel circuit PC2 may be also referred to as the second initialization voltage line VL2. That is, the first initialization voltage lines VL1 and the second initialization voltage lines VL2 extending in the second direction (y-axis direction) may be arranged alternately along the first direction (x-axis direction).

The vertical connecting line DVL may also extend along the second direction (y-axis direction). The vertical connection line DVL may correspond to a part of the data transfer line DTL described with reference to FIG. 7 or FIG. 8, e.g., any one of the first vertical connection line DVL1, the second vertical connection line DVL2, the third vertical connection line DVL3, the first additional vertical connection line DVL1′, the second additional vertical connection line DVL2′, and the third additional vertical connection line DVL3′. In this case, the vertical connection line DVL may be electrically connected to the data line DL of the pixel circuits arranged in a different column from the first pixel circuit PC1 and the second pixel circuit PC2 shown in FIG. 10, so as to transfer data signals to the pixel circuits arranged in the different column. In an alternative embodiment, when the first pixel circuit PC1 or the second pixel circuit PC2 is not disposed near a corner of the display area DA as shown in FIG. 7 or FIG. 8, but rather in the center of the display area DA, the vertical connection line DVL may be a dummy line to which no electrical signal is applied, or may be a dummy line to which a constant electrical signal is applied.

For reference, the horizontal connection line DHL which will be described later may correspond to a part of the data transfer line DTL described with reference to FIG. 7 or FIG. 8, e.g., one of the first horizontal connection line DHL1, the second horizontal connection line DHL2, or the third horizontal connection line DHL3. In this case, the horizontal connection line DHL may be electrically connected to the data line DL of the pixel circuits arranged in a different column from the first pixel circuit PC1 and the second pixel circuit PC2 shown in FIG. 10, along with the vertical connection line DVL, so as to transfer data signals to the pixel circuits arranged in the different column. In an alternative embodiment, when the first pixel circuit PC1 or the second pixel circuit PC2 is not disposed near a corner of the display area DA as shown in FIG. 7 or FIG. 8, but rather in the center of the display area DA, the horizontal connection line DHL may be a dummy line to which no electrical signal is applied, or may be a dummy line to which a constant electrical signal is applied.

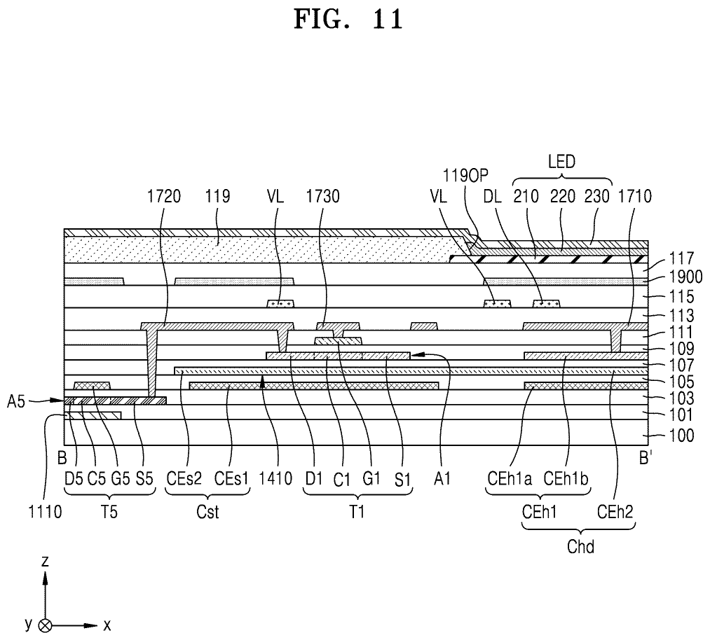

FIG. 11 is a cross-sectional view schematically illustrating a cross-section taken along line B-B′ of FIG. 6. As shown in FIG. 11, the display panel 10 may include a circuit layer including transistors and capacitors on the substrate 100, and a display element layer disposed on the circuit layer described above and including the light-emitting element LED. The circuit layer may include the transistors and the capacitors as described above with reference to FIGS. 9 and 10. FIG. 11 shows the first transistor T1, the fifth transistor T5, the storage capacitor Cst, and the hold capacitor Chd.

A lower metal layer 1110 may be disposed over the substrate 100. The lower metal layer 1110 may include one or more materials selected from among aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu). In an embodiment, the lower metal layer 1110 may have a single-layer including Mo, a double-layer structure in which a Mo layer and a Ti layer are stacked, or a triple-layer structure in which a Ti layer, an Al layer, and a Ti layer are stacked, for example.

The lower metal layer 1110 may have a voltage level of a constant voltage. In an embodiment, the lower metal layer 1110 may have the same voltage level as the driving voltage line PL described above with reference to FIG. 9, for example. That is, the driving voltage ELVDD may be applied to the lower metal layer 1110. For this, the lower metal layer 1110 may be electrically connected to a part of the driving voltage line PL or the first power supply line 15 in the peripheral area PA, for example. The lower metal layer 1110 may block at least a part of light proceeding to a fifth semiconductor layer A5 of the fifth transistor T5 and may shield the fifth transistor T5 from external electrostatic discharge.

A buffer layer 101 may be disposed over the lower metal layer 1110. The buffer layer 101 may be an inorganic insulating layer including an inorganic insulating material such as silicon oxide, silicon nitride and/or silicon oxynitride. This buffer layer 101 may have a single-layer structure or a multi-layer structure.

A silicon semiconductor layer may be disposed over the buffer layer 101. FIG. 11 shows that the fifth transistor T5 includes the silicon semiconductor layer. That is, FIG. 11 shows that the fifth semiconductor layer A5 of the fifth transistor T5 is disposed over the buffer layer 101. The fifth semiconductor layer A5 may include a channel region C5 and conductive regions S5 and D5 arranged at opposite sides of the channel region C5. The conductive regions S5 and D5 may be doped with impurities or may be treated with plasma, to be conductive. One of the conductive regions S5 and D5 of the fifth semiconductor layer A5 may be a source region and a remaining (the other) one may be a drain region.

A first gate insulating layer 103 may be disposed over the buffer layer 101 to cover the fifth semiconductor layer A5. The first gate insulating layer 103 may be an inorganic insulating layer including an inorganic insulating material such as silicon oxide, silicon nitride, and/or silicon oxynitride. The first gate insulating layer 103 may have a single-layer structure or a multi-layer structure.

A fifth gate electrode G5 may be disposed over the first gate insulating layer 103. The fifth gate electrode G5 may overlap the channel region C5 of the fifth semiconductor layer A5. In addition to the fifth gate electrode G5, the first storage electrode CEs1 of the storage capacitor Cst and a sub-layer of the first hold electrode CEh1 of the hold capacitor Chd, e.g., a first lower hold electrode CEh1a, may be disposed on the first gate insulating layer 103.

The fifth gate electrode G5, the first storage electrode CEs1 of the storage capacitor Cst, and the first lower hold electrode CEh1a of the hold capacitor Chd may include the same material as each other. The fifth gate electrode G5, the first storage electrode CEs1 of the storage capacitor Cst, and the first lower hold electrode CEh1a of the hold capacitor Chd may include Al, Pt, Pd, Ag, Mg, Au, Ni, Nd, Ir, Cr, Li, Ca, Mo, Ti, W, and/or Cu, and may have a single-layer structure or multi-layer structure. In an embodiment, the fifth gate electrode G5, the first storage electrode CEs1 of the storage capacitor Cst, and the first lower hold electrode CEh1a of the hold capacitor Chd may have the single-layer structure including molybdenum or the multi-layer structure of molybdenum/aluminum/molybdenum, for example.

A second gate insulating layer 105 may be disposed over the first gate insulating layer 103 to cover the fifth gate electrode G5, the first storage electrode CEs1 of the storage capacitor Cst, and the first lower hold electrode CEh1a of the hold capacitor Chd. The second gate insulating layer 105 may be an inorganic insulating layer including an inorganic insulating material such as silicon oxide, silicon nitride, and/or silicon oxynitride. The second gate insulating layer 105 may have a single-layer structure or a multi-layer structure. When desired, the second gate insulating layer 105 may include a material different from a material of the first gate insulating layer 103. In an embodiment, the first gate insulating layer 103 may include silicon oxide and the second gate insulating layer 105 may include silicon nitride, for example.

A conductive layer 1410 (hereinafter, also referred to as “fifth conductive layer”) may be disposed over the second gate insulating layer 105. The fifth conductive layer 1410 may overlap the first storage electrode CEs1 of the storage capacitor Cst and the first lower hold electrode CEh1a of the hold capacitor Chd. The fifth conductive layer 1410 may include a second storage electrode CEs2 of the storage capacitor Cst and the second hold electrode CEh2 of the hold capacitor Chd. That is, a portion of the fifth conductive layer 1410 may be the second storage electrode CEs2 of the capacitor Cst, and another portion of the fifth conductive layer 1410 may be the second hold electrode CEh2 of the hold capacitor Chd. In this way, the second storage electrode CEs2 of the capacitor Cst and the second hold electrode CEh2 of the hold capacitor Chd may be unitary as a single body.

The fifth conductive layer 1410 may include Al, Pt, Pd, Ag, Mg, Au, Nl, Nd, Ir, Cr, Li, Ca, Mo, Ti, W, and/or Cu, and may have a single-layer structure or a multi-layer structure including the materials described above. In an embodiment, the fifth conductive layer 1410 may have the single-layer structure including molybdenum or the multi-layer structure of molybdenum/aluminum/molybdenum, for example.

A first inter-insulating layer 107 may be disposed over the second gate insulating layer 105 to cover the fifth conductive layer 1410. The first inter-insulating layer 107 may be an inorganic insulating layer including an inorganic insulating material such as silicon oxide, silicon nitride, and/or silicon oxynitride. The first inter-insulating layer 107 may have a single-layer structure or a multi-layer structure. In an embodiment, the first inter-insulating layer 107 may have a stack structure of a layer including silicon oxide and a layer including silicon nitride.

A first semiconductor layer A1 of the first transistor T1 and a first upper hold electrode CEh1b of the hold capacitor Chd may be disposed over the first inter-insulating layer 107. The first semiconductor layer A1 of the first transistor T1 and the first upper hold electrode CEh1b of the hold capacitor Chd may include the same material as each other. Specifically, the first semiconductor layer A1 of the first transistor T1 and the first upper hold electrode CEh1b of the hold capacitor Chd may include an oxide semiconductor. The oxide semiconductor may be an oxide semiconductor including at least one element selected from the group consisting of indium (In), gallium (Ga), stannum (Sn), zirconium (Zr), vanadium (V), hafnium (Hf), cadmium (“CD”), germanium (Ge), chromium (Cr), titanium (Ti), aluminum (Al), cesium (Cs), cerium (Ce), and zinc (Zn). In an embodiment, the oxide semiconductor may include InSnZnO (“ITZO”) or InGaZnO (“IGZO”), for example.

The first semiconductor layer A1 may include a channel region C1 and conductive regions S1 and D1 arranged at opposite sides of the channel region C1. One of the conductive regions S1, D1 of the first semiconductor layer A1 may be a source region and a remaining (the other) one may be a drain region. The first semiconductor layer A1 may be disposed in a layer different from a layer in which the fifth semiconductor layer A5 described above is disposed. A vertical distance from the substrate 100 and the first semiconductor layer A1 may be greater than a vertical distance from the substrate 100 to the fifth semiconductor layer A5.

The first upper hold electrode CEh1b of the hold capacitor Chd may overlap the fifth conductive layer 1410 and the first lower hold electrode CEh1a of the hold capacitor Chd below the fifth conductive layer 1410. The first upper hold electrode CEh1b of the hold capacitor Chd may be electrically connected to the first lower hold electrode CEh1a.

A third gate insulating layer 109 may be disposed over the first inter-insulating layer 107 to cover the first semiconductor layer A1 and the first upper hold electrode CEh1b of the hold capacitor Chd. The third gate insulating layer 109 may be an inorganic insulating layer including an inorganic insulating material such as silicon oxide, silicon nitride, and/or silicon oxynitride. The third gate insulating layer 109 may have a single-layer structure or a multi-layer structure. In an embodiment, the third gate insulating layer 109 may have the single-layer structure including silicon oxide.

FIG. 11 shows that the third gate insulating layer 109 contacts an upper surface of the first inter-insulating layer 107 via a side surface of the first semiconductor layer A1. However, the disclosure is not limited thereto. In an embodiment, the third gate insulating layer 109 may be formed to have substantially the same pattern and/or substantially the same width as a first gate electrode G1 that will be described below, for example. That is, after forming an insulating layer for forming the third gate insulating layer 109 and forming a conductive layer for forming the first gate electrode G1 on the insulating layer, the insulating layer and the conductive layer may be patterned simultaneously to have the same shape, such that the third gate insulating layer 109 and the first gate electrode G1 having the same shape are formed. In this case, the third gate insulating layer 109 may not contact the upper surface of the first inter-insulating layer 107.

A first gate electrode G1 may be disposed over the third gate insulating layer 109. The first gate electrode G1 may overlap the channel region C1 of the first semiconductor layer A1. The first gate electrode G1 may include Al, Pt, Pd, Ag, Mg, Au, Ni, Nd, Ir, Cr, Li, Ca, MO, Ti, W, and/or Cu, and may have a single-layer structure or a multi-layer structure including the materials described above. In an embodiment, the first gate electrode G1 may have a triple-layer structure of a Ti layer, an Al layer, and another Ti layer, for example.

A second inter-insulating layer 111 may be disposed to cover the first gate electrode. The second inter-insulating layer 111 may be an inorganic insulating layer including an inorganic insulating material such as silicon oxide, silicon nitride, and/or silicon oxynitride. The second inter-insulating layer 111 may have a single-layer structure or a multi-layer structure. In an embodiment, the second inter-insulating layer 111 may have a stack structure of a layer including silicon oxide and a layer including silicon oxynitride, for example.

A first connection electrode 1710, a second connection electrode 1720, and a third connection electrode 1730 may be disposed over the second inter-insulating layer 111. The first connection electrode 1710, the second connection electrode 1720, and the third connection electrode 1730 may include the same material as each other. That is, the first connection electrode 1710, the second connection electrode 1720, and the third connection electrode 1730 may be formed simultaneously using the same material as each other. The first connection electrode 1710, the second connection electrode 1720, and the third connection electrode 1730 may include Al, Pt, Pd, Ag, Mg, Au, Ni, Nd, Ir, Cr, Li, Ca, Mo, Ti, W, and/or Cu, and may have a single-layer structure or a multi-layer structure including the materials described above. In an embodiment, the first connection electrode 1710, the second connection electrode 1720, and the third connection electrode 1730 may have a triple-layer structure of a Ti layer, an Al layer, and another Ti layer, for example.

A first organic insulating layer 113 may be disposed over the second inter-insulating layer 111 to cover the first connection electrode 1710, the second connection electrode 1720, and the third connection electrode 1730. The first organic insulating layer 113 may include an organic insulating material such as acryl, benzocyclobutene (“BCB”), polyimide, or hexamethyldisiloxane (“HMDSO”).

The data line DL and the initialization voltage line VL may be disposed over the first organic insulating layer 113. The data line DL and the initialization voltage line VL may include Al, Pt, Pd, Ag, Mg, Au, Ni, Nd, Ir, Cr, Li, Ca, MO, Ti, W, and/or Cu, and may have a single-layer structure or a multi-layer structure including the materials described above. In an embodiment, the data line DL and the initialization voltage line VL may have a triple-layer structure of a Ti layer, an Al layer, and another Ti layer, for example.

A second organic insulating layer 115 may be disposed over the first organic insulating layer 113 to cover the data line DL and the initialization voltage line VL. The second organic insulating layer 115 may include an organic insulating material such as acryl, BCB, polyimide, or HMDSO.

A voltage layer 1900 may be disposed on the second organic insulating layer 115. The voltage layer 1900 may have a voltage level of the driving voltage line PL. The voltage layer 1900 may include Al, Pt, Pd, Ag, Mg, Au, Ni, Nd, Ir, Cr, Li, Ca, Mo, Ti, W, and/or Cu, and may have a single-layer structure or a multi-layer structure including the materials described above. In an embodiment, the voltage layer 1900 may have a triple-layer structure of a Ti layer, an Al layer, and another Ti layer, for example.

A third organic insulating layer 117 may be disposed over the second organic insulating layer 115 to cover the voltage layer 1900. The third organic insulating layer 117 may include an organic insulating material such as acryl, BCB, polyimide, or HMDSO.

The light-emitting element LED may be disposed over the third organic insulating layer 117. The light-emitting element LED may include a pixel electrode 210, an intermediate layer 220, and a common electrode 230, over the third organic insulating layer 117.

The pixel electrode 210 may be a (semi) transparent electrode or a reflective electrode. In an embodiment, the pixel electrode 210 may include a reflective layer including Ag, Mg, Al, Pt, Pd, Au, Ni, Nd, Ir, Cr or any combinations thereof, and a transparent or semitransparent electrode layer disposed on the reflective layer, for example. The transparent or semitransparent electrode layer may include at least one selected from the group consisting of indium tin oxide (“ITO”), indium zinc oxide (“IZO”), zinc oxide (ZnOₓ: ZnO or ZnO₂), indium oxide (In₂O₃), indium gallium oxide (“IGO”), and aluminum zinc oxide (“AZO”). In an embodiment, the pixel electrode 210 may have a triple-layer structure of ITO/Ag/ITO, for example.

A pixel definition layer 119 may be disposed over the third organic insulating layer 117 to cover an edge of the pixel electrode 210. The pixel definition layer 119 may prevent arcs or the like from occurring at the edge of the pixel electrode 210 by covering the edge of the pixel electrode 210 and increasing the distance between the edge of the pixel electrode 210 and the common electrode 230 above the edge of the pixel electrode 210. That is, the pixel definition layer 119 defines an opening to expose a central portion of the pixel electrode 210. The pixel definition layer 119 may include one or more organic insulating materials selected from the group consisting of polyimide, polyamide, acrylic resin, benzocyclobutene, and phenol resin, and may be formed by a method such as spin coating.

An intermediate layer 220 of the light-emitting element LED may include an emission layer and at least a portion of the intermediate layer 220 may be disposed in the opening defined in the pixel definition layer 119. A light-emitting area of the light-emitting element LED may be defined by the opening. The intermediate layer 220 may include the emission layer. The emission layer may include an organic material including a fluorescent or phosphorescent material that emits red, green, blue, or white light. The emission layer may include a low-molecular weight organic material or a polymer organic material, and functional layers, such as a hole transport layer (“HTL”), a hole injection layer (“HIL”), an electron transport layer (“ETL”), and an electron injection layer (“EIL”), may be optionally arranged below and above the emission layer.

In an alternative embodiment, the intermediate layer 220 may include a first stack including an emission layer and a functional layer, a second stack including an emission layer and a functional layer, and a charge generation layer between the first stack and the second stack. The charge generation layer may include a negative charge generation layer and a positive charge generation layer. The emission efficiency of a tandem light-emitting element LED having a plurality of emission layers may be further increased by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

The emission layer may have a patterned shape corresponding to the pixel electrode 210. Each of layers other than the emission layer included in the intermediate layer may be unitary as a single body throughout the plurality of pixel electrodes 210, and may be modified in various ways.

The common electrode 230 may be a light-transmitting electrode or a reflective electrode. In an embodiment, the common electrode 230 may be a transparent or semitransparent electrode and may include a metal thin film with a relatively small work function including Li, Ca, Al, Ag, Mg or any combinations thereof (e.g., LiF), for example. Additionally, the common electrode 230 may further include a transparent conductive oxide (“TCO”) film such as ITO, IZO, ZnO, ZnO₂ or In₂O₃ disposed on the metal thin film.

The common electrode 230 may be unitary as a single body throughout the display area DA to cover the display area DA, and may be disposed over the intermediate layer 220 and the pixel definition layer 119. That is, each of the pixel electrodes 210 is arranged to correspond to each light-emitting element LED, and the common electrode 230 may be unitary as a single body to correspond to a plurality of light-emitting elements LED. The plurality of light-emitting elements LED may share the common electrode 230, and a stacked structure of the pixel electrode 210, the intermediate layer 220, and the common electrode 230 may correspond to the light-emitting element LED.

When desired, an encapsulating layer may be disposed over the light-emitting elements LED. The encapsulating layer may include a first inorganic encapsulating layer, a second inorganic encapsulating layer, and an organic encapsulating layer therebetween.

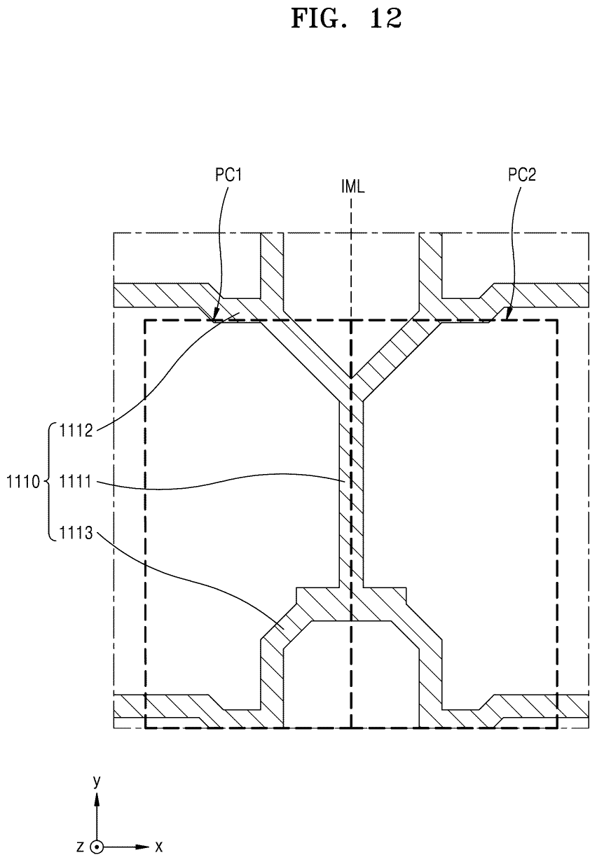

FIGS. 12 to 20 are layout diagrams schematically illustrating, layer by layer, components, such as transistors, capacitors, etc. of the display panel 10 illustrated in FIG. 10. For convenience of explanation, the first pixel circuit PC1 is described as being disposed in the i^{th} row and j^{th} column, and the second pixel circuit PC2 is described as being disposed in the i^{th} row and (j+1)^{th} column. Here, i and j are natural numbers.

As shown in FIG. 12, the lower metal layer 1110 may be disposed over the substrate 100 (refer to FIG. 11). The lower metal layer 1110 may include a first portion 1111 extending in the second direction (y-axis direction) and a second portion 1112 and a third portion 1113 extended to the first portion 1111 and extending generally in the first direction (x-axis direction).

The first portion 1111 of the lower metal layer 1110 may be disposed on the imaginary line IML between the first pixel circuit PC1 and the second pixel circuit PC2. The second portion 1112 and the third portion 1113 of the lower metal layer 1110 may be on opposite sides with the first portion 1111 therebetween. The second portion 1112 and the third portion 1113 may extend generally in the first direction (x-axis direction), and may be locally bent. The lower metal layer 1110 may include a metallic material as described above.

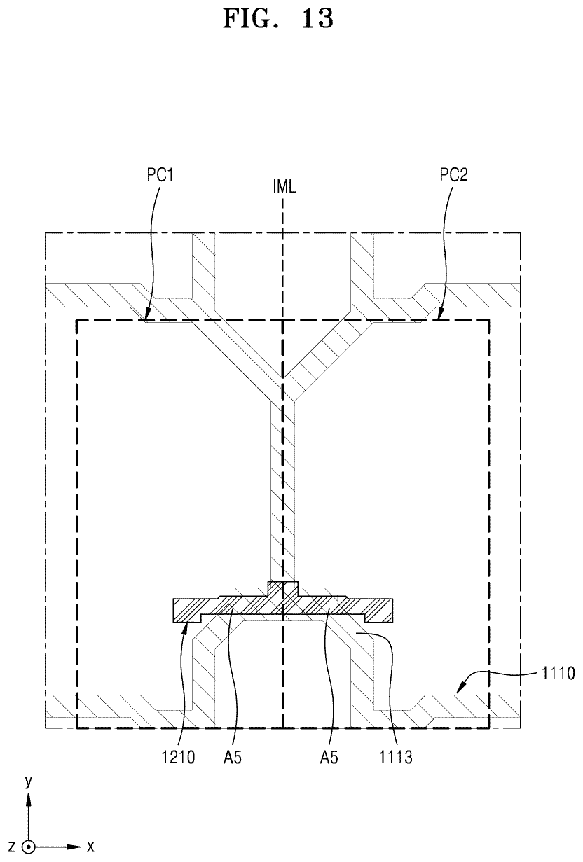

The buffer layer 101 may be formed on the lower metal layer 1110 shown in FIG. 12, and the silicon semiconductor layer 1210 may be formed on the buffer layer 101 as shown in FIG. 13. The silicon semiconductor layer 1210 may include silicon, e.g., polysilicon.

As shown in FIG. 13, the silicon semiconductor layer 1210 may have an isolated shape and may extend approximately in the first direction (x-axis direction). The silicon semiconductor layer 1210 may cross the imaginary line IML between the first pixel circuit PC1 and the second pixel circuit PC2. The silicon semiconductor layer 1210 may include the fifth semiconductor layer A5 of each of the first pixel circuit PC1 and the second pixel circuit PC2. In other words, the fifth semiconductor layer A5 of the first pixel circuit PC1 and the fifth semiconductor layer A5 of the second pixel circuit PC2 may be unitary as a single body.

The silicon semiconductor layer 1210 may overlap the lower metal layer 1110. In an embodiment, the silicon semiconductor layer 1210 may overlap the third portion 1113 of the lower metal layer 1110, for example. Specifically, The fifth semiconductor layer A5 of each of the first pixel circuit PC1 and the second pixel circuit PC2 may overlap the third portion 1113 of the lower metal layer 1110.

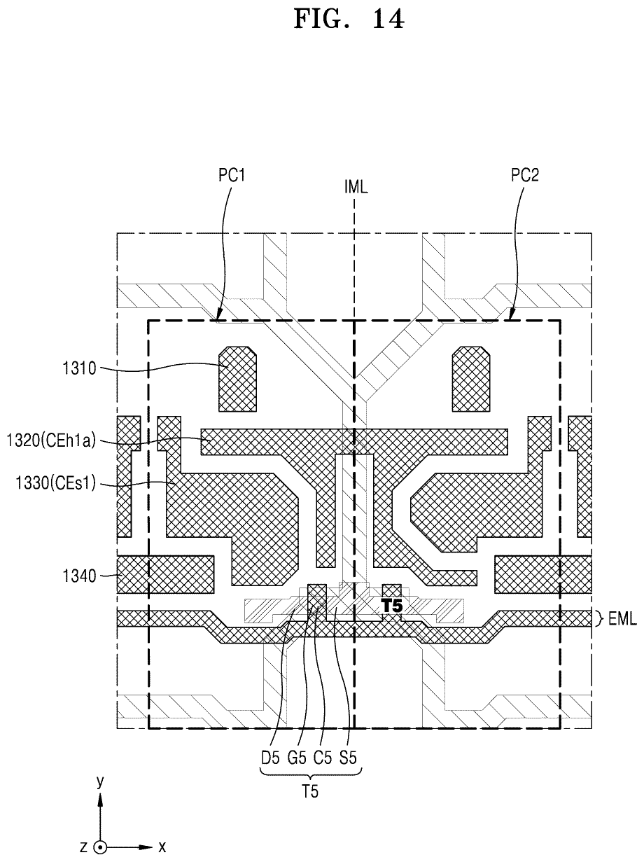

The first gate insulating layer 103 (refer to FIG. 11) may be formed over the structure shown in FIG. 13, and a gate line and a conductive layer shown in FIG. 14 may be formed on the first gate insulating layer 103. FIG. 14 shows that the first emission control line EML, a first conductive layer 1310, a second conductive layer 1320, a third conductive layer 1330, and a fourth conductive layer 1340 are formed on the first gate insulating layer 103.

As shown in FIG. 14, the first emission control line EML, the first conductive layer 1310, the second conductive layer 1320, the third conductive layer 1330, and the fourth conductive layer 1340 may be spaced apart from each other. The first emission control line EML, the first conductive layer 1310, the second conductive layer 1320, the third conductive layer 1330, and the fourth conductive layer 1340 may include Al, Pt, Pd, Ag, Mg, Au, Ni, Nd, Ir, Cr, Li, Ca, Mo, Ti, W, and/or Cu, and may have a single-layer structure or a multi-layer structure including the materials described above.

The first emission control line EML may extend in the first direction (x-axis direction) to pass through the first pixel circuit PC1 and the second pixel circuit PC2. The first emission control line EML may pass through pixel circuits arranged in the same row as the first pixel circuit PC1 and the second pixel circuit PC2.

The first emission control line EML may include the fifth gate electrode G5 of the fifth transistor T5 of each of the first pixel circuit PC1 and the second pixel circuit PC2. Part of the first emission control line EML may protrude to overlap the fifth semiconductor layer A5 and the fifth transistor T5, and the protruding part of the first emission control line EML may correspond to the fifth gate electrode G5 of the fifth transistor T5. The fifth semiconductor layer A5 of the fifth transistor T5 may include the channel region C5 overlapping the fifth gate electrode G5 and the conductive regions S5 and D5. The conductive regions S5 and D5 may be doped with impurities or may be treated with plasma, and may be disposed at opposite sides of the channel region C5. One of the conductive regions S5 and D5 may be the source region and a remaining (the other) one may be the drain region. The source region and drain region may correspond to a source electrode and a drain electrode, respectively. Positions of the source region and the drain region may be interchanged depending on the properties of the transistor.

Each of the first conductive layer 1310 and the third conductive layer 1330 may have an isolated shape. The second conductive layer 1320 may also have an isolated shape, but the second conductive layer 1320 in the first pixel circuit PC1 and the second conductive layer 1320 in the second pixel circuit PC2 may be unitary as a single body. The fourth conductive layer 1340 may also have an isolated shape, but the fourth conductive layer 1340 in the first pixel circuit PC1 and the fourth conductive layer 1340 in a pixel circuit disposed at (j−1)^{th} column may be unitary as a single body, and the fourth conductive layer 1340 in the second pixel circuit PC2 and the fourth conductive layer 1340 in a pixel circuit disposed at (j+2)^{th} column may be unitary as a single body. In the first pixel circuit PC1 and the second pixel circuit PC2, the first conductive layer 1310, the second conductive layer 1320, the third conductive layer 1330, and the fourth conductive layer 1340 may be symmetrical with respect to the aforementioned imaginary line IML.

The second conductive layer 1320 may have an isolated shape and may extend in the first direction (e.g., the x-axis direction) to pass through the first pixel circuit PC1 and the second pixel circuit PC2. The second conductive layer 1320 may cross the imaginary line IML between the first pixel circuit PC1 and the second pixel circuit PC2. The second conductive layer 1320 may include a stem portion extending in the first direction (x-axis direction) and a branch portion branching from the stem portion and protruding in the second direction (y-axis direction). The branch portion of the first pixel circuit PC1 and the branch portion of the second pixel circuit PC2 may be substantially symmetrical to each other with respect to the imaginary line IML between the first pixel circuit PC1 and the second pixel circuit PC2.

The second conductive layer 1320 may include the first lower hold electrode CEh1a, which is a sub-layer of the first hold electrode CEh1 of the hold capacitor Chd. The first lower hold electrode CEh1a of the hold capacitor Chd of the first pixel circuit PC1 and the first lower hold electrode CEh1a of the hold capacitor Chd of the second pixel circuit PC2 may be unitary as a single body.

The third conductive layer 1330 disposed in each of the first pixel circuit PC1 and the second pixel circuit PC2 may include the first storage electrode CEs1 of the storage capacitor Cst.

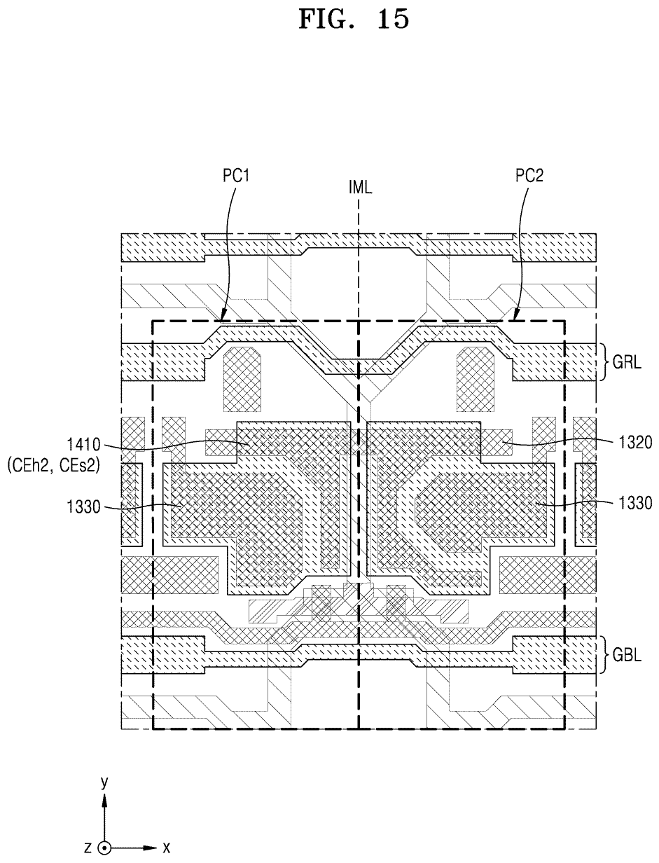

The second gate insulating layer 105 may be formed over the structure shown in FIG. 14, and a gate line and a conductive layer may be formed over the second gate insulating layer 105, as shown in FIG. 15. FIG. 15 shows that the initialization gate line GBL, the reference gate line GRL, and the fifth conductive layer 1410 are formed on a second gate insulating layer 105.

The initialization gate line GBL, the reference gate line GRL, and the fifth conductive layer 1410 may be spaced apart from each other. The initialization gate line GBL, the reference gate line GRL, and the fifth conductive layer 1410 may include Al, Pt, Pd, Ag, Mg, Au, Ni, Nd, Ir, Cr, Li, Ca, Mo, Ti, W, and/or Cu, and may have a single-layer structure or a multi-layer structure including such materials.

Each of the initialization gate line GBL and the reference gate line GRL may extend in the first direction (x-axis direction) to pass through the first pixel circuit PC1 and the second pixel circuit PC2. Each of the initialization gate line GBL and the reference gate line GRL may pass through pixel circuits in the same row as the first pixel circuit PC1 and the second pixel circuit PC2.

The fifth conductive layer 1410 disposed in each of the first pixel circuit PC1 and the second pixel circuit PC2 may have an isolated shape. The fifth conductive layer 1410 in the first pixel circuit PC1 and the fifth conductive layer 1410 in the second pixel circuit PC2 may be spaced apart from each other, and may be substantially symmetrical to each other with respect to the imaginary line IML described above. The fifth conductive layer 1410 may overlap the third conductive layer 1330 of the first pixel circuit PC1, the third conductive layer 1330 of the second pixel circuit PC2, and the second conductive layer 1320 passing through the first pixel circuit PC1 and the second pixel circuit PC2. The fifth conductive layer 1410 may include the second hold electrode CEh2 of the hold capacitor Chd and the second storage electrode CEs2 of the storage capacitor Cst. That is, the second hold electrode CEh2 of the hold capacitor Chd and the second storage electrode CEs2 of the storage capacitor Cst may be unitary as a single body.

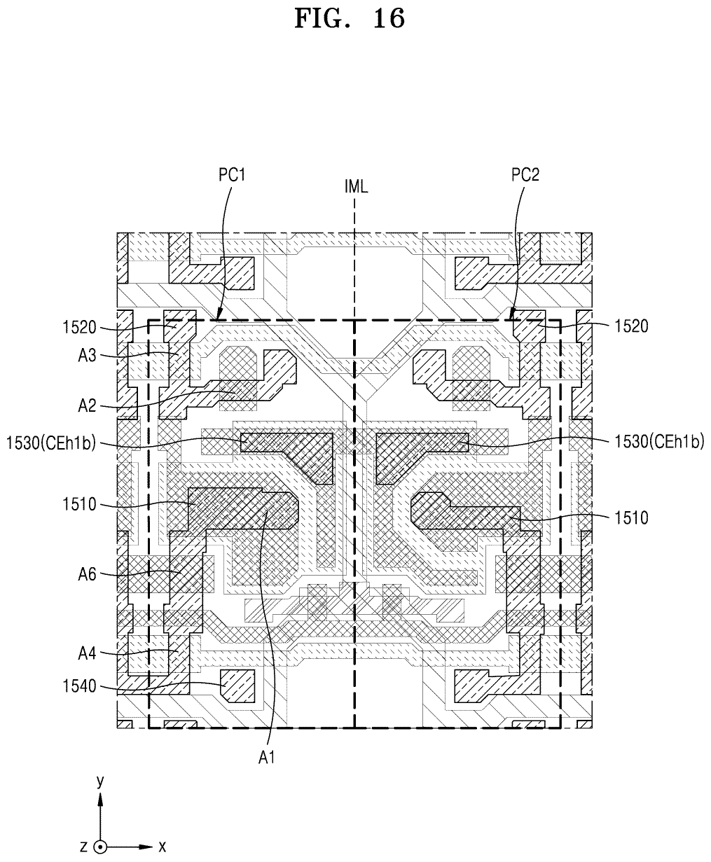

The first inter-insulating layer 107 (refer to FIG. 11) may be formed on the structure shown in FIG. 15, and semiconductor patterns may be formed over the first inter-insulating layer 107, as shown in FIG. 16. FIG. 16 shows that a first oxide semiconductor pattern 1510, a second oxide semiconductor pattern 1520, a third oxide semiconductor pattern 1530, and a fourth oxide semiconductor pattern 1540 are formed on the first inter-insulating layer 107.

As shown in FIG. 16, the first oxide semiconductor pattern 1510, the second oxide semiconductor pattern 1520, the third oxide semiconductor pattern 1530, and the fourth oxide semiconductor pattern 1540 may be spaced apart from each other. Each of the first oxide semiconductor pattern 1510, the second oxide semiconductor pattern 1520, the third oxide semiconductor pattern 1530, and the fourth oxide semiconductor pattern 1540 may include ITZO, IGZO, or the like.

The first oxide semiconductor pattern 1510 of each of the first pixel circuit PC1 and the second pixel circuit PC2 may have an isolated shape. The first oxide semiconductor pattern 1510 may include the first semiconductor layer A1, a fourth semiconductor layer A4, and a sixth semiconductor layer A6. In other words, the first semiconductor layer A1, the fourth semiconductor layer A4, and the sixth semiconductor layer A6 of the first pixel circuit PC1 may be unitary as a single body, and the first semiconductor layer A1, the fourth semiconductor layer A4, and the sixth semiconductor layer A6 of the second pixel circuit PC2 may be unitary as a single body. The first oxide semiconductor pattern 1510 may have a shape that is bent several times.

The first semiconductor layer A1, the fourth semiconductor layer A4, and the sixth semiconductor layer A6 of the first oxide semiconductor pattern 1510 may overlap the fifth conductive layer 1410 and the initialization gate line GBL described above with reference to FIG. 15 and the fourth conductive layer 1340 described above with reference to FIG. 14. That is, the portion of the first oxide semiconductor pattern 1510 overlapping the fifth conductive layer 1410 may be the first semiconductor layer A1, the portion of the first oxide semiconductor pattern 1510 overlapping the initialization gate line GBL may be the fourth semiconductor layer A4, and the portion of the first oxide semiconductor pattern 1510 overlapping the fourth conductive layer may be the sixth semiconductor layer A6.

In the plan view, the shape of the first oxide semiconductor pattern 1510 in the first pixel circuit PC1 and the shape of the first oxide semiconductor pattern 1510 in the second pixel circuit PC2 may be different from each other. The first oxide semiconductor pattern 1510 of the first pixel circuit PC1 and the first oxide semiconductor pattern 1510 in a pixel circuit which is disposed in the same row as the first pixel circuit PC1 and is disposed in a column neighboring the column in which the first pixel circuit PC1 is disposed (e.g., the first oxide semiconductor pattern 1510 in a pixel circuit in the i^{th} row and the (j−1)^{th} column), may be unitary as a single body.

The second oxide semiconductor pattern 1520 in each of the first pixel circuit PC1 and the second pixel circuit PC2 may have an isolated shape. The second oxide semiconductor pattern 1520 may be bent to have an approximately “L” shape. The second oxide semiconductor pattern 1520 of the first pixel circuit PC1 may be symmetrical with the second oxide semiconductor pattern 1520 of the second pixel circuit PC2, with respect to the imaginary line IML described above.

The second oxide semiconductor pattern 1520 may include a second semiconductor layer A2 of the second transistor T2 and a third semiconductor layer A3 of the third transistor T3. That is, the second semiconductor layer A2 of the second transistor T2 and the third semiconductor layer A3 of the third transistor T3 may be unitary as a single body. The second semiconductor layer A2 and the third semiconductor layer A3 of the second oxide semiconductor pattern 1520 may overlap the reference gate line GRL described above with reference to FIG. 15 and the first conductive layer 1310 described with reference to FIG. 14, respectively. That is, a portion of the second oxide semiconductor pattern 1520 overlapping the reference gate line GRL may be the third semiconductor layer A3, and the portion of the second oxide semiconductor pattern 1520 overlapping the first conductive layer 1310 may be the second semiconductor layer A2.

The third oxide semiconductor pattern 1530 in each of the first pixel circuit PC1 and the second pixel circuit PC2 may have an isolated shape. The third oxide semiconductor pattern 1530 of the first pixel circuit PC1 may be symmetrically with the third oxide semiconductor pattern 1530 of the second pixel circuit PC2, with respect to the imaginary line IML described above.

The third oxide semiconductor pattern 1530 may overlap the fifth conductive layer 1410 described with reference to FIG. 15 and the second conductive layer 1320 described with reference to FIG. 14. The third oxide semiconductor pattern 1530 may include the first upper hold electrode CEh1b, which is a sub-layer of the first hold electrode CEh1 of the hold capacitor Chd.

The fourth oxide semiconductor pattern 1540 may be disposed in the first pixel circuit PC1. The fourth oxide semiconductor pattern 1540 may be disposed at a position corresponding to one end of the first oxide semiconductor pattern 1510 of the first pixel circuit PC2 and may correspond to a kind of dummy electrode.

Each of the first oxide semiconductor pattern 1510, the second oxide semiconductor pattern 1520, the third oxide semiconductor pattern 1530, and the fourth oxide semiconductor pattern 1540 may include at least a partially conductive area. In an embodiment, at least part of each of the first oxide semiconductor pattern 1510, the second oxide semiconductor pattern 1520, the third oxide semiconductor pattern 1530, and the fourth oxide semiconductor pattern 1540 may be treated with plasma or the like such that the part which is treated is conductive, for example. The entirety of the area of the third oxide semiconductor pattern 1530 including the first upper hold electrode CEh1b may be conductive to form the hold capacitor Chd.

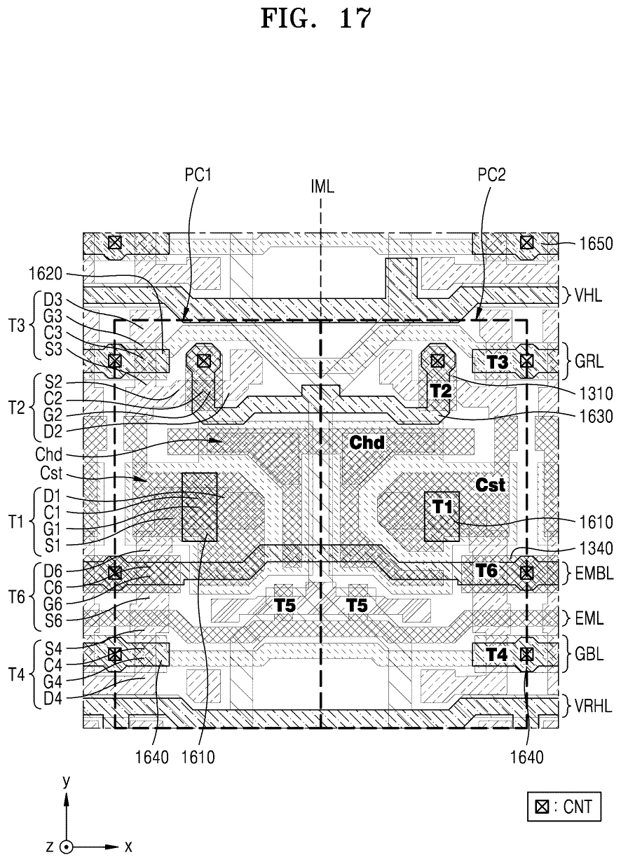

The third gate insulating layer 109 (refer to FIG. 11) may be formed over the structure shown in FIG. 16, a contact hole CNT shown in FIG. 17 is defined in the third gate insulating layer 109, and then the second emission control line EMBL, a horizontal reference voltage line VRHL, a horizontal initialization voltage line VHL, a first electrode layer 1610, a second electrode layer 1620, a third electrode layer 1630, and a fourth electrode layer 1640 shown in FIG. 17 may be formed on the third gate insulating layer 109. The horizontal initialization voltage line VHL, the second emission control line EMBL, the horizontal reference voltage line VRHL, and the first electrode layer 1610, the second electrode layer 1620, the third electrode layer 1630, and the fourth electrode layer 1640 may include Al, Pt, Pd, Ag, Mg, Au, Ni, Nd, Ir, Cr, Li, Ca, Mo, Ti, W, and/or Cu, and may have a single-layer structure or a multi-layer structure including the materials described above.

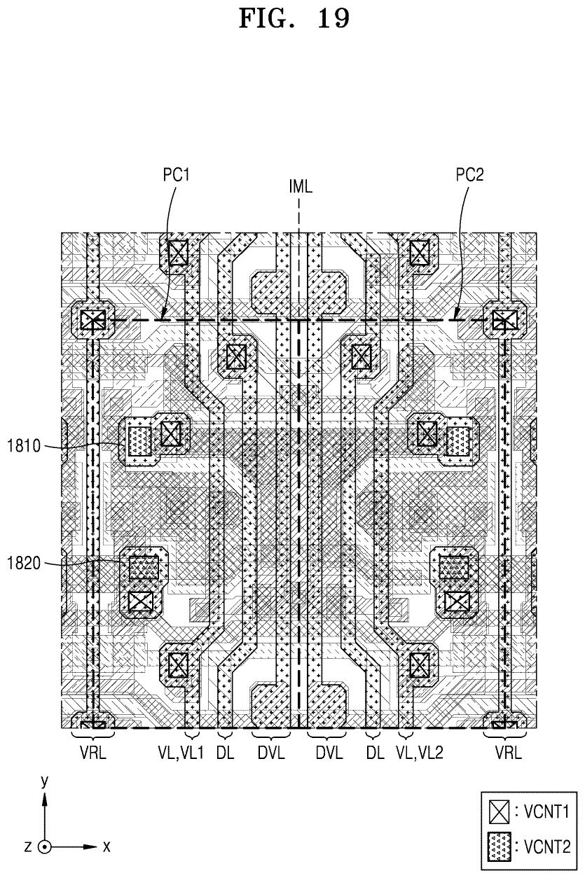

The horizontal initialization voltage line VHL may extend approximately in the first direction (x-axis direction) to pass through the first pixel circuit PC1 and the second pixel circuit PC2. Depending on the location of the first pixel circuit PC1 within the display area DA, the horizontal initialization voltage line VHL may be electrically connected to the initialization voltage line VL which will be described later with reference to FIG. 19.

The horizontal reference voltage line VRHL may extend approximately in the first direction (x-axis direction) to pass through the first pixel circuit PC1 and the second pixel circuit PC2. The horizontal reference voltage line VRHL may be electrically connected to the reference voltage line VRL which will be described later with reference to FIG. 19.

For reference, in the case of pixel circuits in the i^{th} row shown in FIG. 17, and pixel circuits in the (i−2)^{th} and (i+2)^{th} rows (not shown in FIG. 17), the horizontal reference voltage line VRHL extended in the first direction (x-axis direction) may pass therethrough. In case of the pixel circuits in the (i−1)^{th} and (i+1)^{th} rows, the horizontal initialization voltage line VHL extended in the first direction (x-axis direction) may pass therethrough. Therefore, horizontal reference voltage lines VRHL and horizontal initialization voltage lines VHL extending in the first direction (x-axis direction) may be arranged alternately in the second direction (y-axis direction).

The second emission control line EMBL may extend approximately in the first direction (x-axis direction) so as to pass through the first pixel circuit PC1 and the second pixel circuit PC2. The second emission control line EMBL may pass through pixel circuits arranged in the same row as the first pixel circuit PC1 and the second pixel circuit PC2.

The first electrode layer 1610 of each of the first pixel circuit PC1 and the second pixel circuit PC2 may have an isolated shape and may include the first gate electrode G1 of the first transistor T1. That is, the first electrode layer 1610 may correspond to the first gate electrode G1, the portion of the first oxide semiconductor pattern 1510 overlapping the first electrode layer 1610 may be the channel region C1, and regions arranged at opposite sides of the channel region C1 may be conductive regions S1 and D1 which are doped with impurities or treated with plasma to be conductive. One of the conductive regions S1 and D1 of the first oxide semiconductor pattern 1510 may be a source region and a remaining (the other) one may be a drain region. The source region and drain region may correspond to the source electrode and the drain electrode. Positions of the source region and the drain region may be interchanged depending on the properties of the transistor.

The second electrode layer 1620 of each of the first pixel circuit PC1 and the second pixel circuit PC2 may include a third gate electrode G3 of the third transistor T3. The second electrode layer 1620 of the first pixel circuit PC1 and the second electrode layer 1620 of a pixel circuit in the same row as the first pixel circuit PC1 (e.g., the second electrode layer 1620 of the pixel circuit disposed at the i^{th} row and the (j−1)^{th} column) may be unitary as a single body. The second electrode layer 1620 may have an isolated shape and may include the third gate electrode G3 of the third transistor T3. That is, a part of the second electrode layer 1620 corresponds to the third gate electrode G3, and a part of the second oxide semiconductor pattern 1520 overlapping second electrode layer 1620 may be the channel region C3, and regions arranged at opposite sides of the channel region C3 may be conductive regions S3 and D3 which are doped with impurities or treated with plasma to be conductive. One of the conductive regions S3 and D3 may be a source region and a remaining (the other) one may be a drain region. The source region and drain region may correspond to the source electrode and the drain electrode. Positions of the source region and the drain region may be interchanged depending on the properties of the transistor.

The second electrode layer 1620 may be electrically connected to the reference gate line GRL disposed below the third semiconductor layer A3 through a contact hole CNT. Part of the second electrode layer 1620 may overlap part of the reference gate line GRL such that the channel region C3 of the third transistor T3 is therebetween. The part of the reference gate line GRL overlapping the channel region C3 of the third transistor T3 may correspond to a lower gate electrode of the third transistor T3, and through this dual gate structure, the switching performance of the third transistor T3 may be improved.

The third electrode layer 1630 may extend approximately in the first direction (x-axis direction) and may have an isolated shape which is unitary as a single body through the first pixel circuit PC1 and the second pixel circuit PC2. The third electrode layer 1630 may intersect the imaginary line IML described above. The electrode layer 1630 may include a second gate electrode G2 of a second transistor T2. That is, a part of the third electrode layer 1630 corresponds to the second gate electrode G2, and a part of the second oxide semiconductor pattern 1520 overlapping third electrode layer 1630 may be the channel region C2, and regions arranged at opposite sides of the channel region C2 may be conductive regions S2 and D2 which are doped with impurities or treated with plasma to be conductive. One of the conductive regions S2 and D2 may be a source region and a remaining (the other) one may be a drain region. The source region and drain region may correspond to the source electrode and the drain electrode. Positions of the source region and the drain region may be interchanged depending on the properties of the transistor.

The third electrode layer 1630 may be electrically connected to the scan line GWL which will be described later with reference to FIG. 18. The third electrode layer 1630 may be electrically connected to the first conductive layer 1310 disposed below the second semiconductor layer A2 through the contact hole CNT. The third electrode layer 1630 and the first conductive layer 1310 may overlap each other such that the channel region C2 of the second transistor T2 is therebetween. The first conductive layer 1310 may correspond to a lower gate electrode of the second transistor T2, and through this dual gate structure, the switching performance of the second transistor T2 may be improved.

The fourth electrode layer 1640 of each of the first pixel circuit PC1 and the second pixel circuit PC2 may include a fourth gate electrode G4 of the fourth transistor T4. The fourth electrode layer 1640 of the first pixel circuit PC1 and the fourth electrode layer 1640 of the pixel circuit in the same row as the first pixel circuit PC1 (e.g., the second electrode layer 1620 of the pixel circuit disposed at the i^{th} row and the (j−1)^{th} column) may be unitary as a single body. The fourth electrode layer 1640 may have an isolated shape and may include the fourth gate electrode G4 of the fourth transistor T4. That is, a part of the fourth electrode layer 1640 may correspond to the fourth gate electrode G4, and a part of the first oxide semiconductor pattern 1510 overlapping the fourth electrode layer 1640 may be a channel region C4, and regions arranged at opposite sides of the channel region C4 may be conductive regions S4 and D4 which are doped with impurities or treated with plasma to be conductive. One of the conductive regions S4 and D4 may be a source region and a remaining (the other) one may be a drain region. The source region and drain region may correspond to the source electrode and the drain electrode, respectively. Positions of the source region and the drain region may be interchanged depending on the properties of the transistor.

The fourth electrode layer 1640 may be electrically connected to the initialization gate line GBL disposed below the fourth semiconductor layer A4 through the contact hole CNT. Part of the fourth electrode layer 1640 and part of the initialization gate line GBL may overlap each other such that the channel region C4 of the fourth transistor T4 is therebetween. Part of the initialization gate line GBL overlapping the channel region C4 of the fourth transistor T4 may correspond to a lower gate electrode of the fourth transistor T4, and through this dual gate structure, the switching performance of the fourth transistor T4 may be improved.

The second emission control line EMBL may include a sixth gate electrode G6 of the sixth transistor T6. That is, a part of the second emission control line EMBL may correspond to the sixth gate electrode G6, and a part of the first oxide semiconductor pattern 1510 overlapping the second emission control line EMBL may be a channel region C6, and regions arranged at opposite sides of the channel region C6 may be conductive regions S6 and D6 which are doped with impurities or treated with plasma to be conductive. One of the conductive regions S6 and D6 may be a source region and a remaining (the other) one may be a drain region. The source region and drain region may correspond to the source electrode and the drain electrode. Positions of the source region and the drain region may be interchanged depending on the properties of the transistor.

The second emission control line EMBL may be electrically connected to the fourth conductive layer 1340 disposed below the sixth semiconductor layer A6 through a contact hole CNT. Part of the second emission control line EMBL and the fourth conductive layer 1340 may overlap each other such that the channel region C6 of the sixth transistor T6 is therebetween. The fourth conductive layer 1340 may correspond to a lower gate electrode of the sixth transistor T6, and through this dual gate structure, the switching performance of the fourth transistor T4 may be improved.

The second inter-insulating layer 111 (refer to FIG. 11) may be formed over the structure shown in FIG. 17, a contact hole CNT′ shown in FIG. 18 is defined in the second inter-insulating layer 111, the scan line GWL, the first connection electrode 1710, the second connection electrode 1720, the third connection electrode 1730, a fourth connection electrode 1740, a fifth connection electrode 1750, a sixth connection electrode 1760, a seventh connection electrode 1770, an eighth connection electrode 1780, and the horizontal connection line DHL shown in FIG. 18 may be formed over the second inter-insulating layer 111. the scan line GWL, the first connection electrode 1710, the second connection electrode 1720, the third connection electrode 1730, the fourth connection electrode 1740, the fifth connection electrode 1750, the sixth connection electrode 1760, the seventh connection electrode 1770, the eighth connection electrode 1780, and the horizontal connection line DHL may include Al, Pt, Pd, Ag, Mg, Au, Ni, Nd, Ir, Cr, Li, Ca, Mo, Ti, W, and/or Cu, and may have a single-layer structure or a multi-layer structure including the materials described above.

The scan line GWL may extend approximately in the first direction (x-axis direction) to pass through the first pixel circuit PC1 and the second pixel circuit PC2. The scan line GWL may pass through pixel circuits in the same row as the first pixel circuit PC1 and the second pixel circuit PC2.

The first connection electrode 1710 may extend approximately in the first direction (x-axis direction) and may have an isolated shape unitary as a single body through the first pixel circuit PC1 and the second pixel circuit PC2. The first connection electrode 1710 may cross the imaginary line IML between the first pixel circuit PC1 and the second pixel circuit PC2.

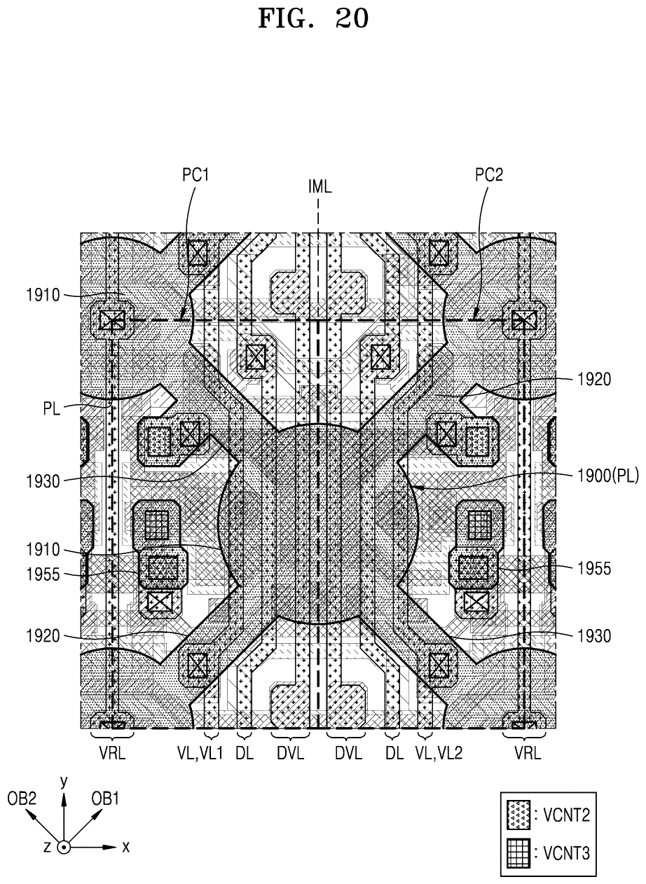

The first connection electrode 1710 may be electrically connected to the second conductive layer 1320 through the contact hole CNT′ and may be electrically connected to the third oxide semiconductor pattern 1530 through the contact hole CNT′. The first connection electrode 1710 may be electrically connected to the fifth semiconductor layer A5 of the fifth transistor T5 through the contact hole CNT′ (located in the −y direction portion of the first connection electrode 1710). Since the first connection electrode 1710 may be electrically connected to the voltage layer 1900 shown in FIG. 20 which will be described later, the first lower hold electrode CEh1a and the first upper hold electrode CEh1b may be electrically connected to the voltage layer 1900, and the fifth transistor T5 shown in FIG. 16 may be electrically connected to the voltage layer 1900.

The second connection electrode 1720 in each of the first pixel circuit PC1 and the second pixel circuit PC2 may have an isolated shape. The second connection electrode 1720 may be electrically connected to the first semiconductor layer A1 of the first transistor T1 through the contact hole CNT′ and may be electrically connected to the fifth semiconductor layer A5 of the fifth transistor T5 through the contact hole CNT′. Therefore, the second connection electrode 1720 may electrically connect the first transistor T1 and the fifth transistor T5.

The third connection electrode 1730 in each of the first pixel circuit PC1 and the second pixel circuit PC2 may have an isolated shape. The third connection electrode 1730 may correspond to the first node N1 in the equivalent pixel circuit shown in FIG. 9. The third connection electrode 1730 may be electrically connected to the first electrode layer 1610 corresponding to the first gate electrode G1 of the first transistor T1 through the contact hole CNT′, electrically connected to the third semiconductor layer A3 through the contact hole CNT′, and electrically connected to the third conductive layer 1330 through the contact hole CNT′. Therefore, the third connection electrode 1730 may electrically connect the first gate electrode G1 of the first transistor T1, the third transistor T3, and the first storage electrode CEs1.

The fourth connection electrode 1740 in each of the first pixel circuit PC1 and the second pixel circuit PC2 may have an isolated shape. The fourth connection electrode 1740 may correspond to the second node N2 in the equivalent pixel circuit of FIG. 9. The fourth connection electrode 1740 may be electrically connected to the fifth conductive layer 1410 including the second storage electrode CEs2 and the second hold electrode CEh2 through the contact hole CNT′, and may be electrically connected to the first oxide semiconductor pattern 1510 through the contact hole CNT′. A connection point of the fourth connection electrode 1740 and the first oxide semiconductor pattern 1510 may be disposed between an area corresponding to the first semiconductor layer A1 and an area corresponding to the sixth semiconductor layer A6 (refer to FIG. 16) within the first oxide semiconductor pattern 1510. Therefore, the fourth connection electrode 1740 may electrically connect the second storage electrode CEs2, the second hold electrode CEh2, the first transistor T1, and the sixth transistor T6.

The fifth connection electrode 1750 in each of the first pixel circuit PC1 and the second pixel circuit PC2 may have an isolated shape. The fifth connection electrode 1750 in the first pixel circuit PC1 and the fifth connection electrode 1750 in the pixel circuit in the (j−1)^{th} column may be unitary as a single body, and the fifth connection electrode 1750 in the second pixel circuit PC2 and the fifth connection electrode 1750 in the pixel circuit in the (j+2)^{th} column may be unitary as a single body. The fifth connection electrode 1750 may be electrically connected to the third semiconductor layer A3 through the contact hole CNT′. The fifth connection electrode 1750 may be connected to the reference voltage line VRL (refer to FIG. 19) which will be described later, and thus may transfer the reference voltage VREF to the third transistor T3.

The sixth connection electrode 1760 in each of the first pixel circuit PC1 and the second pixel circuit PC2 may have an isolated shape. The sixth connection electrode 1760 may be electrically connected to the second semiconductor layer A2 through the contact hole CNT′, and the sixth connection electrode 1760 may be electrically connected to the data line DL (refer to FIG. 19) which will be described later and may transfer the data signal DATA to the second transistor T2.

The seventh connection electrode 1770 in the second pixel circuit PC2 may have an isolated shape. In the second pixel circuit PC2, the seventh connection electrode 1770 may be electrically connected to the fourth semiconductor layer A4 of the fourth transistor T4 through a contact hole CNT′. The seventh connection electrode 1770 may be electrically connected to the second initialization voltage line VL2 (refer to FIG. 19) which will be described later, and may transmit the initialization voltage VINT to the fourth transistor T4. For reference, the fourth transistor T4 in the first pixel circuit PC1 disposed in the j^{th} column may be electrically connected to the fourth transistor T4 of the pixel circuit in the (j−1)^{th} column (next (adjacent) to the j^{th} column from the −x direction), as shown in FIG. 16. Therefore, the fourth transistor T4 in the first pixel circuit PC1 may be electrically connected to the initialization voltage line (not shown in FIG. 16) passing through the pixel circuit in the (j−1)^{th} column (next (adjacent) to the j^{th} column from the −x direction), rather than to the first initialization voltage line VL1 (refer to FIG. 19) passing through the first pixel circuit PC1.

The dummy connection electrode 1770′ in the first pixel circuit PC1 may have an isolated shape. The dummy connection electrode 1770′ may be electrically connected to the fourth oxide semiconductor pattern 1540, which is also a dummy pattern, through a contact hole CNT′.

An eighth connection electrode 1780 in each of the first pixel circuit PC1 and the second pixel circuit PC2 may have an isolated shape. The eighth connection electrode 1780 may be electrically connected to the first oxide semiconductor pattern 1510 through a contact hole CNT′. A connection point of the eighth connection electrode 1780 and the first oxide semiconductor pattern 1510 may be disposed between an area corresponding to the sixth semiconductor layer A6 and an area corresponding to the fourth semiconductor layer A4 within the first oxide semiconductor pattern 1510. Therefore, the eighth connection electrode 1780 may be electrically connected to the sixth semiconductor layer A6 and the fourth semiconductor layer A4, that is, to the fourth transistor T4 and the sixth transistor T6. As described later, since the eighth connection electrode 1780 may be electrically connected to the pixel electrode of the light-emitting element LED, the eighth connection electrode 1780 may electrically connect the fourth transistor T4 and the sixth transistor T6 to the pixel electrode.

The horizontal connection line DHL extending approximately in the first direction (x-axis direction) may correspond to a part of the data transfer line DTL described with reference to FIG. 7 or FIG. 8, e.g., one of the first horizontal connection line DHL1, the second horizontal connection line DHL2, or the third horizontal connection line DHL3. As shown in FIG. 18, the horizontal connection line DHL may have a portion protruding in the second direction (y-axis direction). When it is desired for the horizontal connection line DHL to be electrically connected to the vertical connection line DVL, the horizontal connection line DHL may be electrically connected to the vertical connection line DVL at the portion of the horizontal connection line DHL protruding in the second direction (y-axis direction).

The first organic insulating layer 113 (refer to FIG. 11) may be formed over the structure described with reference to FIG. 18, first via contact holes VCNT1 may be defined in the first organic insulating layer 113, and then the data line DL, the vertical connection line DVL, the initialization voltage line VL, the reference voltage line VRL, a ninth connection electrode 1810, and a tenth connection electrode 1820 may be formed over the first organic insulating layer 113.

Each of the data line DL, the vertical connection line DVL, the initialization voltage line VL, and the reference voltage line VRL may extend in the second direction (y-axis direction). The data line DL, the vertical connection line DVL, the initialization voltage line VL, and the reference voltage line VRL passing through the first pixel circuit PC1 may be symmetrical with the data line DL, the vertical connection line DVL, the initialization voltage line VL, and the reference voltage line VRL passing through the second pixel circuit PC2, with respect to the imaginary line IML.

The data line DL passing through each of the first pixel circuit PC1 and the second pixel circuit PC2 may be electrically connected to the sixth connection electrode 1760 described with reference to FIG. 18 through the first via contact hole VCNT1, and may provide a data signal to the second transistor T2.

The vertical connection line DVL passing through each of the first pixel circuit PC1 and the second pixel circuit PC2 may correspond to a portion of the data transfer line DTL described with reference to FIG. 7 or FIG. 8, for example, any one of the first vertical connection line DVL1, the second vertical connection line DVL2, the third vertical connection line DVL3, the first additional vertical connection line DVL1′, the second additional vertical connection line DVL2′, and the third additional vertical connection line DVL3′. The vertical connection line DVL has a portion protruding in the first direction (x-axis direction), and when it is desired for the vertical connection line DVL to be electrically connected to the horizontal connection line DHL disposed below the vertical connection line DVL, the protruding portion of the vertical connection line DVL may be electrically connected to the horizontal connection line DHL through a via contact hole defined in the first organic insulating layer 113.

The initialization voltage line VL passing through the second pixel circuit PC2 may be electrically connected to the seventh connection electrode 1770 below the initialization voltage line VL through the first via contact hole VCNT1, the seventh connection electrode 1770 may be electrically connected to the first oxide semiconductor pattern 1510 below the seventh connection electrode 1770 through a contact hole CNT′, and thus initialization voltage may be provided to the fourth transistor T4 in the second pixel circuit PC2. FIG. 18 shows that each of a pixel circuit disposed in the +y direction from the first pixel circuit PC1, a pixel circuit disposed in the +y direction from the second pixel circuit PC2, the first pixel circuit PC1, and the second pixel circuit PC2 includes the seventh connection electrode 1770 having a substantially similar shape. Among these, the seventh connection electrode 1770 in the pixel circuit disposed in the +y direction from the second pixel circuit PC2 may be electrically connected to the first oxide semiconductor pattern 1510 through a contact hole CNT′, and may be also electrically connected to the protruding portion of the horizontal initialization voltage line VHL through another contact hole CNT′. Accordingly, the horizontal initialization voltage lines VHL extending in the first direction (x-axis direction) and the second initialization voltage lines VL2 extending in the second direction (y-axis direction) may be electrically connected to each other to form a mesh structure, so that the initialization voltage VINT in the display area DA supplied by the second initialization voltage lines VL2 may be maintained approximately uniformly.

Clearly, the horizontal initialization voltage line VHL in a row other than the (i−1)^{th} row shown in FIG. 17, for example, the horizontal initialization voltage line VHL in the (i+1)^{th} row, may be electrically connected to the first initialization voltage line VL1. In this way, the horizontal initialization voltage lines VHL extending in the first direction (x-axis direction) and the first initialization voltage lines VL1 extending in the second direction (y-axis direction) may be electrically connected to each other to form a mesh structure, so that the initialization voltage VINT in the display area DA supplied by the first initialization voltage lines VL1 may be maintained approximately uniformly.

The initialization voltage line VL passing through the first pixel circuit PC1 may be electrically connected to the dummy connection electrode 1770′ through the first via contact hole VCNT1. As described above with reference to FIG. 18, the fourth transistor T4 in the first pixel circuit PC1 disposed in the j^{th} column may be electrically connected to the fourth transistor T4 of the pixel circuit in the (j−1)^{th} column which is next (adjacent) to the first pixel circuit PC1 from the −x direction, as shown in FIG. 16. Therefore, the fourth transistor T4 in the first pixel circuit PC1 may be electrically connected to the initialization voltage line (not shown in FIG. 19) passing through the pixel circuit in the (j−1)^{th} column which is next (adjacent) to the first pixel circuit PC1 from the −x direction, rather than to the first initialization voltage line (VL1, refer to FIG. 19) passing through the first pixel circuit PC1.

The reference voltage line VRL passing through each of the first pixel circuit PC1 and the second pixel circuit PC2 may be electrically connected to the fifth connection electrode 1750 described with reference to FIG. 18 through the first via contact hole VCNT1, and the fifth connection electrode 1750 may be electrically connected to the second oxide semiconductor pattern 1520 through a contact hole CNT′, such that the reference voltage may be provided to the third transistor T3. FIG. 18 shows that the fifth connection electrodes 1750 are disposed at the upper left, upper right, lower left, and lower right of a set of the first pixel circuit PC1 and the second pixel circuit PC2. In the case of the fifth connection electrodes 1750 at the lower left and lower right of the set of the first pixel circuit PC1 and the second pixel circuit PC2 may be electrically connected to the horizontal reference voltage line VRHL through contact holes CNT′. Therefore, the horizontal reference voltage lines VRHL extending in the first direction (x-axis direction) and the reference voltage lines VRL extending in the second direction (y-axis direction) may be electrically connected to each other to form a mesh structure, so that the reference voltage VREF may be maintained approximately uniformly in the display area DA.

For reference, the first pixel circuit PC1 in the j^{th} column may share the reference voltage line VRL with the pixel circuit in the (j−1)^{th} column which is next (adjacent) to the first pixel circuit PC1 from the −x direction, and the second pixel circuit PC2 in the (j+1)^{th} column may share the reference voltage line VRL with the pixel circuit in the (j+2)^{th} column which is next (adjacent) to the second pixel circuit PC2 from the +x direction.

Each of the ninth connection electrode 1810 and the tenth connection electrode 1820 may have an isolated shape. The ninth connection electrode 1810 disposed in each of the first pixel circuit PC1 and the second pixel circuit PC2 may be electrically connected to the first connection electrode 1710 described with reference to FIG. 18 through the first via contact hole VCNT1. The first connection electrode 1710 and the ninth connection electrode 1810 may electrically connect the voltage layer 1900 which will be described later and the hold capacitor Chd. The tenth connection electrode 1820 in each of the first pixel circuit PC1 and the second pixel circuit PC2 may be electrically connected to the eighth connection electrode 1780 described with reference to FIG. 18 through the first via contact hole VCNT1. The eighth connection electrode 1780 and the tenth connection electrode 1820 may electrically connect a pixel electrode of the light-emitting element LED to the fourth transistor T4 and the sixth transistor T6.

The second organic insulating layer 115 may be formed over the structure described with reference to FIG. 19, and second via contact holes VCNT2 may be defined in the second organic insulating layer 115. As shown in FIG. 20, the voltage layer 1900 and an eleventh connection electrode 1955 may be formed over the second organic insulating layer 115.

As shown in FIG. 20, the voltage layer 1900 may include main portions 1910 spaced apart from each other and bridge portions 1920 and 1930 extending to the main portions 1910 next to each other. The main portions 1910 and the bridge portions 1920 and 1930 may be unitary as a single body. The voltage layer 1900 including the main portion 1910 and the bridge portions 1920 and 1930 may have a mesh structure such that the self-resistance of the voltage layer 1900 may be reduced. That is, the connection structure of the main portion 1910 and the bridge portions 1920 and 1930 may have the mesh structure in a plan view. The voltage layer 1900 may include the driving voltage line PL described above with reference to FIG. 9. That is, the voltage layer 1900 may have a function of the driving voltage line PL described with reference to FIG. 9.

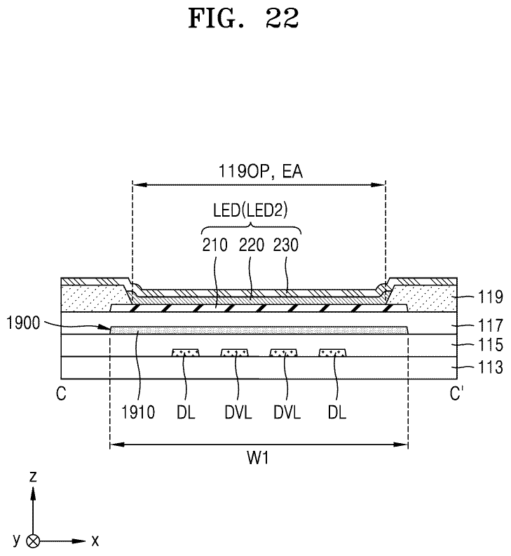

The main portion 1910 may overlap a voltage line or signal line thereunder. Any one of the main portions 1910 may be disposed on the imaginary line IML and may overlap the data line DL and the vertical connection line DVL passing through each of the first pixel circuit PC1 and the second pixel circuit PC2. Another one of the main portions 1910 may overlap the reference voltage line VRL passing through the first pixel circuit PC1. Another one of the main portions 1910 may overlap the reference voltage line VRL passing through the second pixel circuit PC2. The main portion 1910 may overlap an emission area EA (refer to FIG. 22) of the light-emitting element LED which will be described later.

The bridge portions 1920 and 1930 may extend in a first diagonal direction OB1 between the first direction (x-axis direction) and the second direction (y-axis direction), or may extend in a second diagonal direction OB2 crossing the first direction. Each of the bridge portions 1920 and 1930 may connect neighboring (adjacent) main portions 1910. In an embodiment, a first bridge portion 1920 among the bridge portions 1920 and 1930 may extend in the first diagonal direction OB1 and may connect two neighboring (adjacent) main portions 1910, for example. A second bridge portion 1930 among the bridge portions 1920 and 1930 may extend in the second diagonal direction OB2 and may connect two neighboring (adjacent) main portions 1910.

The second bridge portion 1930 passing through the first pixel circuit PC1 may be electrically connected to the ninth connection electrode 1810 in the first pixel circuit PC1 through the second via contact hole VCNT2. The ninth connection electrode 1810 may be electrically connected to the first connection electrode 1710 in the first pixel circuit PC1, and the first connection electrode 1710 may be electrically connected to the second conductive layer 1320 including the first lower hold electrode CEh1a, the third oxide semiconductor pattern 1530 including the first upper hold electrode CEh1b, and the fifth semiconductor layer A5 of the fifth transistor T5. The first lower hold electrode CEh1a and the first upper hold electrode CEh1b are the first hold electrode CEh1 of the hold capacitor Chd. Therefore, the driving voltage of the voltage layer 1900 may be transmitted to the first hold electrode CEh1 of the hold capacitor Chd and the fifth transistor T5 of the first pixel circuit PC1.

The first bridge portion 1920 passing through the second pixel circuit PC2 may be electrically connected to the ninth connection electrode 1810 disposed below the first bridge portion 1920 in the second pixel circuit PC2 through the second via contact hole VCNT2. The ninth connection electrode 1810 may be electrically connected to the first connection electrode 1710 in the second pixel circuit PC2, and the first connection electrode 1710 may be electrically connected to the second conductive layer 1320 including the first lower hold electrode CEh1a, the third oxide semiconductor pattern 1530 including the first upper hold electrode CEh1b, and the fifth semiconductor layer A5 of the fifth transistor T5. The first lower hold electrode CEh1a and the first upper hold electrode CEh1b are parts of the first hold electrode CEh1 of the hold capacitor Chd. Therefore, the driving voltage of the voltage layer 1900 may be transmitted to the first hold electrode CEh1 of the hold capacitor Chd and the fifth transistor T5 of the second pixel circuit PC2.

The eleventh connection electrode 1955 in each of the first pixel circuit PC1 and the second pixel circuit PC2 may have an isolated shape. The eleventh connection electrode 1955 in the first pixel circuit PC1 may be electrically connected to the tenth connection electrode 1820 disposed below the eleventh connection electrode 1955 in the first pixel circuit PC1 through the second via contact hole VCNT2 and the eleventh connection electrode 1955 in the second pixel circuit PC2 may be electrically connected to the tenth connection electrode 1820 disposed below the eleventh connection electrode 1955 in the second pixel circuit PC2 through the second via contact hole VCNT2.

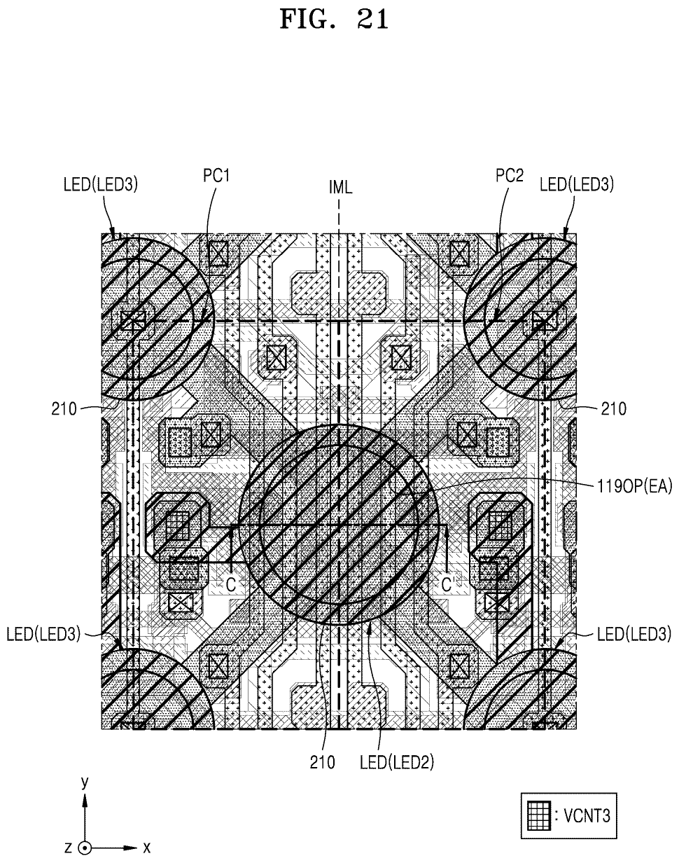

The third organic insulating layer 117 may be formed over the structure shown in FIG. 20, and third via contact holes VCNT3 may be defined in the third organic insulating layer 117. The pixel electrodes 210 of the light-emitting element LED which will be described later with reference to FIG. 21 may be disposed on the third organic insulating layer 117. Each of the pixel electrodes 210 may be electrically connected to the eleventh connection electrode 1955 of a corresponding pixel circuit through the third via contact hole VCNT3.

Although FIG. 20 shows that the main portion 1910 has a circular shape, the disclosure is not limited thereto. In an embodiment, the main portion 1910 may have an elliptical or polygonal (such as quadrangular, e.g., rectangular, pentagonal, hexagonal, octagonal, etc.) shape, for example.

FIG. 21 is a layout diagram schematically illustrating pixel electrodes 210 of the display panel 10 shown in FIG. 10, and FIG. 22 is a cross-sectional view schematically illustrating a cross-section of the display panel 10 taken along line C-C′ of FIG. 21. The pixel electrode 210 may overlap the initialization voltage line VL (refer to FIG. 19). However, for convenience of description, the initialization voltage line VL is omitted in FIG. 21. Since the light-emitting element includes the pixel electrode 210, the position of the pixel electrode 210 may be regarded as the position of the light-emitting element.

As shown in FIG. 21, the light-emitting elements LED may be spaced apart from each other. FIG. 21 shows that a second light-emitting element LED2 overlapping the first pixel circuit PC1 and the second pixel circuit PC2 is electrically connected to the first pixel circuit PC1 disposed in the i^{th} row and j^{th} column. In this way, the second light-emitting element LED2 may be disposed on the imaginary line IML between the first pixel circuit PC1 and the second pixel circuit PC2, and the pixel electrode 210 of the second light-emitting element LED2 may have a protrusion protruding in the −x direction and may be electrically connected to the first pixel circuit PC1 through the third via contact hole VCNT3 below the protrusion, as shown in FIG. 21. Other light-emitting elements may also have the pixel electrode 210 that may be electrically connected to a corresponding pixel circuit through the third via contact hole VCNT3 below the protrusion.

Four third light-emitting elements LED3 may be arranged around the second light-emitting element LED2. In FIG. 21, dotted lines in the shape of a rectangle indicate the boundary of a set of the first pixel circuit PC1 and the second pixel circuit PC2. FIG. 21 shows that the third light-emitting elements LED3 are disposed at four corners of the rectangle of the dotted lines. That is, the third light-emitting element LED3 disposed at the lower right portion in FIG. 21 may be electrically connected to the second pixel circuit PC2 in the i^{th} row and (j+1)^{th} column, the third light-emitting element LED3 disposed at the upper right portion in FIG. 21 may be electrically connected to the pixel circuit which is next (adjacent) to the second pixel circuit PC2 in the +y direction and disposed in the (i−1)^{th} row and (j+1)^{th} column, the third light-emitting element LED3 disposed at the lower left portion in FIG. 21 may be electrically connected to the pixel circuit which is next (adjacent) to the first pixel circuit PC1 in-x direction and disposed in the i^{th} row and (j−1)^{th} column, and the third light-emitting element LED3 disposed at the upper left portion in FIG. 21 may be electrically connected to the pixel circuit disposed in the (i−1)^{th} row and (j−1)^{th} column.

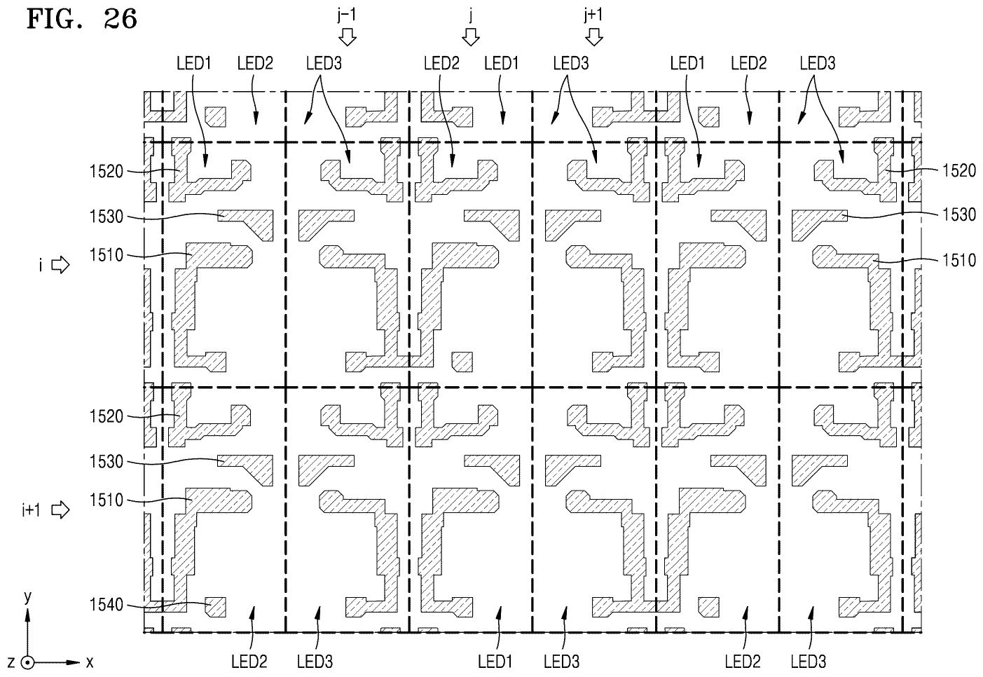

For reference, the first light-emitting element LED1 (refer to FIG. 26) may be electrically connected to the pixel circuit which is next (adjacent) to the first pixel circuit PC1 in the +x direction and disposed in the (i−1)^{th} row and j^{th} column. The first light-emitting elements LED1 may also be electrically connected to the pixel circuit which is next (adjacent) to the second pixel circuit PC2 in the +x direction and disposed in the i^{th} row and (j+2)^{th} column, the pixel circuit disposed in the i^{th} row and (j−2)^{th} column, and the pixel circuit which is next (adjacent) to the first pixel circuit PC1 in the −y direction and disposed in (i+1)^{th} row and j^{th} column. In the case of this first light-emitting element LED1, similarly to the second light-emitting element LED2, four third light-emitting elements LED3 may be arranged around the first light-emitting element LED1.

In this way, a set of four pixel circuits, that is, the pixel circuit for the first light-emitting element LED1, the pixel circuit for the third light-emitting element LED3, the pixel circuit for the second light-emitting element LED2, and the pixel circuit for the third light-emitting element LED3, may be repeatedly arranged in the +x direction in the i^{th} row. Similarly, a set of two pixel circuits, that is, the pixel circuit for the first light-emitting element LED1 and the pixel circuit for the second light-emitting element LED2, may be repeatedly arranged in the second direction (y-axis direction) in the j^{th} column, and the pixel circuit for the third light-emitting element LED3 may be repeatedly arranged in the second direction (y-axis direction) in each of the (j−1)^{th} column and the (j+1)^{th} column.

The first light-emitting element LED1 may emit red light, the second light-emitting element LED2 may emit blue light, and the third light-emitting element LED3 may emit green light.

As shown in FIGS. 21 and 22, each of the light-emitting elements LED may overlap a corresponding one of the main portions 1910 of the voltage layer 1900. An emission area EA of each of the light-emitting elements LED may overlap a corresponding one of the main portions 1910 of the voltage layer 1900.

As shown in FIG. 22, the main portion 1910 of the voltage layer 1900 may be disposed between the pixel electrode 210 and lines which are disposed below the main portion 1910 and provide signals. The lines providing the signals may be data lines DL and vertical connection lines DVL, for example. The main portion 1910 may prevent or minimize the occurrence of parasitic capacitance between each of the data lines DL and/or vertical connection lines DVL and the pixel electrode 210, thereby preventing or minimizing deterioration of display quality due to parasitic capacitance.

The voltage layer 1900 may correspond to the driving voltage line PL described above with reference to FIG. 9, and accordingly, and thus the voltage layer 1900 may have a voltage level (e.g., constant voltage) of the driving voltage ELVDD. However, the disclosure is not limited thereto. In an embodiment, the voltage layer 1900 may have a voltage level (e.g., constant voltage) of the common voltage ELVSS, in which case a feature corresponding to the driving voltage line may be disposed in the same layer as the data line DL or the like, for example.

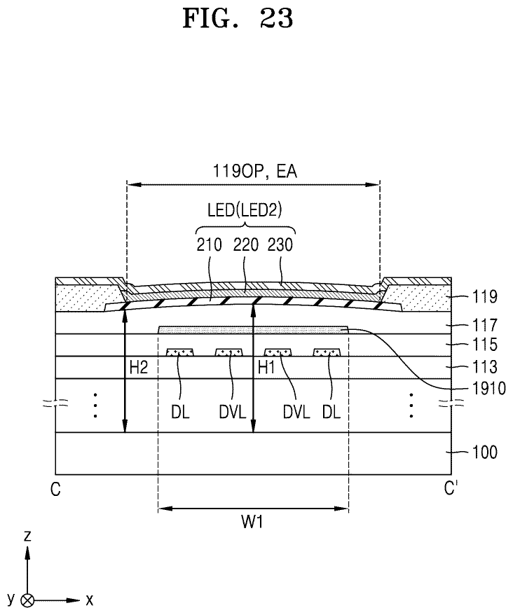

A width W1 of the main portion 1910 may be greater than a width of the emission area EA of each light-emitting element LED, as shown in FIG. 22. The emission area EA of the light-emitting element LED may be defined by the opening 119OP defined in the pixel definition layer 119 overlapping the pixel electrode 210. In this case, the width W1 or area of the main portion 1910 may be greater than a width or area of the opening 119OP overlapping the main portion 1910. However, the disclosure is not limited thereto. In an embodiment, the width W1 of the main portion 1910 may be greater than the width of the emission area EA of each light-emitting element LED, as shown in FIG. 23 which is a cross-sectional view schematically illustrating a cross-section of the display panel 10 in an embodiment, for example. That is, the width W1 or area of the main portion 1910 may be less than a width or area of the opening 119OP overlapping the pixel electrode 210.

As illustrated in FIG. 22, when the width W1 of the main portion 1910 is greater than the width of the emission area EA, a portion of the pixel electrode 210 corresponding to the emission area EA may be maintained in a relatively flat state. As illustrated in FIG. 23, when the width W1 of the main portion 1910 is less than the width of the emission area EA, a portion of an upper surface of the third organic insulating layer 117 disposed below a portion of the pixel electrode 210 corresponding to the emission area EA may not be flat, in the emission area EA. In an embodiment, a first vertical height H1 between a portion of the pixel electrode 210 corresponding a central portion of the emission area EA and the substrate 100 may be greater than the second vertical height H2 between a portion of the pixel electrode 210 corresponding to an edge of the emission area EA and the substrate 100, for example. In the structure shown in FIG. 22, sufficient luminance in a front direction (e.g., the z-axis direction) may be ensured. In the structure shown in FIG. 23, luminance in an oblique direction not the front direction (e.g., z-axis direction) may be increased.

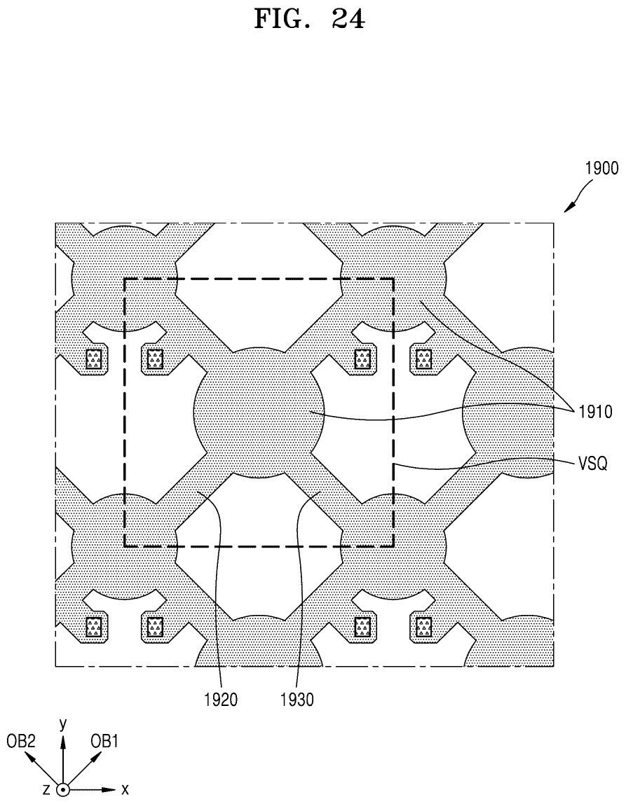

FIG. 24 is a plan view showing the voltage layer 1900 of FIG. 20. As shown in FIG. 24, the main portion 1910 may be spaced apart from each other. As described above, the main portions 1910 may be disposed at the center and at the four corners of the rectangle VSQ of the dotted lines that represents the boundary of the set of the first pixel circuit PC1 and the second pixel circuit PC2.

The main portions 1910 may differ in size. FIG. 24 shows that a size (or width) of the main portion 1910 disposed at the center of the rectangle VSQ of dotted lines is greater than a size (or width) of the main portion 1910 disposed at each of the corners of the rectangle VSQ of dotted lines. However, the disclosure is not limited thereto. In an embodiment, the size (or width) of the main portion 1910 disposed at the center of the rectangle VSQ of dotted lines may be smaller than the size (or width) of the main portion 1910 disposed at each of the corners of the rectangle VSQ of dotted lines, for example.

As shown in FIGS. 20 and 24, the first and second bridge portions 1920 and 1930 connecting the main portions 1910 of the voltage layer 1900 may extend in the first diagonal direction OB1 and the second diagonal direction OB2. Therefore, the main portion 1910 disposed at the center of the rectangle VSQ of the dotted lines may be directly connected to the main portions 1910 disposed at the four corners of the rectangle VSQ of the dotted lines.

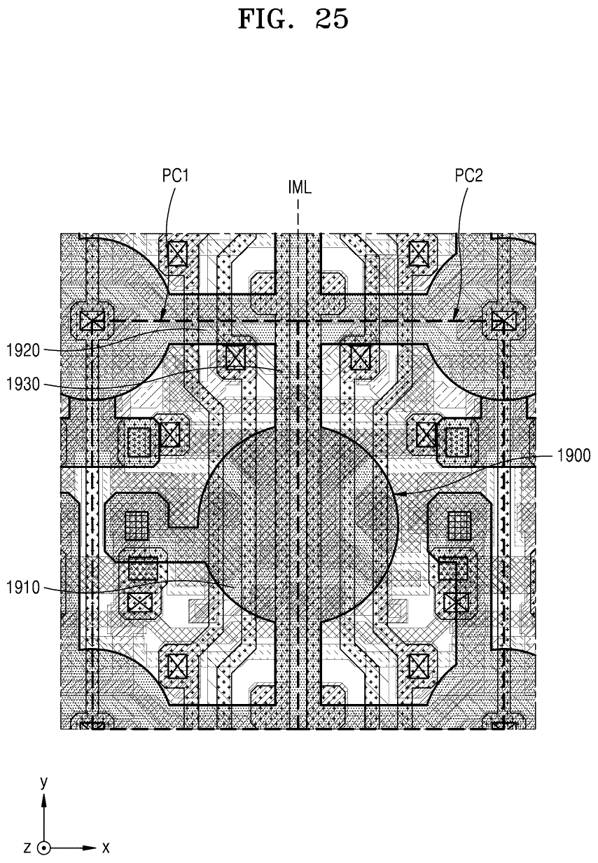

FIG. 25 is a plan view schematically illustrating an embodiment of the voltage layer 1900 of a display panel 10. As shown in FIG. 25, the first bridge portion 1920 may extend in the first direction (x-axis direction) and the second bridge portion 1930 may extend in the second direction (y-axis direction). In this case, two main portions 1910 next (adjacent) to each other in the first direction (x-axis direction) among the main portions 1910 disposed at the four corners of the rectangle VSQ of the dotted lines indicating the boundary of the set of the first pixel circuit PC1 and the second pixel circuit PC2, may be connected to each other through the first bridge portion 1920 extending in the first direction (x-axis direction).

The main portion 1910 disposed at the center of the rectangle VSQ of the dotted lines indicating the boundary of the set of the first pixel circuit PC1 and the second pixel circuit PC2, may be connected to the first bridge portion 1920 which connects two main portions 1910 disposed at the corners of the rectangle VSQ of the dotted lines indicating the boundary of the set of the first pixel circuit PC1 and the second pixel circuit PC2, through the second bridge portion 1930 extending in the second direction (y-axis direction). That is, the main portion 1910 disposed at the center of the rectangle VSQ of the dotted lines indicating the boundary of the set of the first pixel circuit PC1 and the second pixel circuit PC2, may be connected to the main portions 1910 disposed at the corners of the rectangle VSQ of the dotted lines indicating the boundary of the set of the first pixel circuit PC1 and the second pixel circuit PC2, through the second bridge portions 1930 extending in the +y direction and −y direction and the first bridge portions 1920.

In the embodiments described above, through a shielding structure of the main portion 1910 of the voltage layer 1900, parasitic capacitance occurring between the line providing data signals and the pixel electrode 210 may be prevented or minimized. In addition, because the switching transistors have a dual gate structure in which gate electrodes are disposed over and below a semiconductor layer, switching performance of the switching transistors are improved. Further, by oxide transistors, a display panel 10 and electronic apparatus comprising the same having a high-speed driving or response speed and providing high-quality images may be provided.

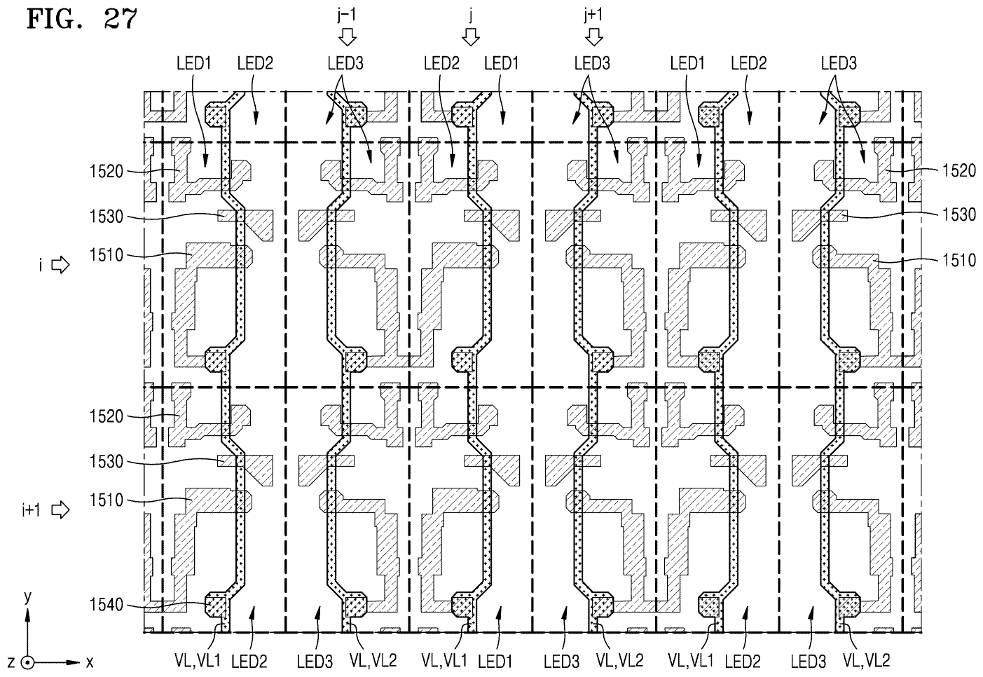

FIG. 26 is a layout diagram schematically illustrating an embodiment of the semiconductor layer patterns 1510, 1520, 1530, and 1540 of the display panel 10 and the electronic apparatus comprising the same, and FIG. 27 is a layout diagram schematically illustrating the positional relationship between the semiconductor layer patterns 1510, 1520, 1530, and 1540 of FIG. 26 and the initialization voltage lines VL. For reference, in FIGS. 26 and 27, the first light-emitting element LED1, the second light-emitting element LED2, and the third light-emitting element LED3 represent an area of the pixel circuit to which the first light-emitting element LED1 is electrically connected, an area of the pixel circuit to which the second light-emitting element LED2 is electrically connected, and an area of the pixel circuit to which the third light-emitting element LED3 is electrically connected.

Similar to the display panel 10 and the electronic apparatus comprising the same which is described above with reference to FIGS. 26 and 27, a set of four pixel circuits, that is, the pixel circuit for the first light-emitting element LED1, the pixel circuit for the third light-emitting element LED3, the pixel circuit for the second light-emitting element LED2, and the pixel circuit for the third light-emitting element LED3, may be repeatedly arranged in the +x direction in the i^{th} row. This also applies to the (i+1)^{th} row and other rows. Similarly, in each of the (j−2)^{th} column, j^{th} column, and (j+2)^{th} column, a set of two pixel circuits, that is, the pixel circuit for the first light-emitting element LED1 and the pixel circuit for the second light-emitting element LED2, may be repeatedly arranged in the second direction (y-axis direction), and in each of the (j−1)^{th} column and (j+1)^{th} column, the pixel circuit for the third light-emitting element LED3 may be repeatedly arranged in the second direction (y-axis direction).

Initialization voltage lines VL extending approximately in the second direction (y-axis direction) within the display area DA may be arranged to be spaced apart from each other in the first direction (x-axis direction). For convenience, it may be regarded that the initialization voltage lines VL include the first initialization voltage line VL1 and the second initialization voltage line VL2, and that the first initialization voltage line VL1 and the second initialization voltage line VL2 are alternately arranged in the first direction (x-axis direction). Along each of the first initialization voltage lines VL1, the pixel circuit for the first light-emitting element LED1 and the pixel circuit for the second light-emitting element LED2, i.e., the first-color pixel circuit and the second-color pixel circuit, may be alternately arranged in the second direction (y-axis direction). Along each of the second initialization voltage lines VL2, pixel circuits for third light-emitting elements LED3, i.e., third-color pixel circuits, may be arranged in the second direction (y-axis direction).

Here, the first oxide semiconductor pattern 1510 in each of the second-color pixel circuits, which are pixel circuits for the second light-emitting elements LED2, may be electrically connected to the first oxide semiconductor pattern 1510 in the third-color pixel circuit, which is the pixel circuit for the third light-emitting element LED3, disposed in the −x direction from the second-color pixel circuit. Because a part of the first oxide semiconductor pattern 1510 is an element of the fourth transistor T4 which is the initialization transistor, the fourth transistor T4 in each of the second-color pixel circuits may be electrically connected to the fourth transistor T4 in any one of the third-color pixel circuits which is next (adjacent) to the second-color pixel circuit in the first direction (x-axis direction). FIGS. 26 and 27 shows that the first oxide semiconductor pattern 1510 in each of the second-color pixel circuits, which are pixel circuits for the second light-emitting elements LED2, and the first oxide semiconductor pattern 1510 in the third-color pixel circuit, which is the pixel circuit for the third light-emitting element LED3 disposed in the −x direction from the second-color pixel circuit, are unitary as a single body. For reference, the first oxide semiconductor pattern 1510 in each of the first-color pixel circuits, which are pixel circuits for the first light-emitting elements LED1, may have an isolated shape within the area of the first-color pixel circuit.

As described above, the intermediate layer 220 including the emission layer is disposed between the pixel electrode 210 and the common electrode 230 of the light-emitting element LED. The materials and thicknesses of the emission layers of the first light-emitting element LED1, the second light-emitting element LED2, and the third light-emitting element LED3, which emit light of different colors, may be different from each other. Accordingly, parasitic capacitances and/or threshold voltages for light emission between the pixel electrodes 210 and the common electrode 230 of the first light-emitting element LED1, the second light-emitting element LED2, and the third light-emitting element LED3 may be different.

The pixel electrode 210 of each of the first light-emitting element LED1, the second light-emitting element LED2, and the third light-emitting element LED3 may be initialized with the initialization voltage VINT from the initialization voltage line VL by the fourth transistor T4, which is the second initialization transistor. Because the parasitic capacitances and threshold voltages for light emission between the common electrode 230 and the pixel electrodes 210 of the first light-emitting element LED1, the second light-emitting element LED2, and the third light-emitting element LED3 are different, the initialization voltages applied to the pixel electrodes 210 of the first light-emitting element LED1, the second light-emitting element LED2, and the third light-emitting element LED3 need to be different from each other, theoretically. To this end, it is desired to separately arrange an initialization voltage line for the first light-emitting element LED1, an initialization voltage line for the second light-emitting element LED2, and an initialization voltage line for the third light-emitting element LED3 within the display area DA. However, in a high-resolution display panel 10 and an electronic apparatus comprising the same, it is not easy to separately arrange the initialization voltage line for the first light-emitting element LED1, the initialization voltage line for the second light-emitting element LED2, and the initialization voltage line for the third light-emitting element LED3.

As described above, in the case of the display panel 10 and the electronic apparatus comprising the same in an embodiment, the pixel circuit for the first light-emitting element LED1 and the pixel circuit for the second light-emitting element LED2, i.e., the first-color pixel circuit and the second-color pixel circuit, are alternately arranged along each of the first initialization voltage lines VL1, in the second direction (y-axis direction). However, the pixel circuit for the first light-emitting element LED1 is electrically connected to the first initialization voltage line VL1, whereas the pixel circuit for the second light-emitting element LED2 is electrically connected to the second initialization voltage line VL2, not the first initialization voltage line VL1. Accordingly, the initialization voltage VINT may be applied to the first light-emitting element LED1 by the first initialization voltage line VL1, and the initialization voltage VINT may be applied to the second light-emitting element LED2 and the third light-emitting element LED3 by the second initialization voltage line VL2. The signal of the initialization voltage VINT applied to the first initialization voltage line VL1 may be different from the signal of the initialization voltage VINT applied to the second initialization voltage line VL2. That is, the electric potential of the initialization voltage VINT applied to the first initialization voltage line VL1 may be different from the electric potential of the initialization voltage VINT applied to the second initialization voltage line VL2.

The optimal initialization voltage VINT for the first light-emitting element LED1 may be different from the optimal initialization voltage VINT for the second light-emitting element LED2. In this situation, the optimal initialization voltage VINT for the second light-emitting element LED2 is not completely identical to the optimal initialization voltage VINT for the third light-emitting element LED3, but may be closer to the optimal initialization voltage VINT for the third light-emitting element LED3 than the optimal initialization voltage VINT for the first light-emitting element LED1. In the display panel 10 and the electronic apparatus comprising the same in embodiments, even though the pixel circuit for the first light-emitting element LED1 and the pixel circuit for the second light-emitting element LED2, that is, the first-color pixel circuit and the second-color pixel circuit, are alternately arranged in the second direction (y-axis direction) along each of the first initialization voltage lines VL1, the display panel 10 and the electronic apparatus comprising the same is capable of displaying high-quality images because only the first-color pixel circuit is electrically connected to the first initialization voltage line VL1 and the second-color pixel circuit is electrically connected to the second initialization voltage line VL2 to which the third-color pixel circuit is electrically connected.

When the first-color pixel circuit is electrically connected to the first initialization voltage line VL1, it means that one end of the fourth transistor T4 of the first-color pixel circuit, which is the second initialization transistor of the first-color pixel circuit, is electrically connected to the first initialization voltage line VL1. When the second-color pixel circuit and the third-color pixel circuit are electrically connected to the second initialization voltage line VL2, it means that one end of the fourth transistor T4 of the second-color pixel circuit, which is the second initialization transistor of the second-color pixel circuit, and one end of the fourth transistor T4 of the third-color pixel circuit, which is the second initialization transistor of the third-color pixel circuit, are electrically connected to the second initialization voltage line VL2. In this situation, an opposite end of the fourth transistor T4 of the first-color pixel circuit opposite to the one end of the fourth transistor T4 may be electrically connected to the pixel electrode 210 of the first light-emitting element LED1, which is an element emitting first-color light, the opposite end of the fourth transistor T4 of the second-color pixel circuit may be electrically connected to the pixel electrode 210 of the second light-emitting element LED2, which is an element emitting second-color light, and the opposite end of the fourth transistor T4 of the third-color pixel circuit may be electrically connected to the pixel electrode 210 of the third light-emitting element LED3, which is an element emitting third-color light.

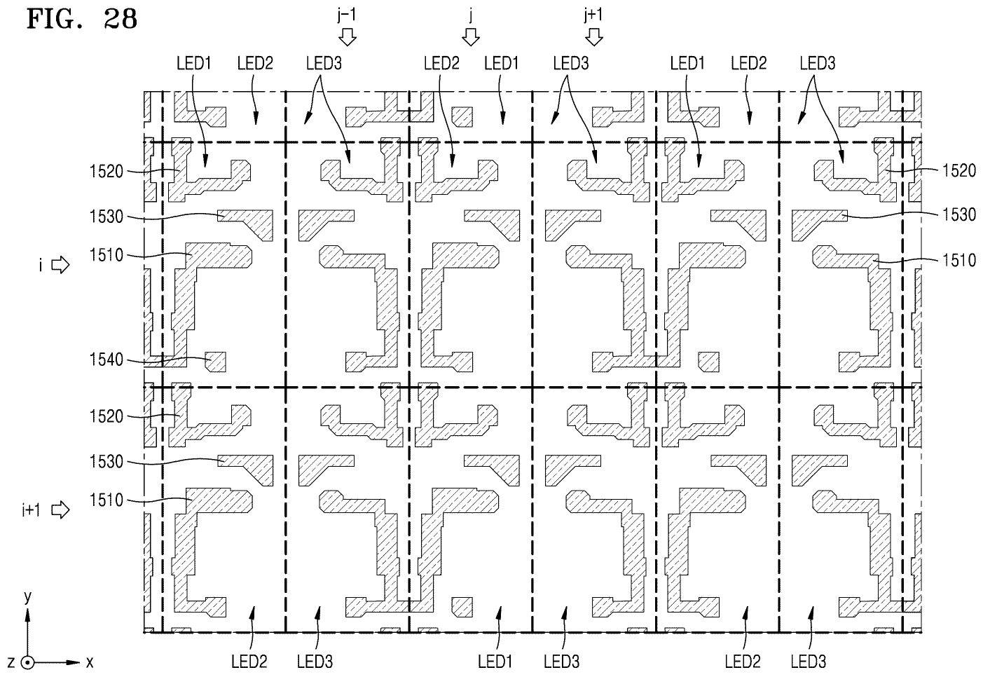

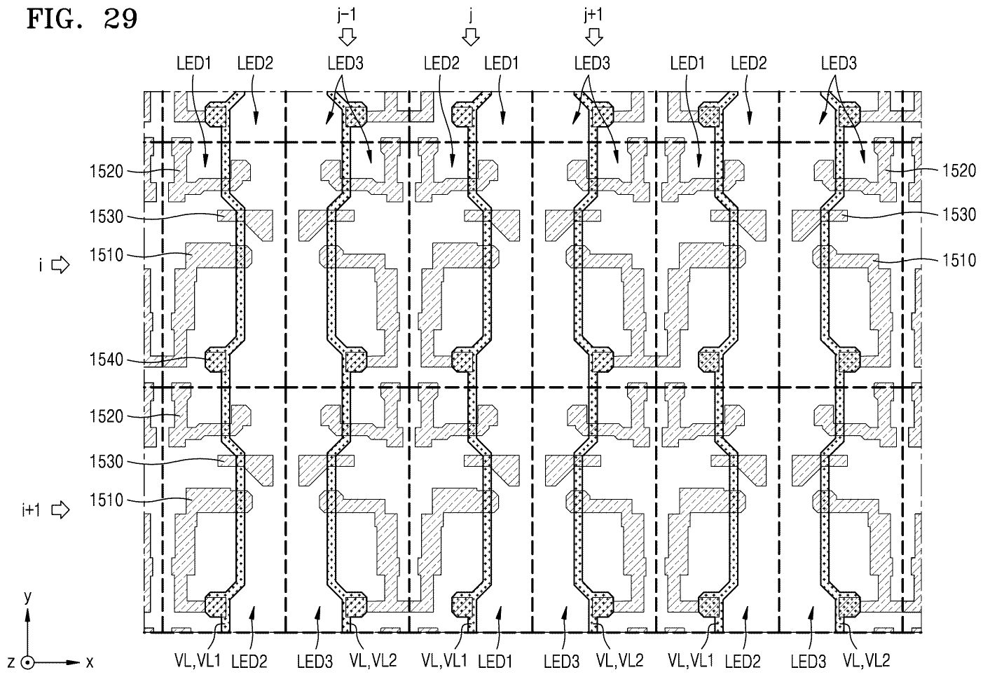

FIG. 28 is a layout diagram schematically illustrating an embodiment of the semiconductor layer patterns 1510, 1520, 1530, and 1540 of the display panel 10 and the electronic apparatus comprising the same, and FIG. 29 is a layout diagram schematically illustrating the positional relationship between the initialization voltage lines VL and the semiconductor layer patterns 1510, 1520, 1530, and 1540 of FIG. 28. For reference, in FIGS. 28 and 29, the first light-emitting element LED1, the second light-emitting element LED2, and the third light-emitting element LED3 represent an area of the pixel circuit to which the first light-emitting element LED1 is electrically connected, an area of the pixel circuit to which the second light-emitting element LED2 is electrically connected, and an area of the pixel circuit to which the third light-emitting element LED3 is electrically connected.

Similar to the display panel 10 and the electronic apparatus comprising the same according to the above-described embodiment with reference to FIGS. 26 and 27, the set of four pixel circuits, that is, the pixel circuit for the first light-emitting element LED1, the pixel circuit for the third light-emitting element LED3, the pixel circuit for the second light-emitting element LED2, and the pixel circuit for the third light-emitting element LED3, may be repeatedly arranged in the +x direction in the i^{th} row. This also applies to the (i+1)^{th} row and other rows. Similarly, in each of the (j−2)^{th} column, j^{th} column, and (j+2)^{th} column, a set of two pixel circuits, that is, the pixel circuit for the first light-emitting element LED1 and the pixel circuit for the second light-emitting element LED2, may be repeatedly arranged in the second direction (y-axis direction), and in each of the (j−1)^{th} column and (j+1)^{th} column, the pixel circuit for the third light-emitting element LED3 may be repeatedly arranged in the second direction (y-axis direction).

Initialization voltage lines VL extending approximately in the second direction (y-axis direction) within the display area DA may be arranged to be spaced apart from each other in the first direction (x-axis direction). For convenience, it may be regarded that the initialization voltage lines VL include the first initialization voltage line VL1 and the second initialization voltage line VL2, and that the first initialization voltage line VL1 and the second initialization voltage line VL2 are alternately arranged in the first direction (x-axis direction). Along each of the first initialization voltage lines VL1, the pixel circuit for the first light-emitting element LED1 and the pixel circuit for the second light-emitting element LED2, i.e., first-color pixel circuit and second-color pixel circuit, may be alternately arranged in the second direction (y-axis direction). Along each of the second initialization voltage lines VL2, pixel circuits for third light-emitting elements LED3, i.e., third-color pixel circuits, may be arranged in the second direction (y-axis direction).

The display panel 10 and the electronic apparatus comprising the same shown in FIGS. 28 and 29 is different from the display panel 10 and the electronic apparatus comprising the same described above with reference to FIGS. 26 and 27 in that the first oxide semiconductor pattern 1510 of each of the first-color pixel circuits, which are pixel circuits for the first light-emitting elements LED1, is electrically connected to the first oxide semiconductor pattern 1510 of the third-color pixel circuit, which is the pixel circuit for the third light-emitting element LED3 disposed in the −x direction from the first-color pixel circuit. A part of the first oxide semiconductor pattern 1510 is an element of the fourth transistor T4 which is the initialization transistor, so that the fourth transistor T4 of each of the first-color pixel circuits may be electrically connected to the fourth transistor T4 of any one of the third-color pixel circuits which is next (adjacent) to the first-color pixel circuit in the first direction (x-axis direction). FIGS. 28 and 29 shows that the first oxide semiconductor pattern 1510 of each of the first-color pixel circuits, which are pixel circuits for the first light-emitting elements LED1, and the first oxide semiconductor pattern 1510 of the third-color pixel circuit, which is the pixel circuit for the third light-emitting element LED3 disposed in the −x direction from the first-color pixel circuit, are unitary as a single body. For reference, the first oxide semiconductor pattern 1510 of each of the second-color pixel circuits, which are pixel circuits for the second light-emitting elements LED2, may have an isolated shape within the area of the second-color pixel circuit.

As described above, in the case of the display panel 10 and the electronic apparatus comprising the same in an embodiment, the pixel circuit for the first light-emitting element LED1 and the pixel circuit for the second light-emitting element LED2, i.e., the first-color pixel circuit and the second-color pixel circuit, are alternately arranged in the second direction (y-axis direction) along each of the first initialization voltage lines VL1. However, the pixel circuit for the second light-emitting element LED2 is electrically connected to the first initialization voltage line VL1, whereas the pixel circuit for the first light-emitting element LED1 is electrically connected to the second initialization voltage line VL2, not the first initialization voltage line VL1. Accordingly, the initialization voltage VINT may be applied to the second light-emitting element LED2 by the first initialization voltage line VL1, and the initialization voltage VINT may be applied to the first light-emitting element LED1 and the third light-emitting element LED3 by the second initialization voltage line VL2. The signal of the initialization voltage VINT applied to the first initialization voltage line VL1 may be different from the signal of the initialization voltage VINT applied to the second initialization voltage line VL2. That is, the electric potential of the initialization voltage VINT applied to the first initialization voltage line VL1 may be different from the electric potential of the initialization voltage VINT applied to the second initialization voltage line VL2.

The optimal initialization voltage VINT for the first light-emitting element LED1 may be different from the optimal initialization voltage VINT for the second light-emitting element LED2. In this situation, the optimal initialization voltage VINT for the first light-emitting element LED1 is not completely identical to the optimal initialization voltage VINT for the third light-emitting element LED3, but may be closer to the optimal initialization voltage VINT for the third light-emitting element LED3 than the optimal initialization voltage VINT for the second light-emitting element LED2. In the display panel 10 and the electronic apparatus comprising the same in embodiments, even though the pixel circuit for the first light-emitting element LED1 and the pixel circuit for the second light-emitting element LED2, that is, the first-color pixel circuit and the second-color pixel circuit, are alternately arranged in the second direction (y-axis direction) along each of the first initialization voltage lines VL1, the display panel 10 and the electronic apparatus comprising the same is capable of displaying high-quality images because only the second-color pixel circuit is electrically connected to the first initialization voltage line VL1 and the first-color pixel circuit is electrically connected to the second initialization voltage line VL2 to which the third-color pixel circuit is electrically connected.

When the second-color pixel circuit is electrically connected to the first initialization voltage line VL1, it means that one end of the fourth transistor T4 of the second-color pixel circuit, which is the second initialization transistor of the second-color pixel circuit, is electrically connected to the first initialization voltage line VL1. When the first-color pixel circuit and the third-color pixel circuit are electrically connected to the second initialization voltage line VL2, it means that one end of the fourth transistor T4 of the first-color pixel circuit, which is the second initialization transistor of the first-color pixel circuit, and one end of the fourth transistor T4 of the third-color pixel circuit, which is the second initialization transistor of the third-color pixel circuit, are electrically connected to the second initialization voltage line VL2. In this situation, an opposite end of the fourth transistor T4 of the first-color pixel circuit may be electrically connected to the pixel electrode 210 of the first light-emitting element LED1, which is an element emitting first-color light, an opposite end of the fourth transistor T4 of the second-color pixel circuit may be electrically connected to the pixel electrode 210 of the second light-emitting element LED2, which is an element emitting second-color light, and the opposite end of the fourth transistor T4 of the third-color pixel circuit may be electrically connected to the pixel electrode 210 of the third light-emitting element LED3, which is an element emitting third-color light.

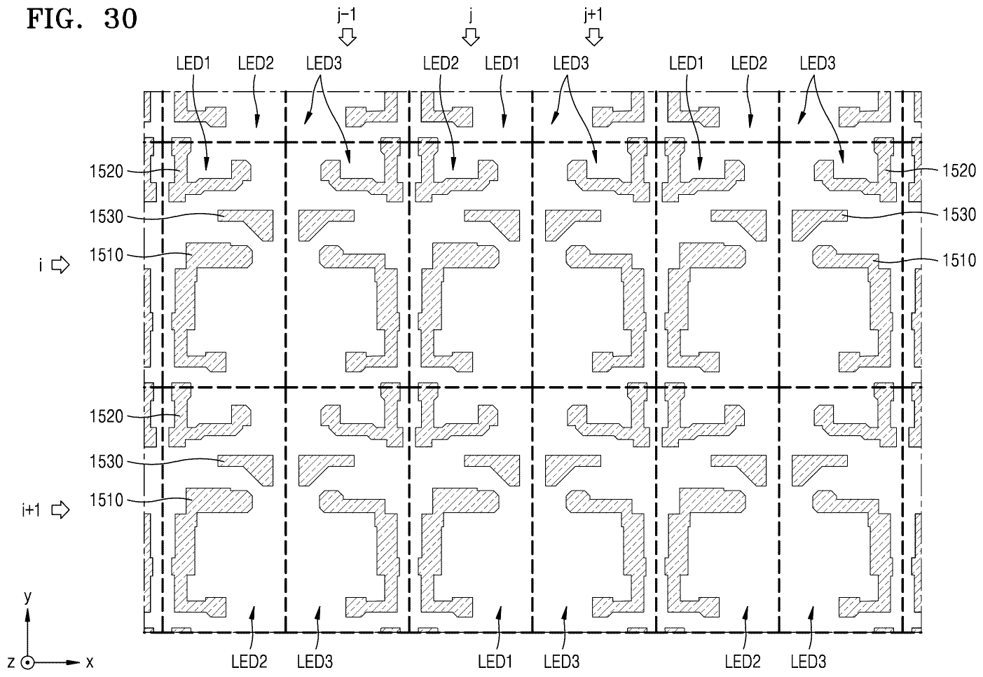

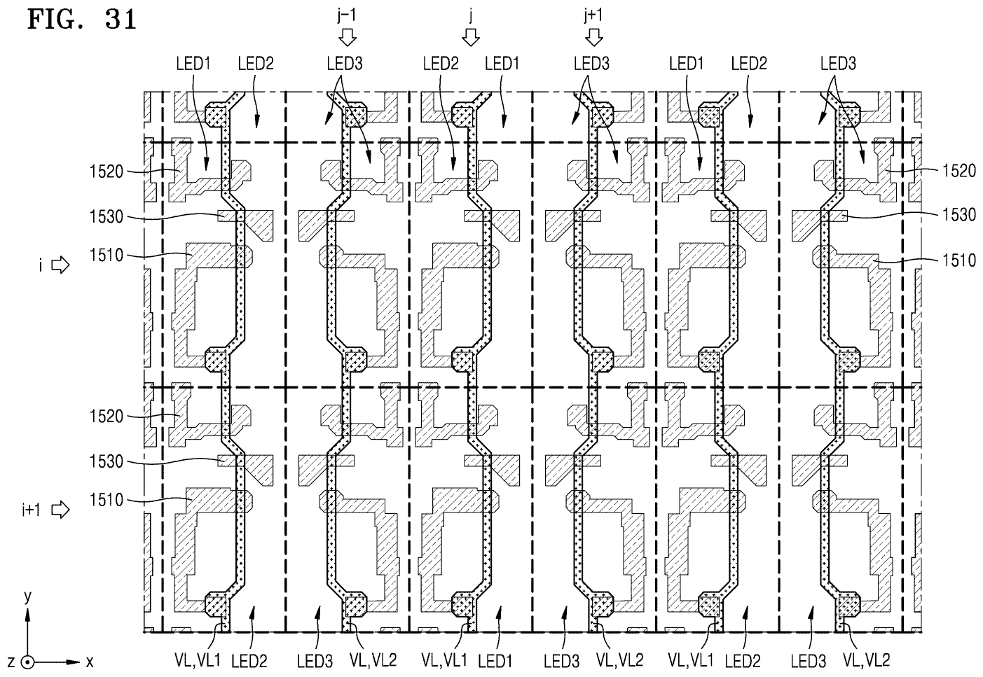

FIG. 30 is a layout diagram schematically illustrating an embodiment of the semiconductor layer patterns 1510, 1520, 1530, and 1540 of the display panel 10 and the electronic apparatus comprising the same, FIG. 31 is a layout diagram schematically illustrating the positional relationship between the initialization voltage lines VL and the semiconductor layer patterns 1510, 1520, 1530, and 1540 of FIG. 30. For reference, in FIGS. 30 and 31, the first light-emitting element LED1, the second light-emitting element LED2, and the third light-emitting element LED3 represent an area of the pixel circuit to which the first light-emitting element LED1 is electrically connected, an area of the pixel circuit to which the second light-emitting element LED2 is electrically connected, and an area of the pixel circuit to which the third light-emitting element LED3 is electrically connected.

Similar to the display panel 10 and the electronic apparatus comprising the same which are described above with reference to FIGS. 26 and 27, a set of four pixel circuits, that is, the pixel circuit for the first light-emitting element LED1, the pixel circuit for the third light-emitting element LED3, the pixel circuit for the second light-emitting element LED2, and the pixel circuit for the third light-emitting element LED3, may be repeatedly arranged in the +x direction in the i^{th} row. This also applies to the (i+1)^{th} row and other rows. Similarly, in each of the (j−2)^{th} column, j^{th} column, and (j+2)^{th} column, a set of two pixel circuits, that is, the pixel circuit for the first light-emitting element LED1 and the pixel circuit for the second light-emitting element LED2, may be repeatedly arranged in the second direction (y-axis direction), and in each of the (j−1)^{th} column and (j+1)^{th} column, the pixel circuit for the third light-emitting element LED3 may be repeatedly arranged in the second direction (y-axis direction).

Initialization voltage lines VL extending approximately in the second direction (y-axis direction) within the display area DA may be arranged to be spaced apart from each other in the first direction (x-axis direction). For convenience, it may be regarded that the initialization voltage lines VL include the first initialization voltage line VL1 and the second initialization voltage line VL2, and that the first initialization voltage line VL1 and the second initialization voltage line VL2 are alternately arranged in the first direction (x-axis direction). Along each of the first initialization voltage lines VL1, the pixel circuit for the first light-emitting element LED1 and the pixel circuit for the second light-emitting element LED2, i.e., the first-color pixel circuit and the second-color pixel circuit, may be alternately arranged in the second direction (y-axis direction). Along each of the second initialization voltage lines VL2, pixel circuits for third light-emitting elements LED3, i.e., third-color pixel circuits, may be arranged in the second direction (y-axis direction).

The display panel 10 and the electronic apparatus comprising the same shown in FIGS. 30 and 31 is different from the display panel 10 and the electronic apparatus comprising the same described above with reference to FIGS. 26 to 29 in that the first oxide semiconductor pattern 1510 of each of the first-color pixel circuits, which are pixel circuits for the first light-emitting elements LED1, has an isolated shape within the area of the first-color pixel circuit, the first oxide semiconductor pattern 1510 of each of the second-color pixel circuits, which are pixel circuits for the second light-emitting elements, has an isolated shape within the area of the second-color pixel circuit, and the first oxide semiconductor pattern 1510 of each of the third-color pixel circuits, which are pixel circuits for the third light-emitting elements LED3, has an isolated shape within the area of the third-color pixel circuit.

As described above, in the case of the display panel 10 and the electronic apparatus comprising the same in an embodiment, the pixel circuit for the first light-emitting element LED1 and the pixel circuit for the second light-emitting element LED2, i.e., the first-color pixel circuit and the second-color pixel circuit, are alternately arranged along each of the first initialization voltage lines VL1, in the second direction (y-axis direction). Both the pixel circuit for the first light-emitting element LED1 and the pixel circuit for the second light-emitting element LED2 are electrically connected to the first initialization voltage line VL1. Pixel circuits for the third light-emitting elements LED3, i.e., third-color pixel circuits, are arranged along each of the second initialization voltage lines VL2, in the second direction (y-axis direction). The pixel circuits for the third light-emitting elements LED3 are electrically connected to the second initialization voltage line VL2. Accordingly, the initialization voltage VINT may be applied to the first light-emitting element LED1 and the second light-emitting element LED2 by the first initialization voltage line VL1, and the initialization voltage VINT may be applied to the third light-emitting element LED3 by the second initialization voltage line VL2. The signal of the initialization voltage VINT applied to the first initialization voltage line VL1 may be different from the signal of the initialization voltage VINT applied to the second initialization voltage line VL2. That is, the electric potential of the initialization voltage VINT applied to the first initialization voltage line VL1 may be different from the electric potential of the initialization voltage VINT applied to the second initialization voltage line VL2.

The optimal initialization voltage VINT for the first light-emitting element LED1 may be different from the optimal initialization voltage VINT for the second light-emitting element LED2. In this situation, the optimal initialization voltage VINT for the first light-emitting element LED1 is not completely identical to the optimal initialization voltage VINT for the second light-emitting element LED2, but may be closer to the optimal initialization voltage VINT for the second light-emitting element LED2 than the optimal initialization voltage VINT for the third light-emitting element LED3. In the display panel 10 and the electronic apparatus comprising the same in embodiments, the pixel circuit for the first light-emitting element LED1 and the pixel circuit for the second light-emitting element LED2, that is, the first-color pixel circuit and the second-color pixel circuit, are alternately arranged in the second direction (y-axis direction) along each of the first initialization voltage lines VL1, and the first-color pixel circuit and the second-color pixel circuit are electrically connected to the first initialization voltage line VL1. And the third-color pixel circuit is electrically connected to the second initialization voltage line VL2. Through this configuration, the display panel 10 and the electronic apparatus comprising the same capable of displaying high-quality images may be implemented.

When the first-color pixel circuit and the second-color pixel circuit are electrically connected to the first initialization voltage line VL1, it means that one end of the fourth transistor T4 of the first-color pixel circuit, which is the second initialization transistor of the first-color pixel circuit, and one end of the fourth transistor T4 of the second-color pixel circuit, which is the second initialization transistor of the second-color pixel circuit, are electrically connected to the first initialization voltage line VL1. When the third-color pixel circuit is electrically connected to the second initialization voltage line VL2, it means that one end of the fourth transistor T4 of the third-color pixel circuit, which is the second initialization transistor of the third-color pixel circuit, is electrically connected to the second initialization voltage line VL2. In this situation, an opposite end of the fourth transistor T4 of the first-color pixel circuit may be electrically connected to the pixel electrode 210 of the first light-emitting element LED1, which is an element emitting first-color light, an opposite end of the fourth transistor T4 of the second-color pixel circuit may be electrically connected to the pixel electrode 210 of the second light-emitting element LED2, which is an element emitting second-color light, and an opposite end of the fourth transistor T4 of the third-color pixel circuit may be electrically connected to the pixel electrode 210 of the third light-emitting element LED3, which is an element emitting third-color light.

FIGS. 26 to 31 show that the set of four pixel circuits, that is, the pixel circuit for the first light-emitting element LED1, the pixel circuit for the third light-emitting element LED3, the pixel circuit for the second light-emitting element LED2, and the pixel circuit for the third light-emitting element LED3, is repeatedly arranged in the +x direction in the i^{th} row. FIGS. 26 to 31 also show that in each of the (j−2)^{th} column, j^{th} column, and (j+2)^{th} column, the set of two pixel circuits, that is, the pixel circuit for the first light-emitting element LED1 and the pixel circuit for the second light-emitting element LED2, are repeatedly arranged in the second direction (y-axis direction), and in each of the (j−1)^{th} column and (j+1)^{th} column, the pixel circuit for the third light-emitting element LED3 is repeatedly arranged in the second direction (y-axis direction). However, the disclosure is not limited thereto.

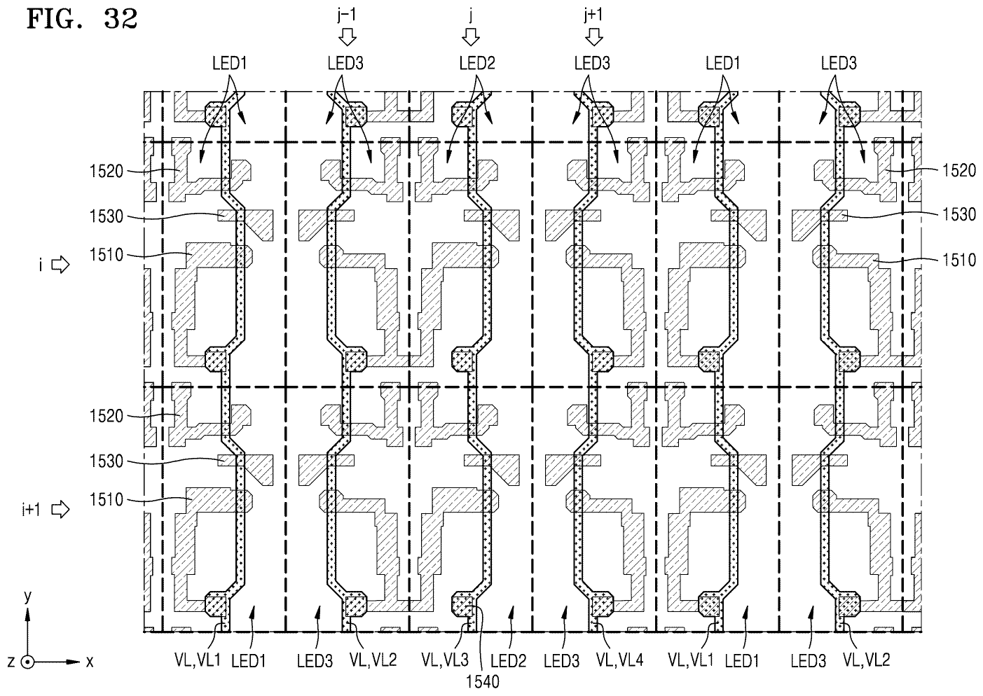

In an embodiment, as shown in FIG. 32, which is a layout diagram schematically illustrating the positional relationship between semiconductor layer patterns 1510, 1520, 1530, and 1540 and initialization voltage lines VL of the display panel 10 and the electronic apparatus comprising the same in an embodiment, the set of four pixel circuits, that is, the pixel circuit for the first light-emitting element LED1, the pixel circuit for the third light-emitting element LED3, the pixel circuit for the second light-emitting element LED2, and the pixel circuit for the third light-emitting element LED3, may be repeatedly arranged in the +x direction in each of the rows, and pixel circuits for light-emitting elements that emit light of the same color may be repeatedly arranged in each column, for example. In an embodiment, all pixels arranged in the y-axis direction in the (j−2)^{th} column may be pixel circuits for the first light-emitting element LED1, all pixels arranged in the y-axis direction in the (j−1)^{th} column may be pixel circuits for the third light-emitting element LED3, all pixels arranged in the y-axis direction in the j^{th} column may be pixel circuits for the second light-emitting element LED2, and all pixels arranged in the y-axis direction in the (j+1)^{th} column may be pixel circuits for the third light-emitting element LED3, for example.

For reference, in FIG. 32, the first light-emitting element LED1, the second light-emitting element LED2, and the third light-emitting element LED3 represent an area of the pixel circuit to which the first light-emitting element LED1 is electrically connected, an area of the pixel circuit to which the second light-emitting element LED2 is electrically connected, and an area of the pixel circuit to which the third light-emitting element LED3 is electrically connected. The first light-emitting element may be a diode that emits red light, the second light-emitting element LED2 may be a diode that emits blue light, and the third light-emitting element LED3 may be a diode that emits green light.

Initialization voltage lines VL extending approximately in the second direction (y-axis direction) within the display area DA may be arranged to be spaced apart from each other in the first direction (x-axis direction). For convenience, it may be regarded that the initialization voltage lines VL include the first initialization voltage lines VL1, the second initialization voltage lines VL2, third initialization voltage lines VL3, and fourth initialization voltage lines VL4, and a set of the first initialization voltage line VL1, the second initialization voltage line VL2, the third initialization voltage line VL3, and the fourth initialization voltage line VL4 may be repeatedly arranged in the first direction (x-axis direction). In this situation, the pixel circuits for the first light-emitting elements LED1, i.e., first-color pixel circuits, may be arranged along each of the first initialization voltage lines VL1 in the second direction (y-axis direction), the pixel circuits for the third light-emitting elements LED3, i.e., third-color pixel circuits, may be arranged along each of the second initialization voltage lines VL2 in the second direction (y-axis direction), the pixel circuits for the second light-emitting elements LED2, i.e., second-color pixel circuits, may be arranged along each of the third initialization voltage lines VL3 in the second direction (y-axis direction), and the pixel circuits for the third light-emitting elements LED3, i.e., third-color pixel circuits, may be arranged along each of the fourth initialization voltage lines VL4 in the second direction (y-axis direction).

The first oxide semiconductor pattern 1510 of each of the second-color pixel circuits, which are pixel circuits for the second light-emitting elements LED2, may be electrically connected to the first oxide semiconductor pattern 1510 of the third-color pixel circuit, which is the pixel circuit for the third light-emitting element LED3 disposed in the −x direction from the second-color pixel circuit. Because a part of the first oxide semiconductor pattern 1510 is an element of the fourth transistor T4 which is the initialization transistor, the fourth transistor T4 of each of the second-color pixel circuits may be electrically connected to the fourth transistor T4 of any one of the third-color pixel circuits which is next (adjacent) to the second-color pixel circuit in the first direction (x-axis direction). FIG. 32 shows that the first oxide semiconductor pattern 1510 of each of the second-color pixel circuits, which are pixel circuits for the second light-emitting elements LED2, and the first oxide semiconductor pattern 1510 of the third-color pixel circuit, which is the pixel circuit for the third light-emitting element LED3 disposed in the −x direction from the second-color pixel circuit are unitary as a single body. For reference, the first oxide semiconductor pattern 1510 of each of the first-color pixel circuits, which are pixel circuits for the first light-emitting elements LED1, may have an isolated shape within the area of the first-color pixel circuit.

The optimal initialization voltage VINT for the first light-emitting element LED1 may be different from the optimal initialization voltage VINT for the second light-emitting element LED2. In this situation, the optimal initialization voltage VINT for the second light-emitting element LED2 is not completely identical to the optimal initialization voltage VINT for the third light-emitting element LED3, but may be closer to the optimal initialization voltage VINT for the third light-emitting element LED3 than the optimal initialization voltage VINT for the first light-emitting element LED1. In the case of the display panel 10 and the electronic apparatus comprising the same in an embodiment, the pixel circuits for the first light-emitting elements LED1 disposed in the (j−2)^{th} column are electrically connected to the first initialization voltage line VL1 disposed in the (j−2)^{th} column, and the pixel circuits for the second light-emitting elements LED2 disposed in the j^{th} column are electrically connected to the second initialization voltage line VL2 disposed in the (j−1)^{th} column to which the pixel circuits for the third light-emitting elements LED3 disposed in the (j−1)^{th} column are electrically connected, thereby the display panel 10 and the electronic apparatus comprising the same capable of displaying high-quality images may be implemented.

For reference, the pixel circuits for the third light-emitting elements LED3 disposed in the (j+1)^{th} column may be electrically connected to the fourth initialization voltage line VL4 disposed in the (j+1)^{th} column. The third initialization voltage line VL3 disposed in the j^{th} column may be electrically connected to the fourth oxide semiconductor pattern 1540, which may have an isolated shape and may be regarded as a kind of dummy electrode. The third initialization voltage line VL3 may be a dummy line to which no electrical signal is applied, or may be a dummy line to which a constant electrical signal is applied when desired.

When the first-color pixel circuit is electrically connected to the first initialization voltage line VL1, it means that one end of the fourth transistor T4 of the first-color pixel circuit, which is the second initialization transistor of the first-color pixel circuit, is electrically connected to the first initialization voltage line VL1. When the second-color pixel circuit and the third-color pixel circuit are electrically connected to the second initialization voltage line VL2, it means that one end of the fourth transistor T4 of the second-color pixel circuit, which is the second initialization transistor of the second-color pixel circuit, and one end of the fourth transistor T4 of the third-color pixel circuit, which is the second initialization transistor of the third-color pixel circuit, are electrically connected to the second initialization voltage line VL2. In this situation, the opposite end of the fourth transistor T4 of the first-color pixel circuit may be electrically connected to the pixel electrode 210 of the first light-emitting element LED1, which is an element emitting first-color light, the opposite end of the fourth transistor T4 of the second-color pixel circuit may be electrically connected to the pixel electrode 210 of the second light-emitting element LED2, which is an element emitting second-color light, and the opposite end of the fourth transistor T4 of the third-color pixel circuit may be electrically connected to the pixel electrode 210 of the third light-emitting element LED3, which is an element emitting third-color light.

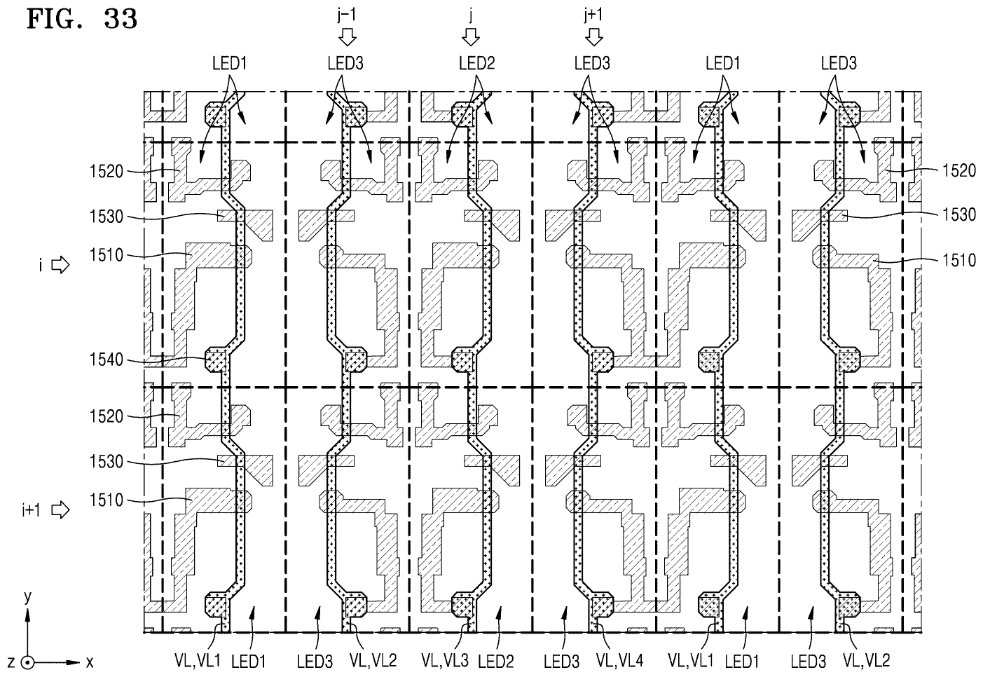

FIG. 33 is a layout diagram schematically illustrating an embodiment of the positional relationship between semiconductor layer patterns 1510, 1520, 1530, and 1540 and initialization voltage lines VL of the display panel 10 and the electronic apparatus comprising the same. For reference, in FIG. 33, the first light-emitting element LED1, the second light-emitting element LED2, and the third light-emitting element LED3 represent an area of the pixel circuit to which the first light-emitting element LED1 is electrically connected, an area of the pixel circuit to which the second light-emitting element LED2 is electrically connected, and an area of the pixel circuit to which the third light-emitting element LED3 is electrically connected.

The arrangement of the pixel circuit for the first light-emitting element LED1, the pixel circuit for the second light-emitting element LED2, and the pixel circuit for the third light-emitting element LED3 in the display panel 10 may be the same as that described above with reference to FIG. 32. The display panel 10 shown in FIG. 33 is different from the display panel 10 described above with reference to FIG. 32 in the shape of the semiconductor layer.

Specifically, the first oxide semiconductor pattern 1510 of each of the first-color pixel circuits, which are pixel circuits for the first light-emitting elements LED1, may be electrically connected to the first oxide semiconductor pattern 1510 of the third-color pixel circuit, which is the pixel circuit for the third light-emitting element LED3 disposed in the −x direction from the first-color pixel circuit. Because a part of the first oxide semiconductor pattern 1510 is an element of the fourth transistor T4 which is the initialization transistor, the fourth transistor T4 of each of the first-color pixel circuits may be electrically connected to the fourth transistor T4 of any one of the third-color pixel circuits which is next (adjacent) to the first-color pixel circuit in the first direction (x-axis direction). FIG. 33 shows that the first oxide semiconductor pattern 1510 of each of the first-color pixel circuits, which are pixel circuits for the first light-emitting elements LED1, and the first oxide semiconductor pattern 1510 of the third-color pixel circuit, which is the pixel circuit for the third light-emitting element LED3 disposed in the −x direction from the first-color pixel circuit are unitary as a single body. For reference, the first oxide semiconductor pattern 1510 of each of the second-color pixel circuits, which are pixel circuits for the second light-emitting elements LED2, may have an isolated shape within the area of the second-color pixel circuit.

The optimal initialization voltage VINT for the first light-emitting element LED1 may be different from the optimal initialization voltage VINT for the second light-emitting element LED2. In this situation, the optimal initialization voltage VINT for the first light-emitting element LED1 is not completely identical to the optimal initialization voltage VINT for the third light-emitting element LED3, but may be closer to the optimal initialization voltage VINT for the third light-emitting element LED3 than the optimal initialization voltage VINT for the second light-emitting element LED2. In the case of the display panel 10 and the electronic apparatus comprising the same in an embodiment, the pixel circuits for the second light-emitting elements LED2 disposed in the j^{th} column are electrically connected to the third initialization voltage line VL3 disposed in the j^{th} column, and the pixel circuits for the first light-emitting elements LED1 disposed in the (j+2)^{th} column are electrically connected to the fourth initialization voltage line VL4 disposed in the (j+1)^{th} column to which the pixel circuits for the third light-emitting elements LED3 disposed in the (j+1)^{th} column are electrically connected, thereby the display panel 10 and the electronic apparatus comprising the same capable of displaying high-quality images may be implemented.

For reference, the pixel circuits for the third light-emitting elements LED3 disposed in the (j−1)^{th} column may be electrically connected to the second initialization voltage line VL2 disposed in the (j−1)^{th} column. The first initialization voltage line VL1 disposed in the (j+2)^{th} column may be electrically connected to the fourth oxide semiconductor pattern 1540, which may have an isolated shape and may be regarded as a kind of dummy electrode. The first initialization voltage line VL1 may be a dummy line to which no electrical signal is applied, or may be a dummy line to which a constant electrical signal is applied when desired.

When the second-color pixel circuit is electrically connected to the third initialization voltage line VL3, it means that one end of the fourth transistor T4 of the second-color pixel circuit, which is the second initialization transistor of the second-color pixel circuit, is electrically connected to the third initialization voltage line VL3. When the first-color pixel circuit and the third-color pixel circuit are electrically connected to the fourth initialization voltage line VL4, it means that one end of the fourth transistor T4 of the first-color pixel circuit, which is the second initialization transistor of the first-color pixel circuit, and one end of the fourth transistor T4 of the third-color pixel circuit, which is the second initialization transistor of the third-color pixel circuit, are electrically connected to the fourth initialization voltage line VL4. In this situation, an opposite end of the fourth transistor T4 of the first-color pixel circuit may be electrically connected to the pixel electrode 210 of the first light-emitting element LED1, which is an element emitting first-color light, an opposite end of the fourth transistor T4 of the second-color pixel circuit may be electrically connected to the pixel electrode 210 of the second light-emitting element LED2, which is an element emitting second-color light, and an opposite end of the fourth transistor T4 of the third-color pixel circuit may be electrically connected to the pixel electrode 210 of the third light-emitting element LED3, which is an element emitting third-color light.

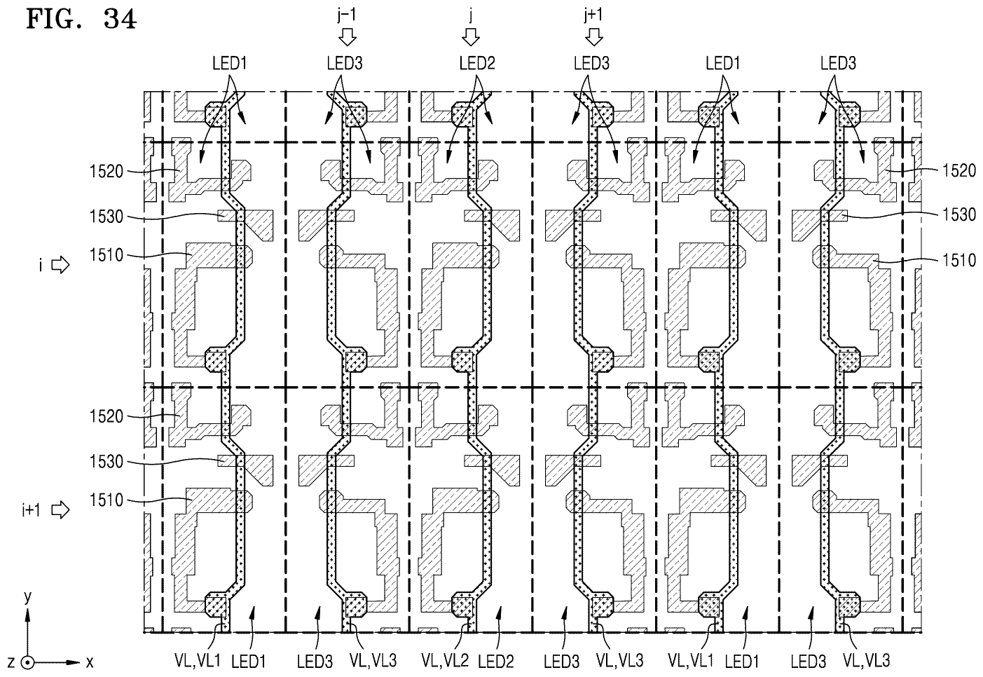

FIG. 34 is a layout diagram schematically illustrating an embodiment of the positional relationship between semiconductor layer patterns 1510, 1520, 1530, and 1540 and initialization voltage lines VL of the display panel 10 and the electronic apparatus comprising the same. For reference, in FIG. 34, the first light-emitting element LED1, the second light-emitting element LED2, and the third light-emitting element LED3 represent an area of the pixel circuit to which the first light-emitting element LED1 is electrically connected, an area of the pixel circuit to which the second light-emitting element LED2 is electrically connected, and an area of the pixel circuit to which the third light-emitting element LED3 is electrically connected.

The arrangement of the pixel circuit for the first light-emitting element LED1, the pixel circuit for the second light-emitting element LED2, and the pixel circuit for the third light-emitting element LED3 in the display panel 10 may be the same as that described above with reference to FIG. 32.

The display panel 10 and the electronic apparatus comprising the same shown in FIG. 34 is different from the display panel 10 and the electronic apparatus comprising the same described above with reference to FIGS. 32 and 33 in that the first oxide semiconductor pattern 1510 of each of the first-color pixel circuits, which are pixel circuits for the first light-emitting elements LED1, has an isolated shape within the area of the first-color pixel circuit, the first oxide semiconductor pattern 1510 of each of the second-color pixel circuits, which are pixel circuits for the second light-emitting elements LED2, has an isolated shape within the area of the second-color pixel circuit, and the first oxide semiconductor pattern 1510 of each of the third-color pixel circuits, which are pixel circuits for the third light-emitting elements LED3, has an isolated shape within the area of the third-color pixel circuit.

In the case of the display panel 10 and the electronic apparatus comprising the same in an embodiment, the pixel circuits for the first light-emitting elements LED1 disposed in the (j−2)^{th} column are electrically connected to the first initialization voltage line VL1 disposed in the (j−2)^{th} column, the pixel circuits for the third light-emitting elements LED3 disposed in the (j−1)^{th} column are electrically connected to the third initialization voltage line VL3 disposed in the (j−1)^{th} column, the pixel circuits for the second light-emitting elements LED3 disposed in the j^{th} column are electrically connected to the second initialization voltage line VL3 disposed in the j^{th} column, and the pixel circuits for the third light-emitting elements LED3 disposed in the (j+1)^{th} column are electrically connected to the third initialization voltage line VL3 disposed in the (j+1)^{th} column. Accordingly, the initialization voltage VINT may be applied to the first light-emitting element LED1 by the first initialization voltage line VL1, the initialization voltage VINT may be applied to the second light-emitting element LED2 by the second initialization voltage line VL2, and the initialization voltage VINT may be applied to the third light-emitting element LED3 by the third initialization voltage line VL3.

The signal of the initialization voltage VINT applied to the first initialization voltage line VL1 may be different from the signal of the initialization voltage VINT applied to the second initialization voltage line VL2 and the signal of the initialization voltage VINT applied to the third initialization voltage line VL3. That is, the electric potential of the initialization voltage VINT applied to the first initialization voltage line VL1 may be different from the electric potential of the initialization voltage VINT applied to the second initialization voltage line VL2 and the electric potential of the initialization voltage VINT applied to the third initialization voltage line VL3. In addition, the signal of the initialization voltage VINT applied to the second initialization voltage line VL2 may be different from the signal of the initialization voltage VINT applied to the third initialization voltage line VL3. That is, the electric potential of the initialization voltage VINT applied to the second initialization voltage line VL2 may be different from the electric potential of the initialization voltage VINT applied to the third initialization voltage line VL3.

The optimal initialization voltage VINT for the first light-emitting element LED1, the optimal initialization voltage VINT for the second light-emitting element LED2, and the optimal initialization voltage VINT for the third light-emitting element LED3 may be different from one another. In the case of the display panel 10 and the electronic apparatus comprising the same in an embodiment, the initialization voltage VINT that is optimal for the first light-emitting element LED1 may be applied to the first light-emitting element LED1, the initialization voltage VINT that is optimal for the second light-emitting element LED2 may be applied to the second light-emitting element LED2, and the initialization voltage (VINT) that is optimal for the third light-emitting element LED3 may be applied to the third light-emitting element LED3. Through this configuration, the display panel 10 and the electronic apparatus capable of displaying high-quality images may be implemented.

Clearly, even in the case shown in FIG. 34, when desired, the same electrical signal may be applied to the second initialization voltage line VL2 and the third initialization voltage line VL3 and a different electrical signal may be applied to the first initialization voltage line VL1 so as to produce the same effect as the case shown in FIG. 32, or the same electrical signal may be applied to the first initialization voltage line VL1 and the third initialization voltage line VL3 and a different electrical signal may be applied to the second initialization voltage line VL2 so as to produce the same effect as the case shown in FIG. 33.

So far, the structure of the display panel 10 has been mainly described, but the disclosure is not limited thereto. The electronic device 1 comprising such a display panel 10 may also be said to fall within the scope of the disclosure.

In embodiments as described above, the display panel and the electronic apparatus comprising the same capable of displaying high-quality images may be implemented. However, the scope of the disclosure is not limited by the above effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display panel comprising:
first initialization voltage lines and second initialization voltage lines which are alternately arranged along a first direction in a display area, each of the first initialization voltage lines and the second initialization voltage lines extending in a second direction crossing the first direction;
first-color pixel circuits and second-color pixel circuits alternately arranged along the first initialization voltage lines; and
third-color pixel circuits arranged along the second initialization voltage lines,
wherein an initialization transistor of each of the second-color pixel circuits is electronically connected to an initialization transistor of one third-color pixel circuit among the third-color pixel circuits, and
the one third-color pixel circuit is disposed next to the initialization transistor of each of the second-color pixel circuits in the first direction.

2. The display panel of claim 1, wherein
a semiconductor layer of the initialization transistor of each of the second-color pixel circuits is electrically connected to a semiconductor layer of the initialization transistor of the one third-color pixel circuit.

3. The display panel of claim 1, wherein
a semiconductor layer of the initialization transistor of each of the second-color pixel circuits and a semiconductor layer of the initialization transistor of the one third-color pixel circuit are unitary as a single body.

4. The display panel of claim 1, wherein
the first initialization voltage lines are electrically connected to one end of an initialization transistor of each of the first-color pixel circuits, and
the second initialization voltage lines are electrically connected to one end of the initialization transistor of each of the second-color pixel circuits and one end of an initialization transistor of each of the third-color pixel circuits.

5. The display panel of claim 4, wherein
an opposite end of the initialization transistor of each of the first-color pixel circuits opposite to the end of the initialization transistor of each of the first-color pixel circuits is electrically connected to an element which emits first-color light,
an opposite end of the initialization transistor of each of the second-color pixel circuits opposite to the one end of the initialization transistor of each of the second-color pixel circuits is electrically connected to an element which emits second-color light, and
an opposite end of the initialization transistor of each of the third-color pixel circuits opposite to the one end of the initialization transistor of each of the third-color pixel circuits is electrically connected to an element which emits third-color light.

6. The display panel of claim 4, wherein
an opposite end of the initialization transistor of each of the first-color pixel circuits opposite to the end of the initialization transistor of each of the first-color pixel circuits is electrically connected to a pixel electrode of an element which emits first-color light, an opposite end of the initialization transistor of each of the second-color pixel circuits opposite to the one end of the initialization transistor of each of the second-color pixel circuits is electrically connected to a pixel electrode of an element which emits second-color light, and an opposite end of the initialization transistor of each of the third-color pixel circuits opposite to the one end of the initialization transistor of each of the third-color pixel circuits is electrically connected to a pixel electrode of an element which emits third-color light.

7. The display panel of claim 1, wherein
each of the first-color pixel circuits is electrically connected to an element which emits red light, each of the second-color pixel circuits is electrically connected to an element which emits blue light, and each of the third-color pixel circuits is electrically connected to an element which emits green light.

8. The display panel of claim 1, wherein
each of the first-color pixel circuits is electrically connected to an element which emits blue light, each of the second-color pixel circuits is electrically connected to an element which emits red light, and each of the third-color pixel circuits is electrically connected to an element which emits green light.

9. An electronic apparatus comprising:
a display panel comprising:
first initialization voltage lines and second initialization voltage lines which are alternately arranged along a first direction in a display area, each of the first initialization voltage lines and the second initialization voltage lines extending in a second direction crossing the first direction;
first-color pixel circuits and second-color pixel circuits alternately arranged along the first initialization voltage lines; and
third-color pixel circuits arranged along the second initialization voltage lines; and
a lower cover forming an exterior of the electronic apparatus and defining an opening which exposes a portion of the display panel,
wherein an initialization transistor of each of the second-color pixel circuits is electronically connected to an initialization transistor of one third-color pixel circuit among the third-color pixel circuits, and
the one third-color pixel circuit is disposed next to the initialization transistor of each of the second-color pixel circuits in the first direction.

10. The electronic apparatus of claim 9, wherein
a semiconductor layer of the initialization transistor of each of the second-color pixel circuits is electrically connected to a semiconductor layer of the initialization transistor of the one third-color pixel circuit.

11. The electronic apparatus of claim 9, wherein
a semiconductor layer of the initialization transistor of each of the second-color pixel circuits and a semiconductor layer of the initialization transistor of the one third-color pixel circuit are unitary as a single body.

12. The electronic apparatus of claim 9, wherein
the first initialization voltage lines are electrically connected to one end of an initialization transistor of each of the first-color pixel circuits and one end of the initialization transistor of each of the second-color pixel circuits, and
the second initialization voltage lines are electrically connected to one end of an initialization transistor of each of the third-color pixel circuits.

13. The electronic apparatus of claim 12, wherein
an opposite end of the initialization transistor of each of the first-color pixel circuits opposite to the end of the initialization transistor of each of the first-color pixel circuits is electrically connected to an element which emits first-color light, an opposite end of the initialization transistor of each of the second-color pixel circuits opposite to the one end of the initialization transistor of each of the second-color pixel circuits is electrically connected to an element which emits second-color light, and an opposite end of the initialization transistor of each of the third-color pixel circuits opposite to the one end of the initialization transistor of each of the third-color pixel circuits is electrically connected to an element which emits third-color light.

14. The electronic apparatus of claim 12, wherein
an opposite end of the initialization transistor of each of the first-color pixel circuits opposite to the end of the initialization transistor of each of the first-color pixel circuits is electrically connected to a pixel electrode of an element which emits first-color light, an opposite end of the initialization transistor of each of the second-color pixel circuits opposite to the one end of the initialization transistor of each of the second-color pixel circuits is electrically connected to a pixel electrode of an element which emits second-color light, and an opposite end of the initialization transistor of each of the third-color pixel circuits opposite to the one end of the initialization transistor of each of the third-color pixel circuits is electrically connected to a pixel electrode of an element which emits third-color light.

15. The electronic apparatus of claim 9, wherein
each of the first-color pixel circuits is electrically connected to an element which emits red light, each of the second-color pixel circuits is electrically connected to an element which emits blue light, and each of the third-color pixel circuits is electrically connected to an element which emits green light.

16. The electronic apparatus of claim 9, wherein
each of the first-color pixel circuits is electrically connected to an element which emits blue light, each of the second-color pixel circuits is electrically connected to an element which emits red light, and each of the third-color pixel circuits is electrically connected to an element which emits green light.

17. The electronic apparatus of claim 9, wherein
a signal applied to the first initialization voltage lines is different from a signal applied to the second initialization voltage lines.

18. The electronic apparatus of claim 9, wherein
electric potential of a signal applied to the first initialization voltage lines is different from electric potential of a signal applied to the second initialization voltage lines.

19. An electronic apparatus comprising:
first initialization voltage lines and second initialization voltage lines which are alternately arranged along a first direction in a display area, each of the first initialization voltage lines and the second initialization voltage lines extending in a second direction crossing the first direction;
first-color pixel circuits and second-color pixel circuits alternately arranged along the first initialization voltage lines; and
third-color pixel circuits arranged along the second initialization voltage lines,
wherein a signal applied to the first initialization voltage lines is different from a signal applied to the second initialization voltage lines.

20. The electronic apparatus of claim 19, wherein
the first initialization voltage lines are electrically connected to one end of an initialization transistor of each of the first-color pixel circuits and one end of the initialization transistor of each of the second-color pixel circuits, and
the second initialization voltage lines are electrically connected to one end of an initialization transistor of each of the third-color pixel circuits.
